(19) United States
(12) Patent Application Publication
(10) Pub. No.: US 2024/0138175 A1
(43) Pub. Date: Apr. 25, 2024

(54) ORGANIC LIGHT-EMITTING DEVICE

(71) Applicant: CANON KABUSHIKI KAISHA, Tokyo (JP)

(72) Inventors: HIROKAZU MIYASHITA, Miyagi (JP); HITOSHI NAGASHIMA, Kanagawa (JP); YOSUKE NISHIDE, Kanagawa (JP); NAOKI YAMADA, Tokyo (JP)

(21) Appl. No.: 18/481,160

(22) Filed: Oct. 4, 2023

(30) Foreign Application Priority Data
Oct. 6, 2022 (JP) 2022-161354

(51) Int. Cl. H10K 50/125

(52) U.S. Cl. CPC H10K 50/125; H10K 2101/30

(57) ABSTRACT

An organic light-emitting device includes a first light-emitting layer and a second light-emitting layer. The first light-emitting layer contains a first organic compound, a first light-emitting material, and a second light-emitting material. The second light-emitting layer contains a second organic compound and a third light-emitting material. Each of the light-emitting materials is a fluorescent material. The following relationships or inequalities (a) to (c) are satisfied,

S1D2>S1D1 (a),

S1D3≥S1D2 (b),

and

S1D2−S1D1>S1D3−S1D2 (c)

where S1D1 is a singlet energy of the first light-emitting material, S1D2 is a singlet energy of the second light-emitting material, and S1D3 is a singlet energy of the third light-emitting material.

### BACKGROUND OF THE INVENTION

### Technical Field

One disclosed aspect of the embodiments relates to an organic light-emitting device and various apparatuses each including the organic light-emitting device. Description of the Related Art

Organic light-emitting devices (hereinafter, also referred to as “organic electroluminescent devices” or “organic EL devices”) each include a pair of electrodes and an organic compound layer disposed between these electrodes, the organic compound layer including a light-emitting layer. Such an organic light-emitting device emits light by energizing the organic compound layer through the pair of electrodes.

In recent years, research and development of full-color displays using organic light-emitting devices has been vigorously pursued. Organic light-emitting devices are known to be broadly classified into fluorescent devices and phosphorescent devices in accordance with the type of compound contained in light-emitting layers, and energy diagrams suitable for each are required to be designed.

In the case of producing a full-color display, there are known a method in which a light-emitting layer is separately provided for each pixel (element), and a method in which an organic light-emitting device is used in which a light-emitting layer emits white light and a color filter is provided separately for each pixel. In the case of using a white light-emitting layer, two or more light-emitting materials are known to be used in an organic light-emitting device.

Japanese Patent Laid-Open No. 2015-201279 (PTL 1) discloses an organic light-emitting device including stacked blue light-emitting layers that fluoresce. PCT Japanese Translation Patent Publication No. 2008-505449 (PTL 2) discloses an organic light-emitting device in which a light-emitting layer composed of a hole-transporting host and a fluorescent material and a light-emitting layer composed of an electron-transporting host and a fluorescent material are stacked. Japanese Patent Laid-Open No. 2009-182322 (PTL 3) discloses an organic light-emitting device including stacked blue light-emitting layers that fluoresce. Japanese Patent Laid-Open No. 2005-108727 (PTL 4) discloses an organic light-emitting device including an orange light-emitting layer that fluoresces and a blue light-emitting layer that fluoresces are stacked.

The organic light-emitting devices described in PTLs 1 to 4 have room for improvement in durability characteristics because it is difficult to adjust the carrier balance and energy transfer in the stacked light-emitting layers.

### SUMMARY OF THE INVENTION

One embodiment has been accomplished in light of the above circumstances and provides an organic light-emitting device having improved driving durability by adjusting carrier balance and energy transfer in stacked light-emitting layers.

One aspect of the embodiments is directed to providing an organic light-emitting device including a first electrode, a first light-emitting layer, a second light-emitting layer in contact with the first light-emitting layer, and a second electrode.

The first light-emitting layer contains a first organic compound, a first light-emitting material, and a second light-emitting material.

The second light-emitting layer contains a second organic compound and a third light-emitting material, the second light-emitting layer being free of the first light-emitting material.

Each of the first light-emitting material, the second light-emitting material, and the third light-emitting material is a fluorescent material.

The following relationships or inequalities (a) to (c) are satisfied,

S1D2>S1D1 (a),

S1D3≥S1D2 (b),

and

S1D2−S1D1>S1D3−S1D2 (c)

where S1D1 is the singlet energy of the first light-emitting material, S1D2 is the singlet energy of the second light-emitting material, and S1D3 is the singlet energy of the third light-emitting material.

Further features of the disclosure will become apparent from the following description of exemplary embodiments with reference to the attached drawings.

### BRIEF DESCRIPTION OF THE DRAWINGS

FIG. 1 is a schematic cross-sectional view of an organic light-emitting device according to an embodiment.

FIG. 2 is an energy diagram schematically illustrating energy levels around a light-emitting layer of an organic light-emitting device according to an embodiment.

FIG. 3 is a diagram schematically illustrating singlet energy levels of fluorescent materials contained in a light-emitting layer of an organic light-emitting device according to an embodiment.

FIG. 4A is a schematic view of a display apparatus according to an embodiment.

FIG. 4B is a schematic view of a display apparatus according to an embodiment.

FIG. 5 is a schematic view of a display apparatus according to an embodiment.

FIG. 6A is a schematic view of an image pickup apparatus according to an embodiment. FIG. 6B is a schematic view of an electronic apparatus according to an embodiment.

FIG. 7A is a schematic view of a display apparatus according to an embodiment.

FIG. 7B is a schematic view of a foldable display apparatus according to an embodiment.

FIG. 8A is a schematic view of a lighting apparatus according to an embodiment.

FIG. 8B is a schematic view of an automobile including an automotive lighting unit according to an embodiment.

FIG. 9A is a schematic view illustrating an example of a wearable device according to an embodiment. FIG. 9B is a schematic view of an example of a wearable device according to an embodiment, the wearable device including an image pickup apparatus.

FIG. 10A is a schematic view of an example of an image-forming apparatus according to an embodiment and an example of an exposure light source thereof, FIG. 10B is a schematic view of an example of an exposure light source of an image-forming apparatus according to an embodiment. FIG. 10C is a schematic view of an example of an exposure light source of an image-forming apparatus according to an embodiment.

### DESCRIPTION OF THE EMBODIMENTS

An organic light-emitting device according to an embodiment of the disclosure includes a first electrode, a first light-emitting layer, a second light-emitting layer, and a second electrode. One of the first electrode and the second electrode is an anode, and the other is a cathode. At least one of the first electrode and the second electrode may be an electrode that transmits light. One of the first electrode and the second electrode may be a reflective electrode. The first light-emitting layer and the second light-emitting layer are in contact with each other. The first light-emitting layer and the second light-emitting layer are arranged between the anode and the cathode.

The first light-emitting layer contains a first organic compound, a first light-emitting material, and a second light-emitting material. The second light-emitting layer contains a second organic compound and a third light-emitting material. Moreover, the second light-emitting layer does not contain the first light-emitting material. The first light-emitting material, the second light-emitting material, and the third light-emitting material are fluorescent materials.

The organic light-emitting device according to an embodiment is characterized by satisfying the following relationships or inequalities (a) to (c).

S1D2>S1D1 (a)

S1D3≥S1D2 (b)

S1D2−S1D1>S1D3−S1D2 (c)
S1D1: The singlet energy of the first light-emitting material
S1D2: The singlet energy of the second light-emitting material
S1D3: The singlet energy of the third light-emitting material

The meanings of the above relations (a) to (c) are described below.

The relation (a) indicates that the first light-emitting layer contains the first light-emitting material and the second light-emitting material, the first light-emitting material has lower singlet energy than the second light-emitting material, and the emission from the first light-emitting material is mainly observed.

The relation (b) indicates that the singlet energy of the third light-emitting material contained in the second light-emitting layer is larger than or equal to the singlet energy of the second light-emitting material contained in the first light-emitting layer. Together with the above relation (a), it also indicates that the third light-emitting material has higher singlet energy than the first light-emitting material. This indicates that the second light-emitting layer emits light having a shorter wavelength than the light emitted from the first light-emitting layer.

The relation (c) indicates that the difference in singlet energy between the third light-emitting material and the second light-emitting material is less than the difference in singlet energy between the first light-emitting material and the second light-emitting material. As will be described later, this indicates that energy transfer occurs more easily between the third light-emitting material and the second light-emitting material than between the third light-emitting material and the first light-emitting material.

The third light-emitting material and the second light-emitting material are fluorescent materials having little or no difference in singlet energy and have substantially the same energy gap. The positional relationship between the highest occupied molecular orbital (HOMO) and lowest unoccupied molecular orbital (LUMO) energy levels thereof is also close, so that carrier transfer occurs more easily between the third light-emitting material and the second light-emitting material than between the third light-emitting material and the first light-emitting material. Thus, as will be described below, the density of excitons generated in the first light-emitting layer and the second light-emitting layer can be easily adjusted between the light-emitting layers to improve the driving durability.

The term “singlet energy” used in this specification refers to the energy of the lowest excited singlet state, and is expressed in units of eV. The larger value indicates higher energy. In the case of conversion into wavelength, the higher energy indicates a shorter wavelength.

In this specification, an energy gap refers to a gap in energy from the energy level of the HOMO to the energy level of the LUMO, and is also referred to as a band gap. In this specification, the energy level of HOMO may also be referred to as a HOMO level or HOMO, and the energy level of LUMO may also be referred to as a LUMO level or LUMO.

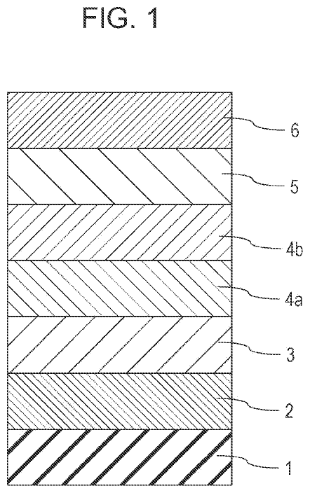

Embodiments of the disclosure will be described in more detail below using FIGS. 1 to 3.

FIG. 1 is a schematic cross-sectional view of an organic light-emitting device according to an embodiment. In the organic light-emitting device illustrated in FIG. 1, an anode 2, a hole transport layer 3, a first light-emitting layer 4a, a second light-emitting layer 4b, an electron transport layer 5, and a cathode 6 are disposed, in that order, over an insulating layer 1.

In the present embodiment, the light-emitting layer refers to a layer that emits light among organic compound layers provided between electrodes. Among the compounds contained in each light-emitting layer, a compound having the largest proportion by mass may be referred to as a host, and a compound mainly contributing to light emission may be referred to as a dopant or a guest.

More specifically, the terms “host” refers to a material whose content in a light-emitting layer is more than 50% by mass among materials contained in the light-emitting layer. More specifically, the terms “dopant” refers to a material whose content in the light-emitting layer is less than 50% by mass among the materials contained in the light-emitting layer. The concentration of the dopant in the light-emitting layer is preferably 0.1% or more by mass and 20% or less by mass, more preferably 10% or less by mass, in order to inhibit concentration quenching. The dopant used in the disclosure indicates the first light-emitting material and the third light-emitting material.

Among compounds contained in each light-emitting layer, the assist material refers to a compound that has a lower proportion by mass than the host in the compounds contained in the light-emitting layer and that assists the light emission of the guest. The assist material is also referred to as a “second host”. Alternatively, when the guest is referred to as a “first compound”, the assist material can be referred to as a “second compound”. The assist material according to an embodiment is a second light-emitting material.

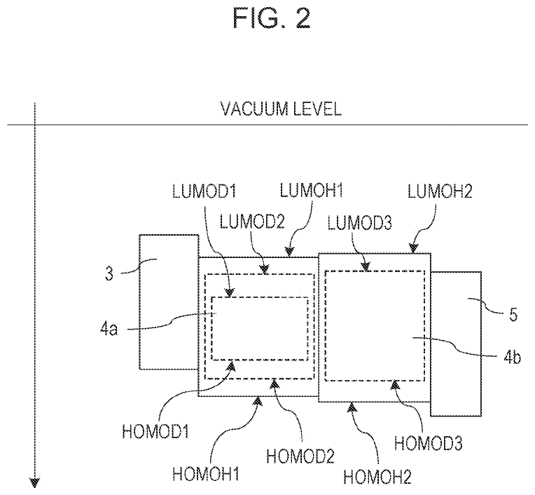

FIG. 2 is an energy diagram schematically illustrating energy levels around the light-emitting layer included in the organic light-emitting device according to an embodiment. In FIG. 2, the HOMO levels and the LUMO levels of the materials are presented as follows.
HOMOD1: HOMO level of the first light-emitting material
LUMOD1: LUMO level of the first light-emitting material
HOMOD2: HOMO level of the second light-emitting material
LUMOD2: LUMO level of the second light-emitting material
HOMOD3: HOMO level of the third light-emitting material
LUMOD3: LUMO level of the third light-emitting material
HOMOH1: HOMO level of the first organic compound
LUMOH1: LUMO level of the first organic compound
HOMOH2: HOMO level of the second organic compound
LUMOH2: LUMO level of the second organic compound

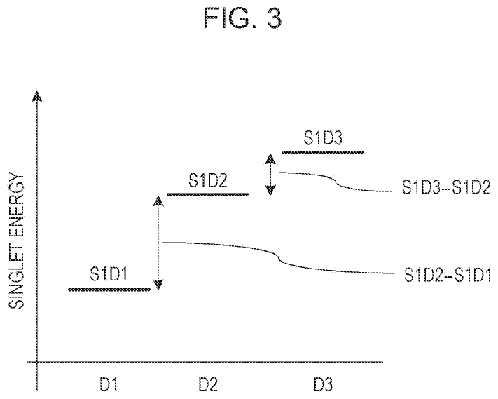

FIG. 3 is a diagram schematically illustrating the relationship between the singlet energy levels of fluorescent materials contained in a light-emitting layer included in an organic light-emitting device according to an embodiment. In FIG. 3, the vertical axis represents the energy level, and the upper direction of the figure represents higher energy. In FIG. 3, the singlet energy of each material is presented as follows.
S1D1: The singlet energy of the first light-emitting material
S1D2: The singlet energy of the second light-emitting material
S1D3: The singlet energy of the third light-emitting material

As illustrated in FIG. 3, in an embodiment, the following relationships or inequalities (a) to (c) are satisfied between the first light-emitting material and the second light-emitting material contained in the first light-emitting layer 4a and the third light-emitting material contained in the second light-emitting layer 4b.

S1D2>S1D1 (a)

S1D3≥S1D2 (b)

S1D2−S1D1>S1D3−S1D2 (c)

In an embodiment of the disclosure, as the singlet energy of the fluorescent material, an actually measured value may be used, or a value obtained by a molecular orbital calculation method may be used. As the molecular orbital calculation method for the fluorescent materials used in the present specification, the density functional theory (DFT), which is widely used at present, was used with the B3LYP functional and 6-31G* as the basis function. The molecular orbital calculation method was performed using Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery, Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010), which is widely used at present.

The method for measuring the actually measured value will be specifically described in examples described below.

The organic light-emitting device according to an embodiment has a device configuration having two or more light-emitting layers, and has the following configurations [1] and [2].
(1) Two light-emitting layers are stacked. Each of the light-emitting layers contains a fluorescent material that exhibits a different emission color. One of the light-emitting layers contains a fluorescent material that is an assist material for singlet energy transfer.

In the organic light-emitting device according to an embodiment, two light-emitting layers are stacked. Each light-emitting layer contains a fluorescent material. Each light-emitting layer exhibits a different emission wavelength. Fluorescence is luminescence derived from singlet energy. That is, the singlet energies generated in the respective light-emitting layers are different from each other and have a magnitude relationship. Thus, energy is transferred from a light-emitting layer having higher singlet energy to a light-emitting layer having lower singlet energy.

The inventors have found that the device durability is improved by rapidly transferring excess singlet energy generated in a light-emitting layer having higher singlet energy to an adjacent light-emitting layer having lower singlet energy.

More specifically, a fluorescent material having a singlet energy level that is an intermediate value between the singlet energy levels of the fluorescent materials contained in the light-emitting layers is contained in the light-emitting layer to which the energy is transferred. Such a structure can promote energy transfer from the high-energy light-emitting layer to the adjacent low-energy light-emitting layer. In other words, an assist material for singlet energy transfer is contained.

In general, singlet-singlet annihilation (SSA) is one of the deterioration models of fluorescent devices. SSA is caused by collision between excess singlet excitons that are not transferred to the light emission process. The higher-order excited state generated by SSA has high energy. This may lead to material deterioration to deteriorate the device durability.

The high energy generated by SSA is proportional to the singlet energy of the light-emitting layer. Thus, in a light-emitting layer having higher singlet energy, SSA occurs in which a higher-order excited state having higher energy is generated. This may lead to further material deterioration. The material deterioration, therefore, can be considered to be inhibited by reducing SSA in a light-emitting layer having higher energy and increasing SSA in a light-emitting layer having lower energy instead.

In an embodiment of the disclosure, the above relationships or inequalities (a) and (b) are satisfied. That is, the first light-emitting layer contains the second light-emitting material having an intermediate energy level for promoting the singlet energy transfer in order to facilitate energy transfer from the second light-emitting layer containing the third light-emitting material having higher singlet energy to the first light-emitting layer containing the first light-emitting material having lower singlet energy in the two adjacent light-emitting layers.

This can reduce SSA that may occur in the second light-emitting layer containing the third light-emitting material having higher singlet energy, and can inhibit material deterioration to provide the organic light-emitting device having superior durability characteristics.
[2] The singlet energy of the assist material that promotes energy transfer is closer to the singlet energy of the light-emitting material from which the energy is transferred than to the singlet energy of the light-emitting material to which the energy is transferred.

As described above, the organic light-emitting device according to an embodiment includes the stacked light-emitting layers having driving durability improved by promoting singlet energy transfer due to the use of the assist material.

Typically, the energy transfer of a singlet exciton is considered to be caused by Förster energy transfer. As illustrated in the following equation [1], the rate constant of Förster energy transfer is proportional to the overlap between the emission spectrum of a donor from which energy is transferred and the absorption spectrum of an acceptor to which energy is transferred. In addition, the rate constant is inversely proportional to the intermolecular distance between the donor and the acceptor.

$${k}_{FRET} = \frac{9000 {c}^{4} {K}^{2} Φ ( ln 10 )}{128 {π}^{5} {n}^{4} N τ {R}^{6}} \int {f}_{H} ( λ ) {ε}_{D} ( λ ) {λ}^{4} d λ \qquad [ 1 ]$$

C: Speed of light
K²: Dipole orientation factor
Φ: Emission quantum yield
N: Refractive index of medium
N: Avogadro's number
τ: Fluorescence lifetime of donor
R: Intermolecular distance between donor and acceptor
f_{H}(λ): Normalized donor emission spectrum
ε_{D}(λ): Molar extinction coefficient of acceptor

The inventors have found that Förster energy transfer between the first light-emitting layer and the second light-emitting layer can be promoted when the relationship or inequality (c) is satisfied.

That is, in the stacked light-emitting layer structure according to an embodiment, the singlet energy of the second light-emitting material, which is an assist material for promoting energy transfer, has a value closer to that of the third light-emitting material, from which energy is transferred, than to that of the first light-emitting material, to which energy is transferred. Thereby, energy transfer is promoted.

In an embodiment, the second light-emitting material serving as an assist material is contained in the first light-emitting layer. The third light-emitting material from which energy is transferred is contained in the second light-emitting layer. For this reason, an opportunity to reduce the intermolecular distance between the donor (third light-emitting material) and acceptor (second light-emitting material) is limited to the interface between the first light-emitting layer and the second light-emitting layer.

From the above equation [1], in Förster energy transfer, a shorter intermolecular distance between the donor and acceptor results in easier energy transfer. Thus, the distance between the donor and acceptor can be short.

The inventors have found that the compatibility is improved and the intermolecular distance is shortened by reducing the difference in singlet energy between the donor and the acceptor. The reason for this is presumably as follows: the donor and the acceptor are fluorescent materials. Thus, for example, the singlet energy of the π-π* transition is proportional to the conjugation length of the molecule, so they have similar molecular structural features. The dipole moments are easily aligned, so that the molecules are easy to approach each other.

For example, when the second light-emitting layer is stacked after the formation of the first light-emitting layer containing the acceptor, the donor molecules gather easily to the acceptor molecules that have a similar energy level and that are likely to be more stable in terms of energy. As a result, the intermolecular distance between the donor and the acceptor is shortened.

In addition, the difference in singlet energy between the donor and the acceptor is small; thus, the overlap between the emission spectrum of the donor and the absorption spectrum of the acceptor is sufficiently large.

As described above, when the relationship or inequality (c) is satisfied, the intermolecular distance between the donor (the third light-emitting material) and the acceptor (the second light-emitting material) is shortened, and the overlap between the emission spectrum of the donor and the absorption spectrum of the acceptor is sufficiently increased, thereby promoting Förster energy transfer.

After the energy transfer from the third light-emitting material to the second light-emitting material, energy is transferred from the second light-emitting material to the first light-emitting material in the first light-emitting layer, and the light emission process of the first light-emitting material begins. When the stacked light-emitting layers are successively subjected to the singlet energy transfer process as described above, the accumulation itself of excess singlet excitons present without participating in the light emission process can be considered to be reduced. In other words, singlet excitons diffuse easily in the stacked light-emitting layers. That is, another feature of the disclosure is that SSA itself in which excess singlet excitons collide with each other can be reduced, and an organic light-emitting device having improved durability characteristics can be provided.

The organic light-emitting device according to an embodiment preferably has the following configurations in addition to the above-described [1] and [2].
[3] The LUMO level of the first light-emitting material is lower than the LUMO level of the first organic compound.
[4] The LUMO level of the third light-emitting material is lower than the LUMO level of the second organic compound.
[5] The concentration of the second light-emitting material is more than or equal to the concentration of the third light-emitting material.
[6] The concentration of the second light-emitting material is more than or equal to the concentration of the first light-emitting material.
[7] The second light-emitting material and the third light-emitting material have at least one identical partial structure.
[8] The second light-emitting material and the third light-emitting material are the same compound.
[9] The second light-emitting material and the third light-emitting material have a HOMO level difference of within 0.2 eV and a LUMO level difference of within 0.2 eV.
[10] The second light-emitting layer contains an assist material.
[11] The emission color of the first light-emitting material is red, and the emission color of the third light-emitting material is green.
[12] The first light-emitting layer is adjacent to the anode, and the second light-emitting layer is adjacent to the cathode.
[13] The concentration of the third light-emitting material is higher than the concentration of the first light-emitting material.
[14] The first organic compound and the second organic compound are the same compound.

These will be described below.
[3] The LUMO level of the first light-emitting material is lower than the LUMO level of the first organic compound.

That is, the following relationship or inequality (d) is satisfied.

LUMOD1<LUMOH1 (d)
LUMOD1: The LUMO level of the first light-emitting material
LUMOH1: The HOMO level of the first organic compound

The relationship or inequality (d) above indicates that the first light-emitting layer is an electron trapping light-emitting layer.

Since the first light-emitting layer is an electron trapping light-emitting layer, a structure in which holes among carriers are not excessively accumulated can be used. This is advantageous for a compound that is deteriorated by radical cations.
[4] The LUMO level of the third light-emitting material is lower than the LUMO level of the second organic compound.

That is, the following relationship or inequality (e) is satisfied.

LUMOD3<LUMOH2 (e)
LUMOD3: The LUMO level of the third light-emitting material
LUMOH2: The LUMO level of the second organic compound

The relationship or inequality (e) above indicates that the second light-emitting layer is an electron trapping light-emitting layer. Since the second light-emitting layer is an electron trapping light-emitting layer, a structure in which holes among carriers are not excessively accumulated can be used. This is advantageous for a compound that is deteriorated by radical cations.
[5] The concentration of the second light-emitting material is more than or equal to the concentration of the third light-emitting material.

That is, the following relationship or inequality (f) is satisfied.

C1D2≥C1D3 (f)
C1D2: The concentration of the second light-emitting material in the first light-emitting layer
C1D3: The concentration of the third light-emitting material in the second light-emitting layer

As described above, the intermolecular distance between the third light-emitting material (donor) contained in the second light-emitting layer and the second light-emitting material (acceptor) contained in the first light-emitting layer is shortest at the interface between the first light-emitting layer and the second light-emitting layer. When the concentration of the third light-emitting material in the second light-emitting layer is higher than or equal to the concentration of the second light-emitting material in the first light-emitting layer, energy transfer between the first light-emitting layer and the second light-emitting layer can be promoted. This is because the second light-emitting material that has received energy needs to perform energy transfer to the first light-emitting material. When the concentration of the third light-emitting material is higher than that of the second light-emitting material (C1D2<C1D3), a large amount of singlet energy is received from the third light-emitting material. The second light-emitting material has a large amount of singlet excitons before energy is transferred to the first light-emitting material, thereby easily causing SSA. If SSA occurs in the second light-emitting material, energy cannot be transferred to the first light-emitting material, which is disadvantageous.
[6] The concentration of the second light-emitting material is more than or equal to the concentration of the first light-emitting material.

That is, the following relationship or inequality (g) is satisfied.

C1D2≥C1D1 (g)
C1D2: The concentration of the second light-emitting material in the first light-emitting layer
C1D1: The concentration of the first light-emitting material in the first light-emitting layer

The organic light-emitting device including the stacked light-emitting layers according to an embodiment is characterized in that, for example, the singlet energy is successively transferred. Specifically, energy is transferred from the third light-emitting material to the second light-emitting material and further from the second light-emitting material to the first light-emitting material. When the stacked light-emitting layers are successively subjected to the singlet energy transfer process as described above, the accumulation itself of excess singlet excitons present without participating in the light emission process can be considered to be reduced.

The concentration of the second light-emitting material in the first light-emitting layer can be higher than or equal to the concentration of the first light-emitting material. When the concentration of the first light-emitting material is higher than that of the second light-emitting material (C1D2<C1D1), singlet energy is transferred from the third light-emitting material not to the second light-emitting material but to the first light-emitting material. This makes it difficult for excitons to diffuse through the above-described successive energy transfer process.
[7] The second light-emitting material and the third light-emitting material have at least one identical partial structure.

As described above, the compatibility between the third light-emitting material (donor) contained in the second light-emitting layer and the second light-emitting material (acceptor) contained in the first light-emitting layer is enhanced; thus, the energy transfer between the first light-emitting layer and the second light-emitting layer is promoted.

As a method for enhancing the compatibility between the third light-emitting material and the second light-emitting material, they can have an identical partial structure in the molecule. Specifically, the identical π-conjugated partial structure can be contained in the molecular structures of the fluorescent materials. Thus, molecules having the identical partial structure can easily approach each other, and as a result, the intermolecular distance between the third light-emitting material and the second light-emitting material can be considered to be reduced. In particular, the second light-emitting material and the third light-emitting material can be fluorescent materials each containing fluoranthene in the partial structure.

Examples of the compound containing fluoranthene in a partial structure include the following π-conjugated aromatic compounds. However, the disclosure is not limited thereto. The numbers of fused rings in the partial structures containing fluoranthene can be close to each other. Here, the fact that the numbers of fused rings in partial structures are close to each other will be described. For example, FF1 and FF2 in the specific examples below can be said to be close in number of fused rings, whereas FF1 and FF39 are far apart in number of fused rings.

Fluoranthene contains an electron-deficient five-membered ring, so that fluoranthene has a low LUMO level (far from the vacuum level) and is excellent in oxidation stability. Thus, excellent durability characteristics are provided. In addition, the skeleton has high planarity; thus, the molecules easily overlap with each other. For this reason, the second light-emitting material and the third light-emitting material easily approach each other. This promotes the energy transfer, thus providing excellent durability characteristics.

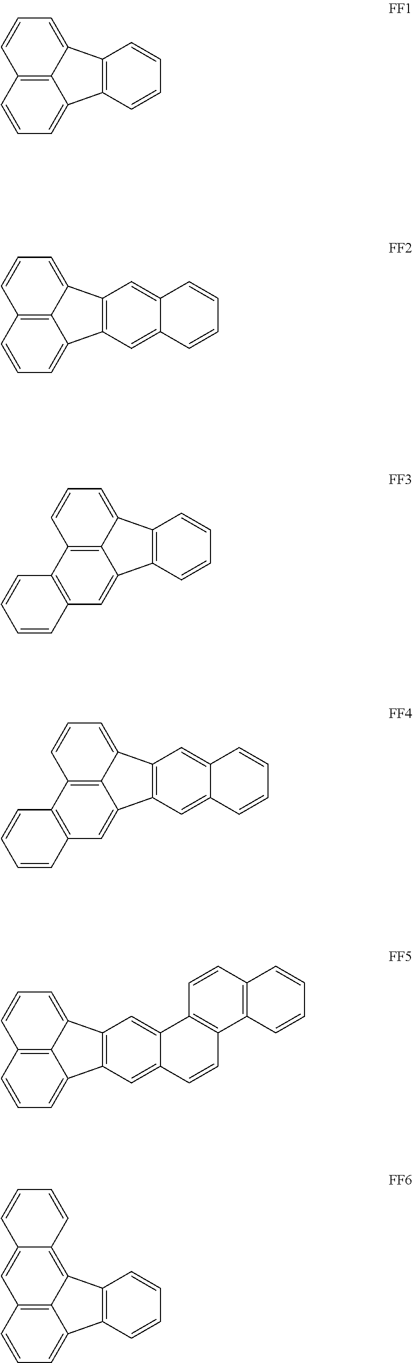

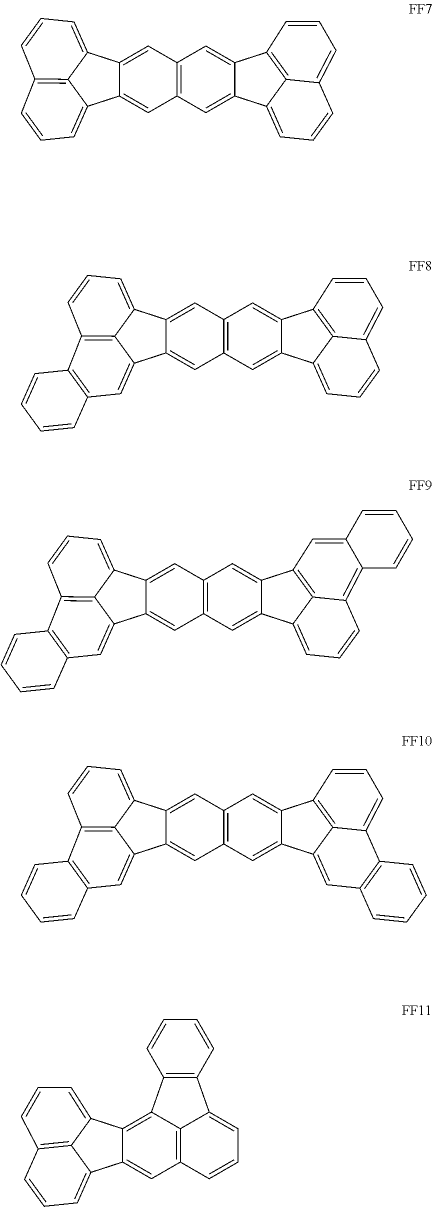

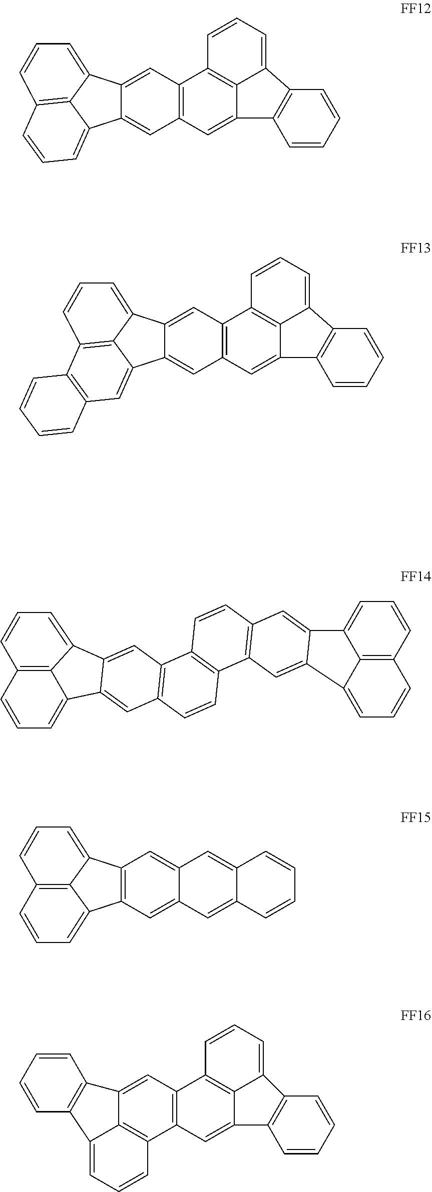

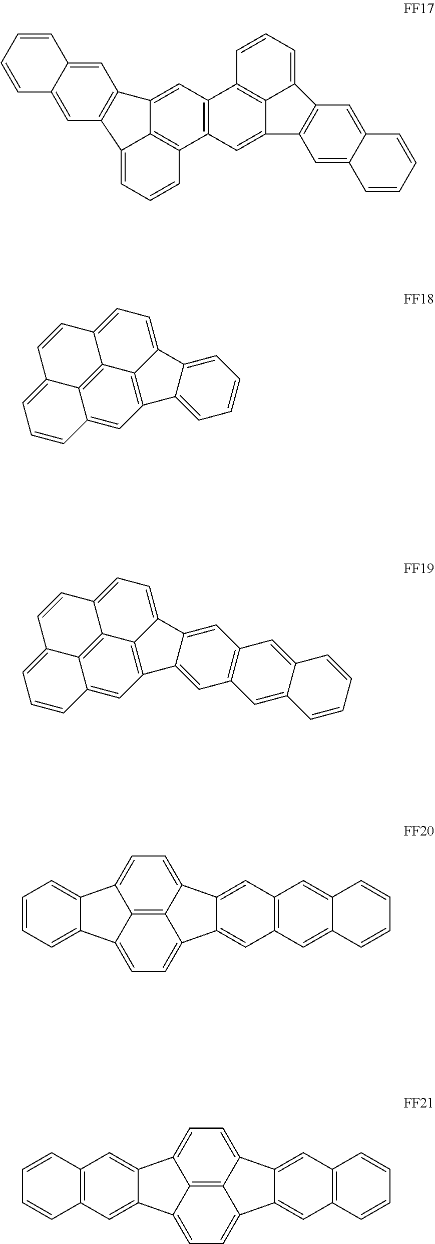

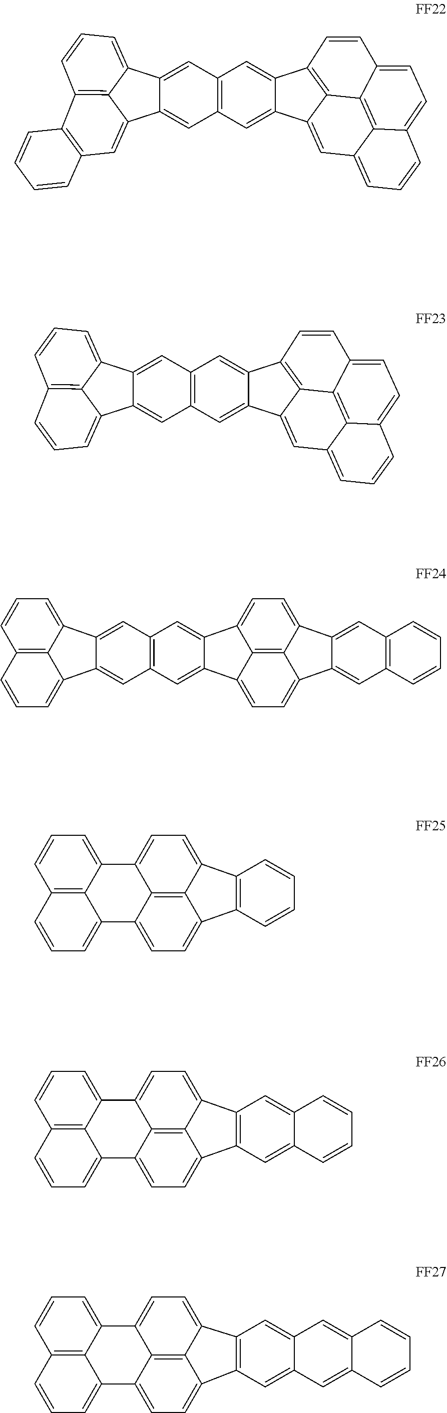

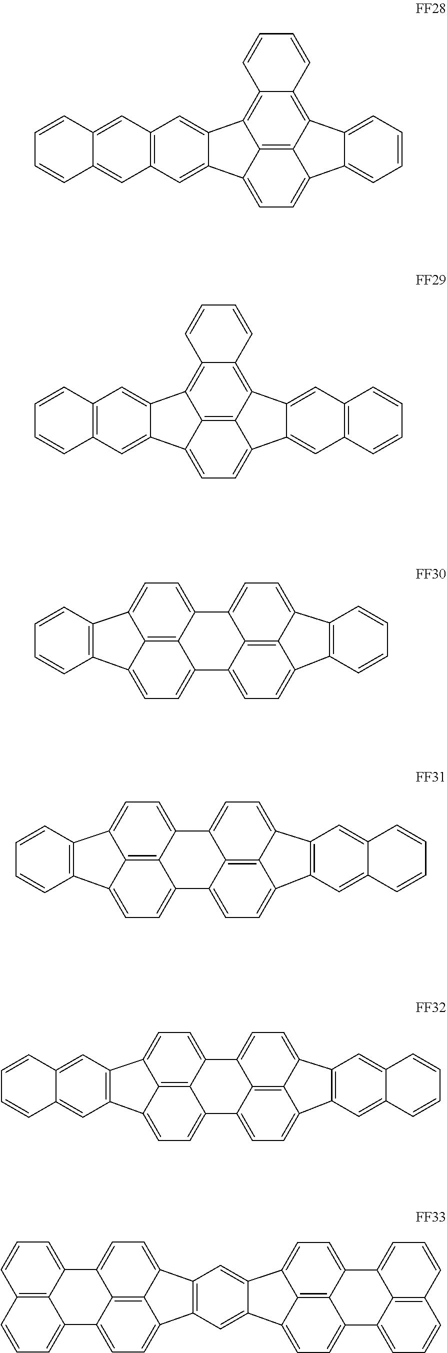

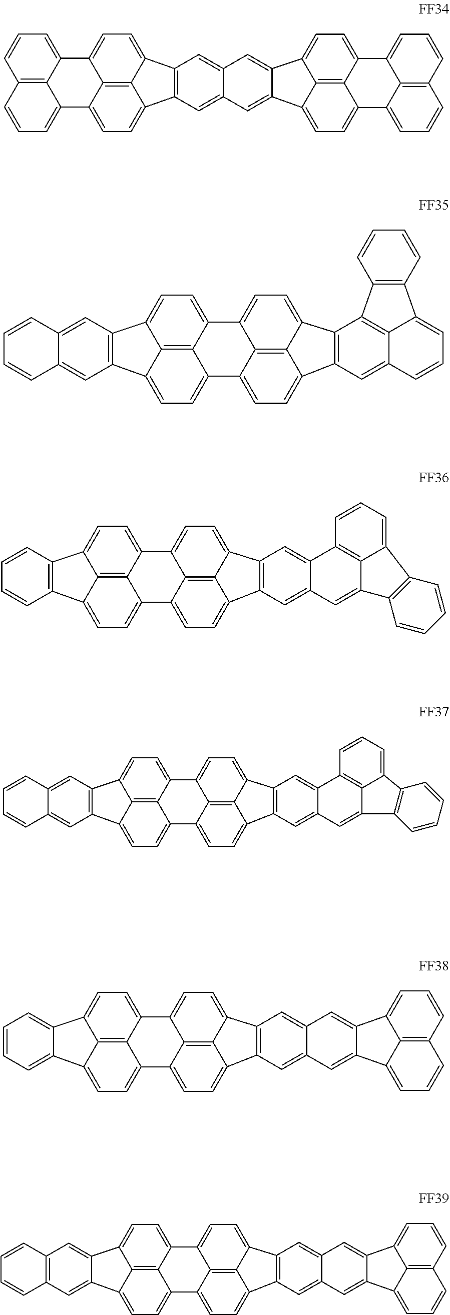

[8] The second light-emitting material and the third light-emitting material are the same compound.

As described above, in an embodiment, carrier transfer and energy transfer between the stacked light-emitting layers can be good. Thus, the second light-emitting material and the third light-emitting material can be the same compound. In this case, the compatibility between the second light-emitting material and the third light-emitting material can be enhanced, in particular, to promote carrier transfer and energy transfer between the first light-emitting layer and the second light-emitting layer.
[9] The second light-emitting material and the third light-emitting material have a HOMO level difference of within 0.2 eV and a LUMO level difference of within 0.2 eV.

That is, the following relationships or inequalities (h) and (i) are satisfied.

|LUMOD3−LUMOD2|≤0.2 eV (h)

|HOMOD3−HOMOD2|≤0.2 eV (i)
LUMOD2: The LUMO level of the second light-emitting material
HOMOD2: The HOMO level of the second light-emitting material
LUMOD3: The LUMO level of the third light-emitting material
HOMOD3: The HOMO level of the third light-emitting material

In the organic light-emitting device according to the embodiment illustrated in FIG. 2, the first light-emitting layer 4a contains the first organic compound as a first host, the second light-emitting material as an assist material, and the first light-emitting material as a dopant. The light-emitting layer 4b contains a second organic compound as a second host and a third light-emitting material as a dopant. Thus, the dopant or the assist material is considered to act as a trapping level for carriers (holes and electrons) moving in the light-emitting layers 4a and 4b.

When the second light-emitting material and the third light-emitting material have a HOMO level difference of within 0.2 eV and a LUMO level difference of within 0.2 eV, career mobility is promoted between the first light-emitting layer and the second light-emitting layer. That is, the second light-emitting material, serving as a carrier-trapping level, in the first light-emitting layer 4a and the second light-emitting material, serving as a carrier-trapping level, in the second light-emitting layer 4b have similar HOMO levels and similar LUMO levels, thereby promoting carrier transfer. When there is a marked difference between the HOMO levels or the LUMO levels of the second light-emitting material and the third light-emitting material, carriers are accumulated at the interface between the first light-emitting layer 4a and the second light-emitting layer 4b, so that the recombination zone is concentrated, which is disadvantageous for the luminous efficiency and the device durability. The enhancement of carrier transfer eliminates unwanted charge accumulation and exciton concentration, thereby reducing the occurrence of SSA and improving durability characteristics.
[10] The second light-emitting layer contains an assist material.

As described above, in the organic light-emitting device according to an embodiment, the recombination region is slightly shifted toward the second light-emitting layer. Energy can thus be efficiently transferred to the first light-emitting layer to allow well-balanced light emission to be extracted from the light-emitting layers.

The second light-emitting layer can contain an assist material. The assist material can be a material that allows carriers, either holes or electrons, to be injected into the second light-emitting layer and adjusts the recombination zone slightly toward the center of the second light-emitting layer.

Specifically, a material containing any of a triarylamine skeleton, a carbazole skeleton, an azine ring, an anthraquinone skeleton, a xanthone skeleton, and a thioxanthone skeleton in a partial structure can be used. These materials are excellent in electron-donating property and electron-withdrawing property; thus, HOMO and LUMO are easily adjusted, and injection of carriers from adjacent layers can be promoted.
[11] The emission color of the first light-emitting material is red, and the emission color of the third light-emitting material is green.

From the viewpoint of maximizing the luminous efficiency of each of the first light-emitting layer and the second light-emitting layer while satisfying the relationships or inequalities (a) to (c) described above, the first light-emitting material can be a red light-emitting material, and the third light-emitting material can be a green light-emitting material. This is because the organic light-emitting device according to an embodiment has a stacked structure in which energy can be efficiently transferred to the first light-emitting layer by slightly shifting the recombination zone to the second light-emitting layer, and thus light emission with a good balance between green light emission and red light emission can be easily achieved.

In the present specification, a blue light-emitting material refers to a light-emitting material that exhibits an emission spectrum with a maximum peak wavelength of 430 nm to 480 nm. The green light-emitting material refers to a light-emitting material that exhibits an emission spectrum with a maximum peak wavelength of 500 nm to 570 nm. The red light-emitting material refers to a light-emitting material that exhibits an emission spectrum with a maximum peak wavelength of 580 nm to 680 nm. The emission spectra can be measured with the influence of other compounds and crystalline states reduced by using, for example, a dilute solution in toluene.

Yellow light emission indicates that a main part of an emission spectrum is included in 565 nm to 590 nm. For example, yellow light emission can also be obtained by mixing green light emission and red light emission. Cyan light emission indicates that a main part of an emission spectrum is included in 485 nm to 500 nm. For example, cyan light emission can also be obtained by mixing blue light emission and green light emission.
[12] The anode, the first light-emitting layer, the second light-emitting layer, and the cathode are arranged in this order.

While the condition [11] described above is satisfied, the first light-emitting layer 4a containing the first organic compound, the second light-emitting material, and the first light-emitting material can be arranged between the anode and the cathode, and the second light-emitting layer 4b containing the second organic compound and the third light-emitting material can be arranged between the first light-emitting layer and the cathode, as described in FIG. 2. In this case, the first light-emitting material, which is a red light-emitting material, traps holes, and the third light-emitting material, which is a green light-emitting material, traps electrons; thus, a stacked-layer structure with the best carrier balance is provided.
[13] The concentration of the third light-emitting material is higher than the concentration of the first light-emitting material.

In addition to the above-described condition [12], the concentration of the third light-emitting material in the second light-emitting layer can be higher than the concentration of the first light-emitting material in the first light-emitting layer. That is, the following relationship or inequality (j) is satisfied.

C1D3>C1D1 (j)
C1D1: The concentration of the first light-emitting material in the first light-emitting layer
C1D3: The concentration of the third light-emitting material in the second light-emitting layer

When the first light-emitting material is a red fluorescent material, the band gap is small, and thus the carrier trapping property is likely to be high. In the present embodiment, the hole trapping property is improved. When the first light-emitting material serving as the red fluorescent material has a higher concentration than the third light-emitting material (C1D3<C1D1), the hole concentration in the first light-emitting layer is disadvantageously localized. For this reason, the carrier balance is adjusted by setting the concentration of the first light-emitting material to be low and allowing the second light-emitting material, which is an assist material, to play the role of transporting holes in the first light-emitting layer. In the second light-emitting layer, the third light-emitting material serves to transport electrons; thus, as described above, carriers can be smoothly transferred from and to the second light-emitting material. Therefore, the concentration of the third light-emitting material can be higher than the concentration of the first light-emitting material.
[14] The first organic compound and the second organic compound are the same type of compound.

As described above, in an embodiment, carrier transfer and energy transfer between the stacked light-emitting layers can be good. Thus, the first organic compound as the first host and the second organic compound as the second host can be the same compound. In this case, in particular, carrier transfer and energy transfer between the first light-emitting layer and the second light-emitting layer can be promoted.

### First to Third Light-Emitting Materials

The first to third light-emitting materials used in an embodiment will be described below.

The first to third light-emitting materials used in an embodiment are all fluorescent materials. Examples thereof include fused-ring compounds, such as fluorene derivatives, naphthalene derivatives, pyrene derivatives, perylene derivatives, tetracene derivatives, anthracene derivatives, and rubrene, quinacridone derivatives, coumarin derivatives, stilbene derivatives, organoaluminum complexes, such as tris(8-quinolinolato)aluminum, iridium complexes, platinum complexes, rhenium complexes, copper complexes, europium complexes, ruthenium complexes, and polymer derivatives, such as poly(phenylene vinylene) derivatives, polyfluorene derivatives and polyphenylene derivatives.

In particular, as described above, the fluoranthene skeleton is excellent in oxidation stability; thus, the durability characteristics can be improved. In addition, the fluoranthene skeleton provides excellent light emission characteristics and thus can be used in terms of luminous efficiency. Specific examples of then-conjugated aromatic compound containing fluoranthene in its partial structure include compounds illustrated in group FF exemplified as the second light-emitting material and the third light-emitting material.

Specific examples of the first to third light-emitting materials according to the present embodiment are illustrated below. However, the disclosure is not limited thereto.

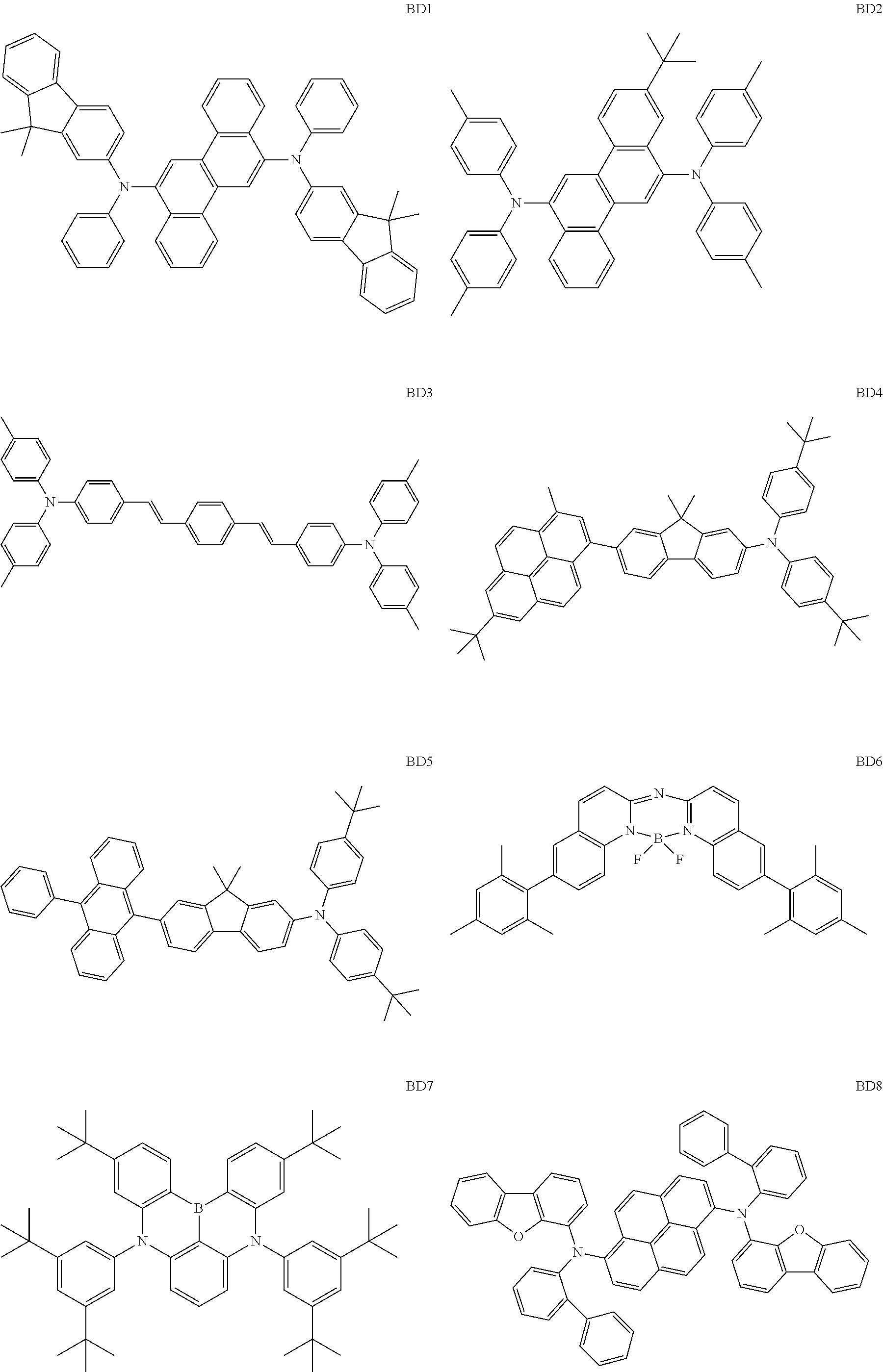

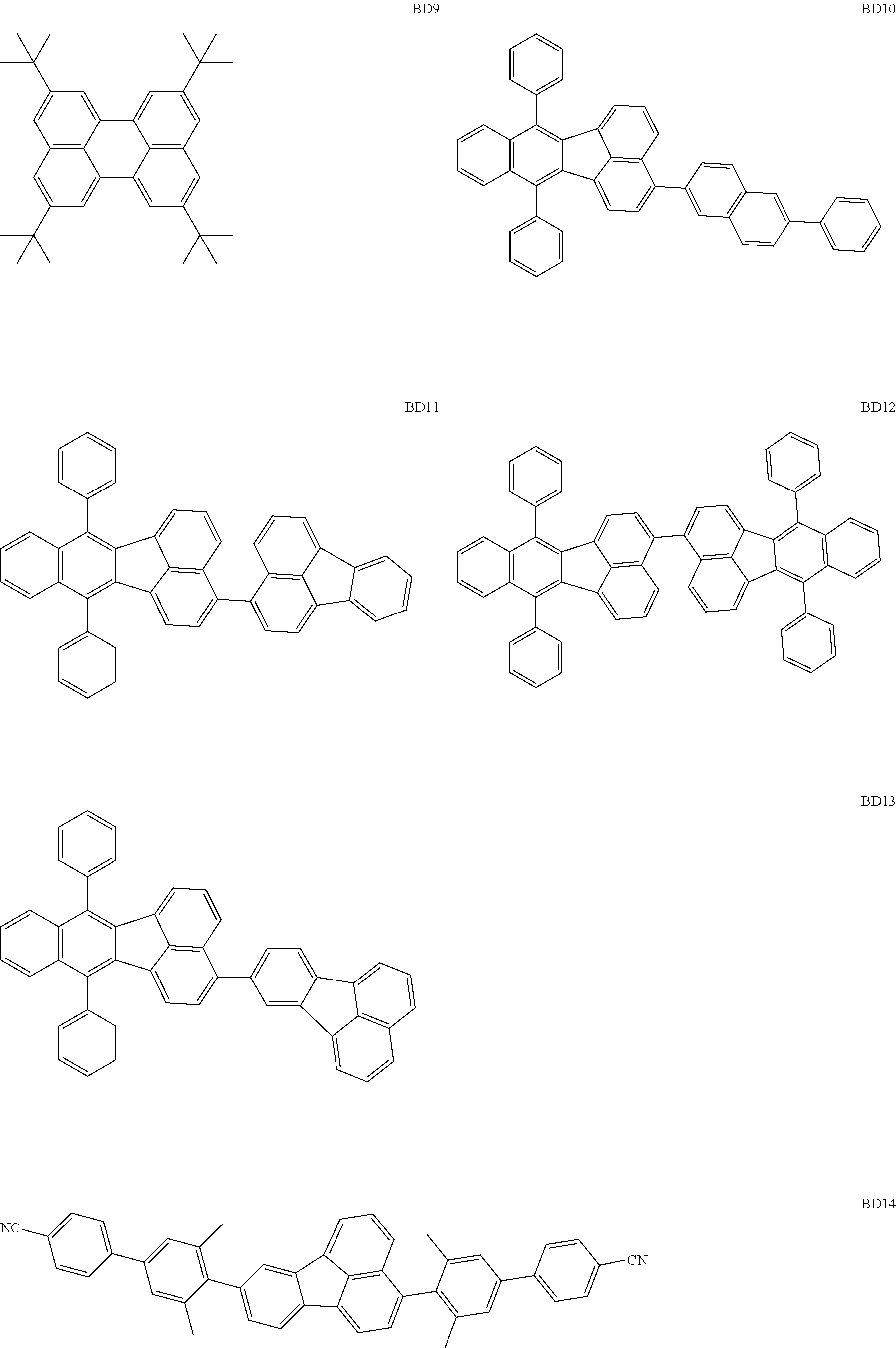

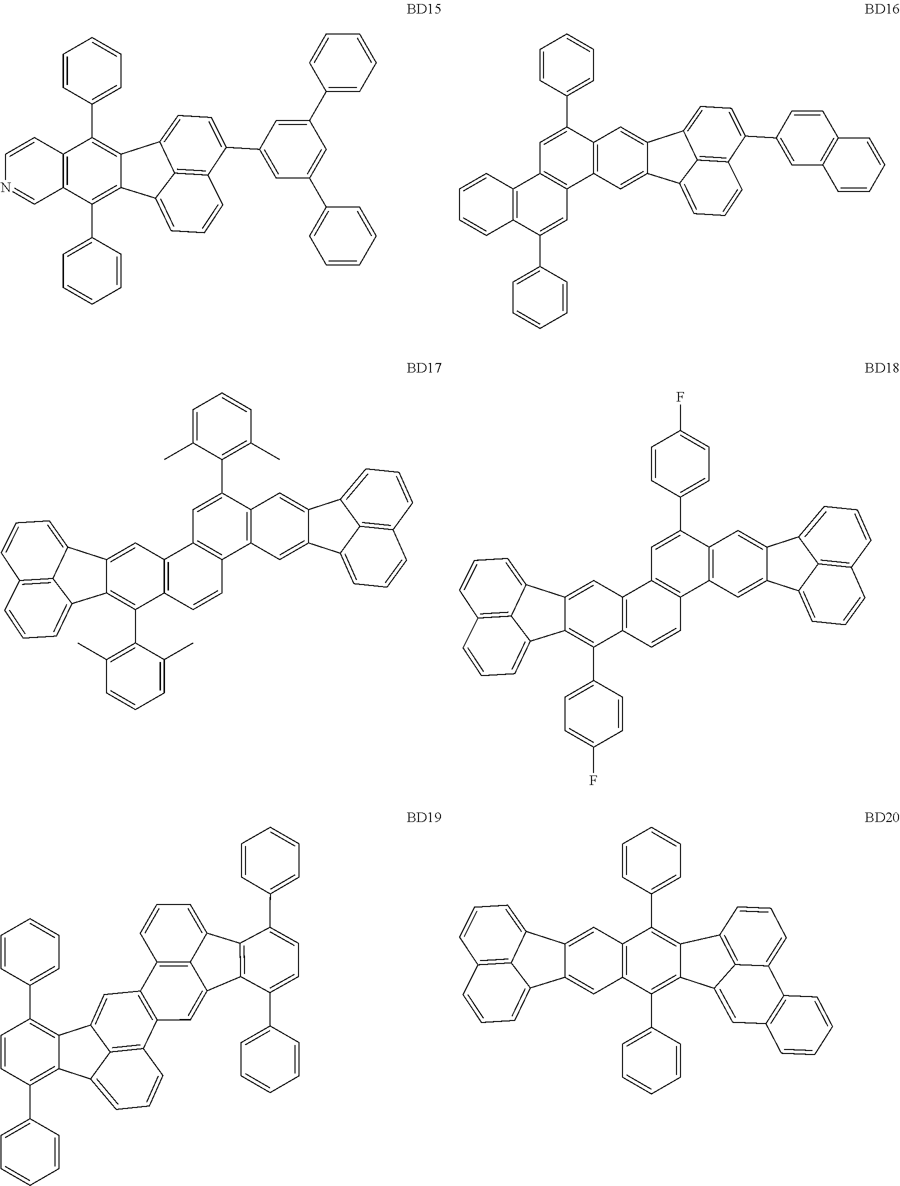

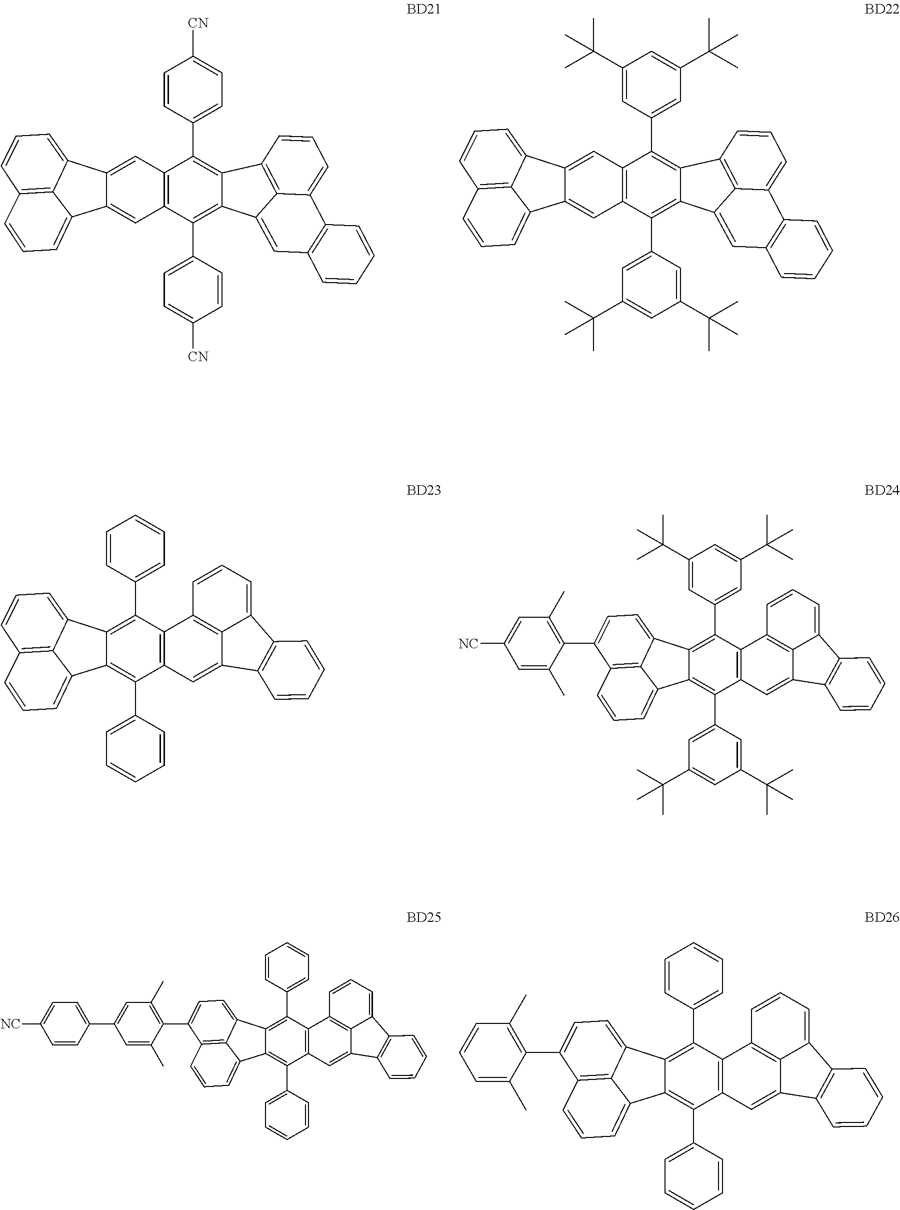

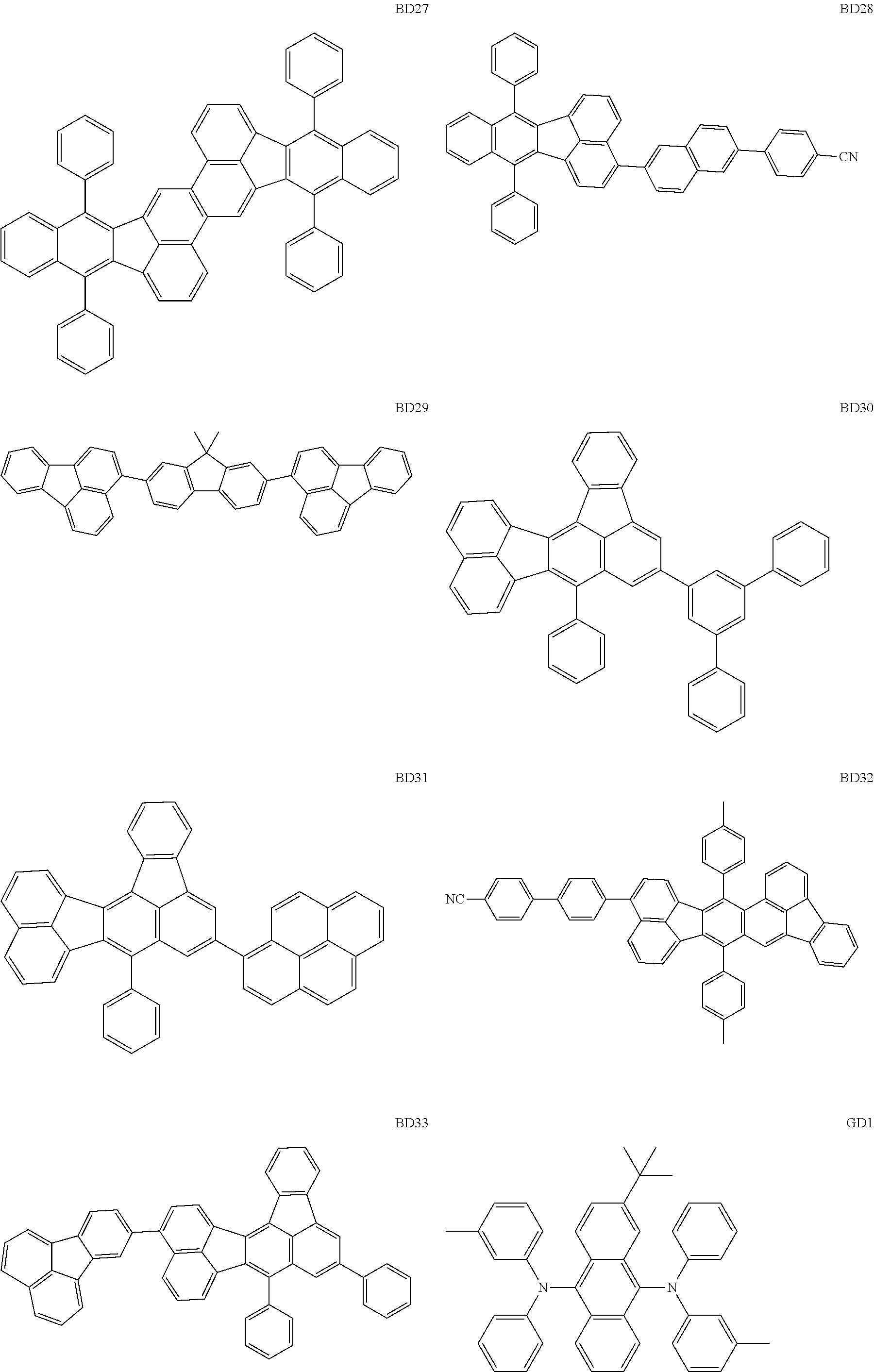

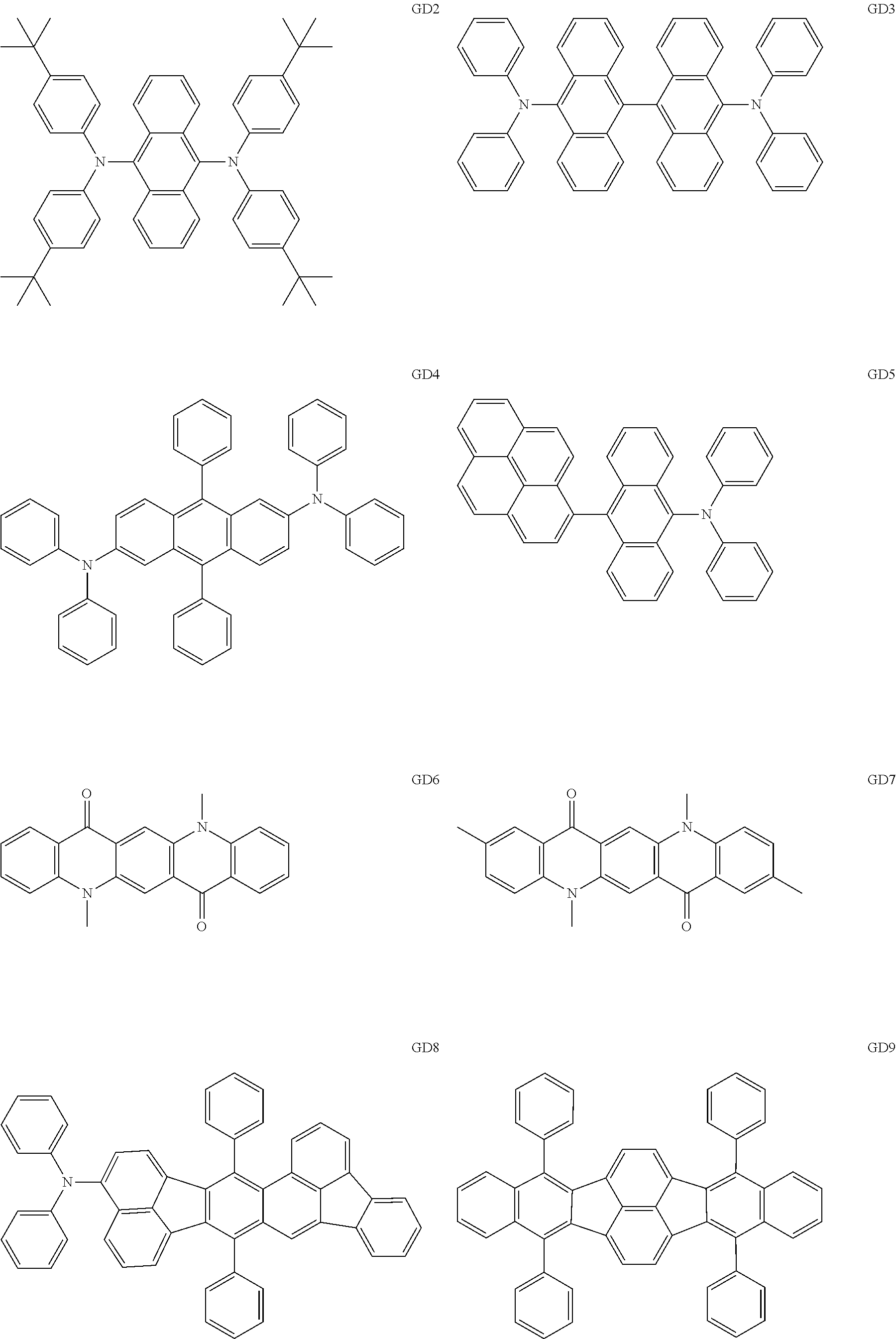

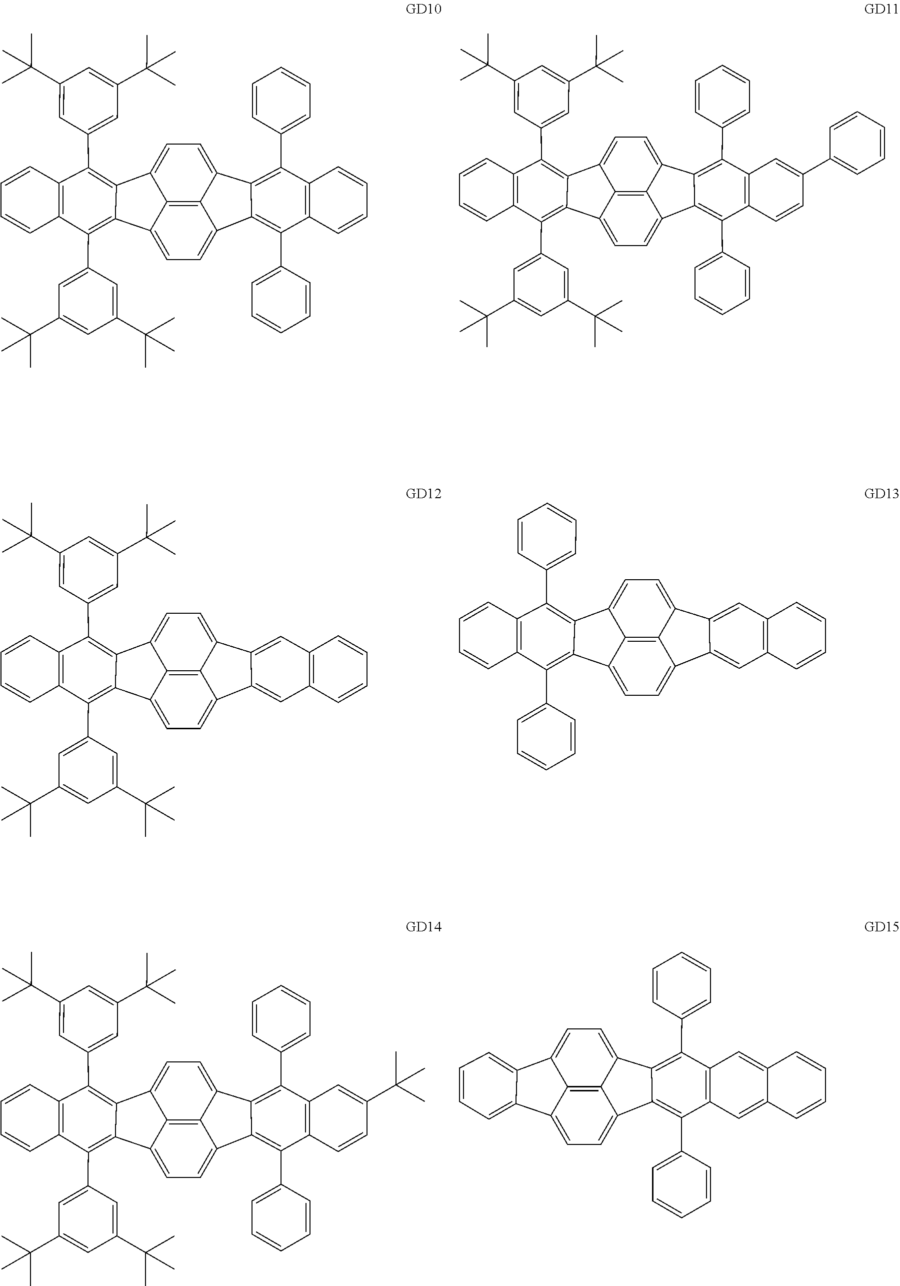

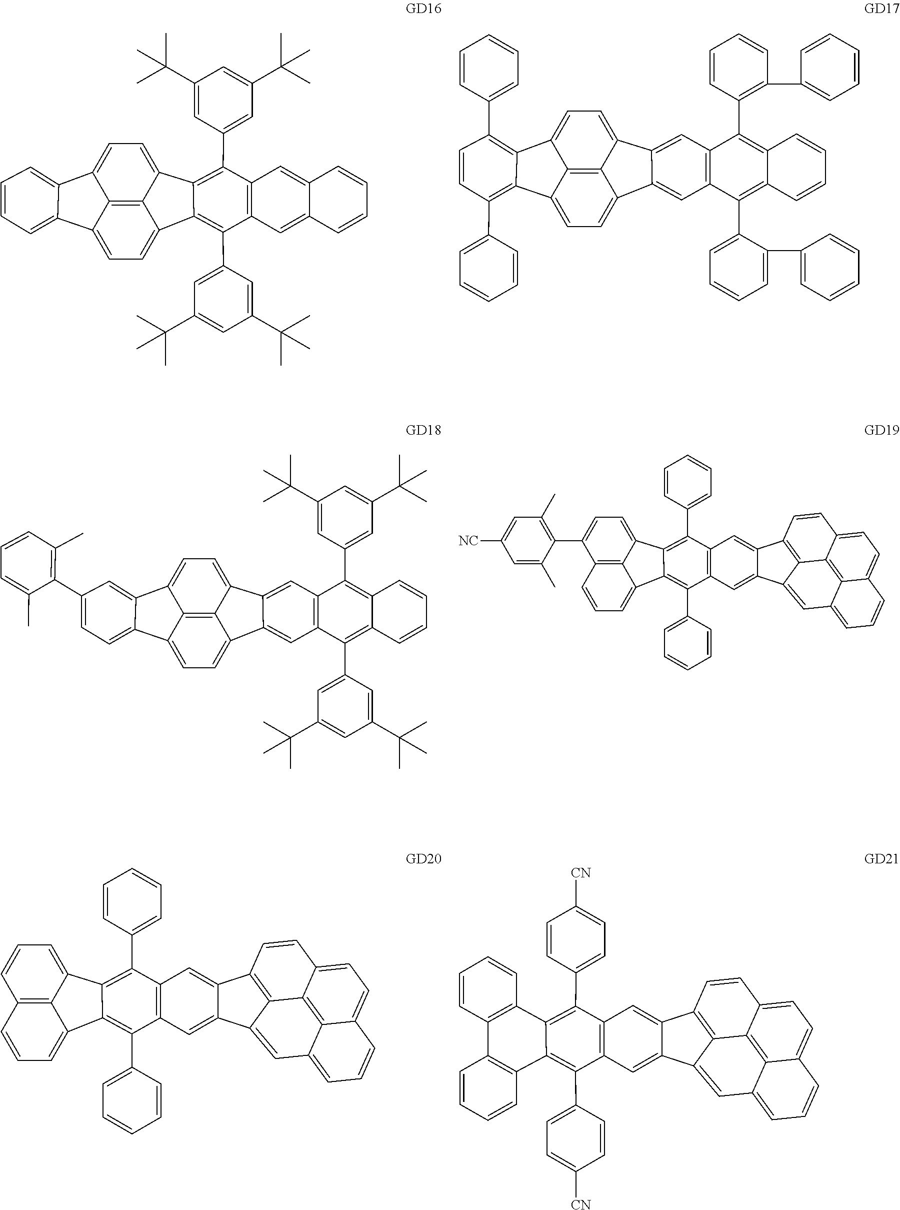

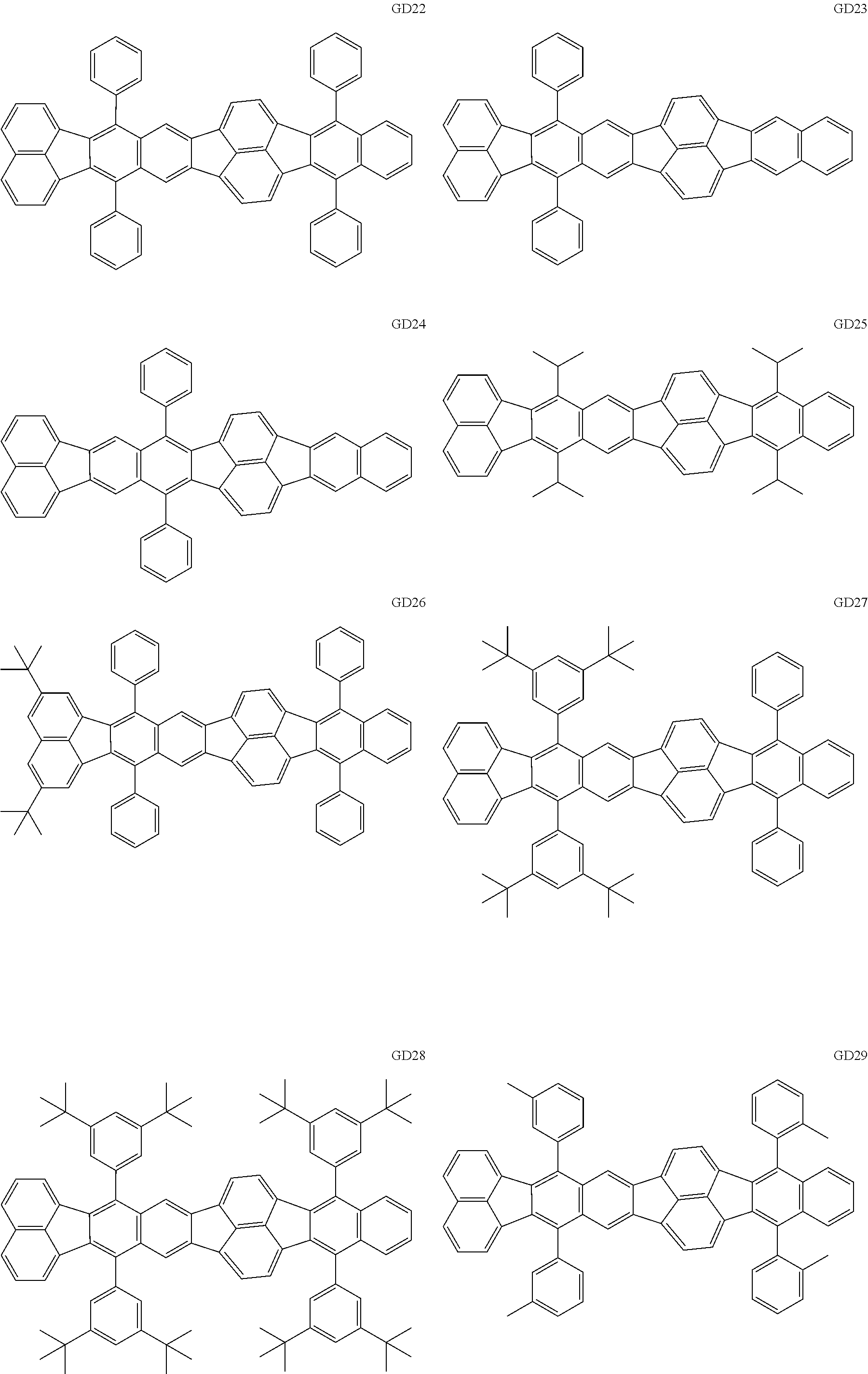

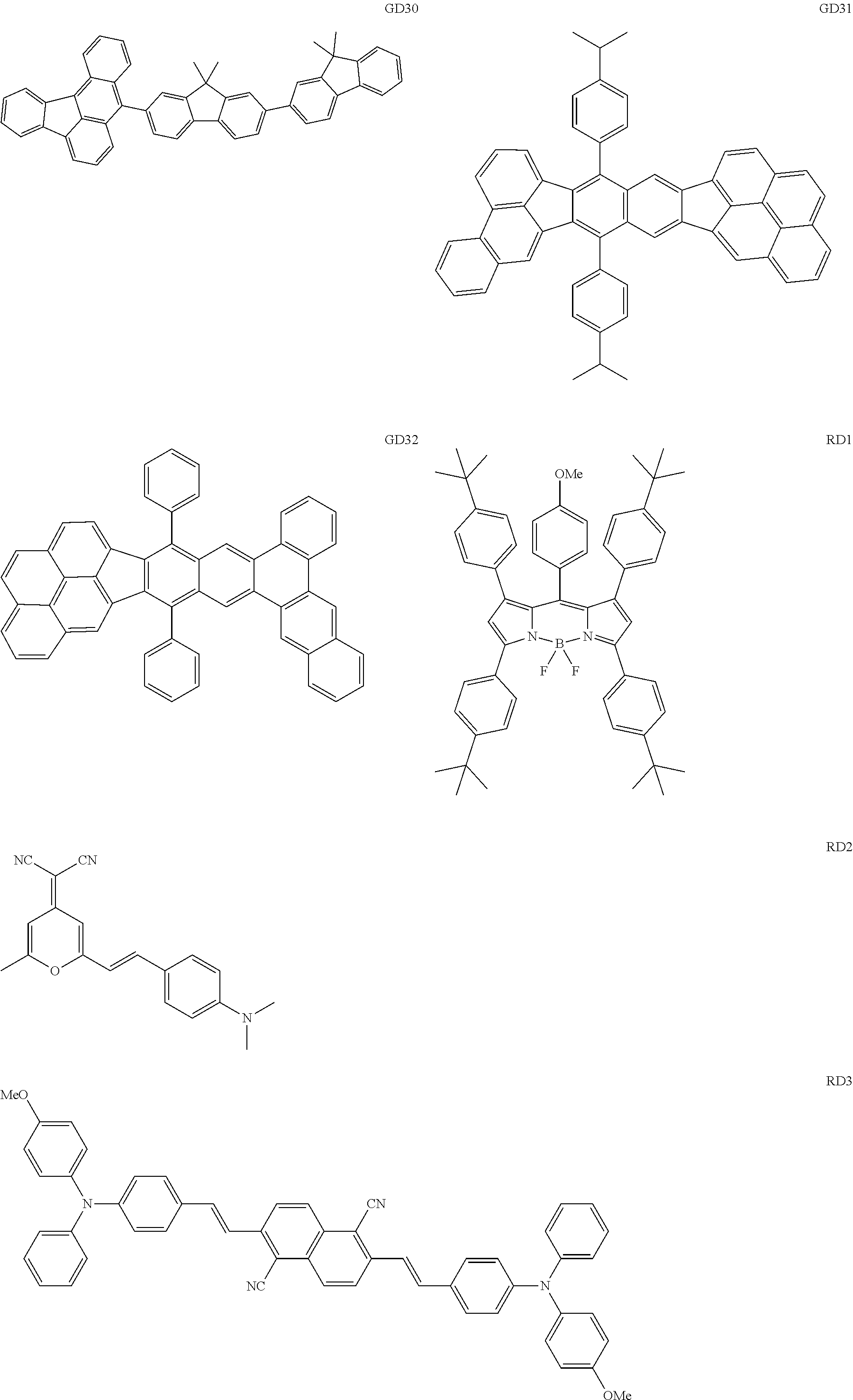

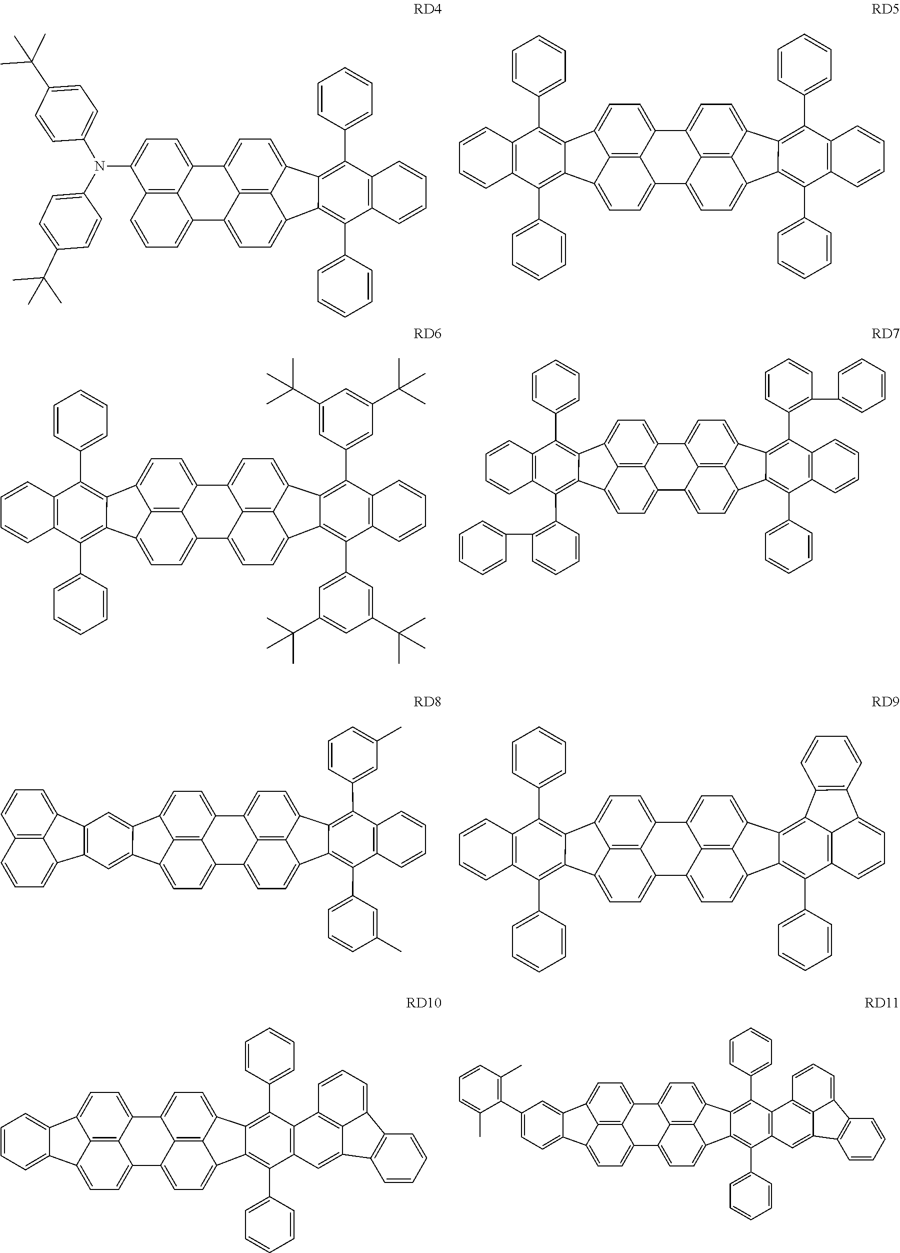

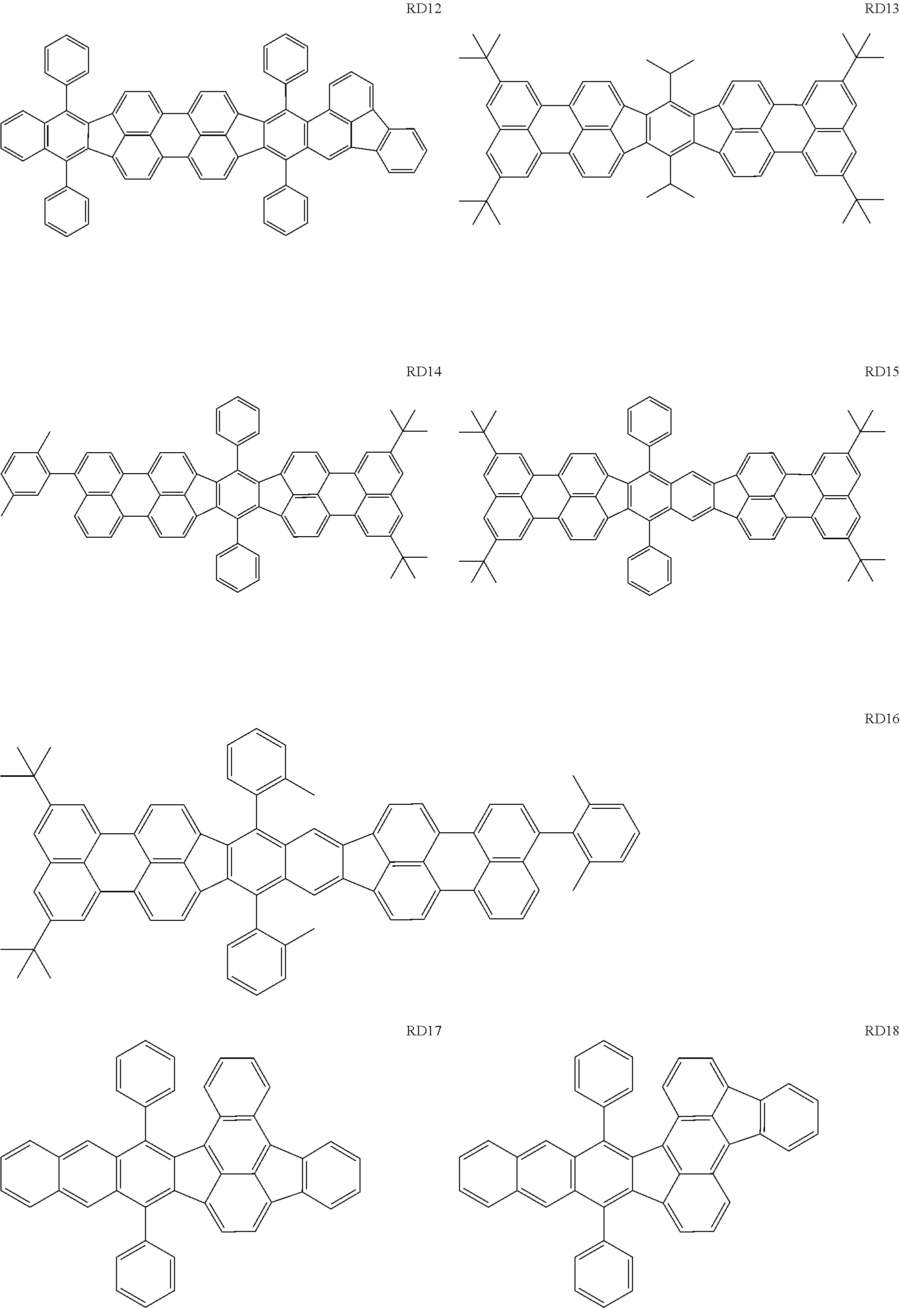

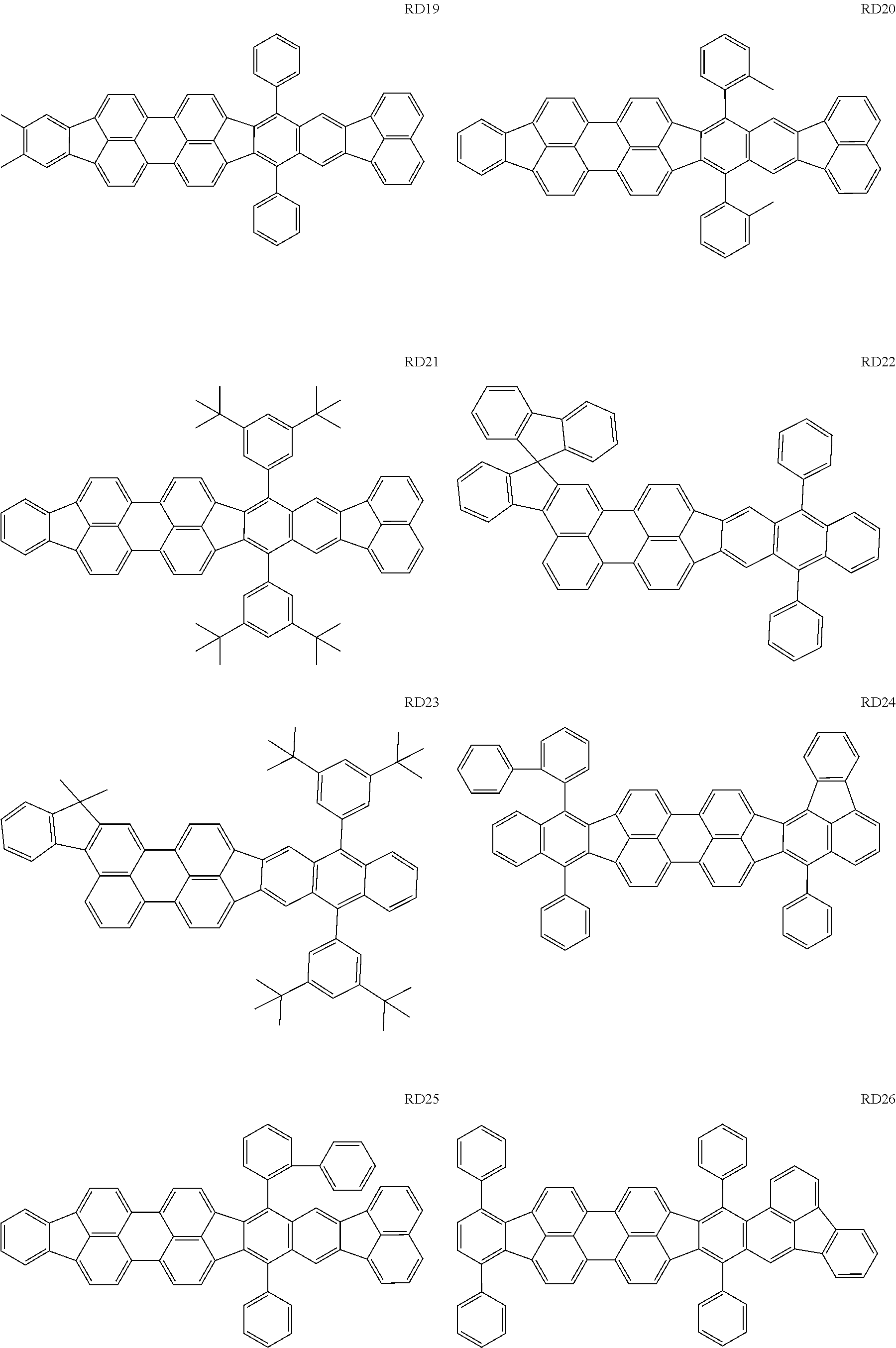

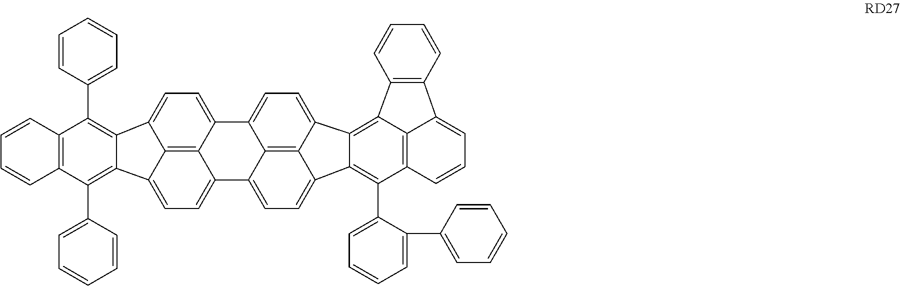 [SMILES: c1ccc(-c2ccccc2-c2c3cccc4c5ccccc5c(c34)c3c4ccc5c6ccc7c8c(ccc(c9ccc(c23)c4c95)c86)-c2c-7c(-c3ccccc3)c3ccccc3c2-c2ccccc2)cc1]

Among the fluorescent materials, exemplified compounds belonging to group BD are blue light-emitting materials. Among these, BD10 to BD33 are compounds each having a fluoranthene skeleton. Thus, these are compounds that can be used in the embodiment of the disclosure.

Among the fluorescent materials, the exemplified compounds belonging to group GD are green light-emitting materials. Among these, GD8 to GD32 are compounds each having a fluoranthene skeleton. Thus, these are compounds that can be used in the embodiment of the disclosure.

Among the fluorescent materials, exemplified compounds belonging to group RD are red light-emitting materials. Among these, RD4 to RD23 are compounds each having a fluoranthene skeleton. Thus, these are compounds that can be used in the embodiment of the disclosure.

### First and Second Organic Compounds

The first and second organic compounds can be materials having at least any one of a pyrene skeleton, an anthracene skeleton, a phenanthrene skeleton, a triphenylene skeleton, and a perylene skeleton, because they have high planarity and can promote carrier transfer between the light-emitting layers. When these organic compounds are used as hosts in combination with the device configuration according to an embodiment, a good carrier balance can be achieved. That is, the use of these organic compounds can provide the organic light-emitting device having superior device durability.

Specific examples of the first and second organic compounds according to the embodiment are illustrated below. However, the disclosure is not limited thereto.

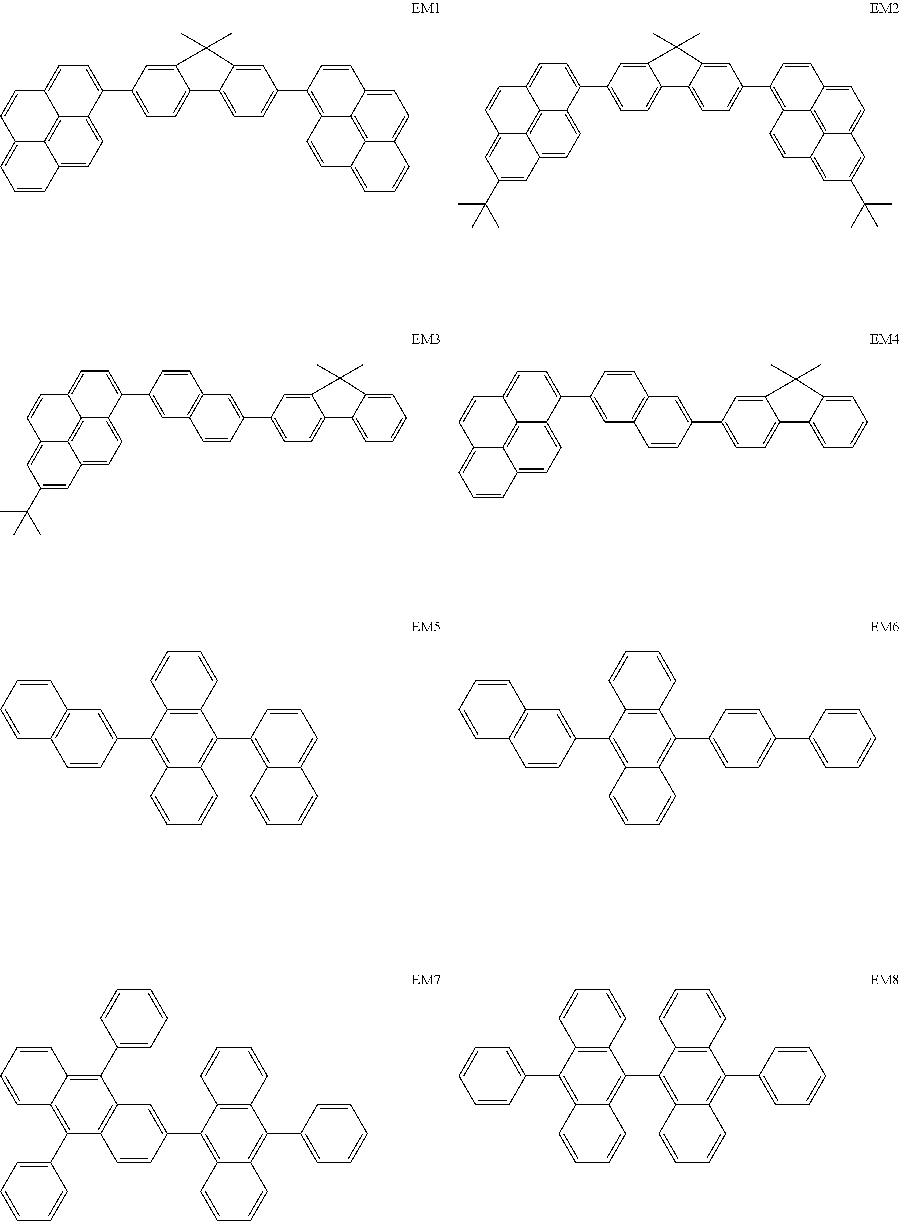

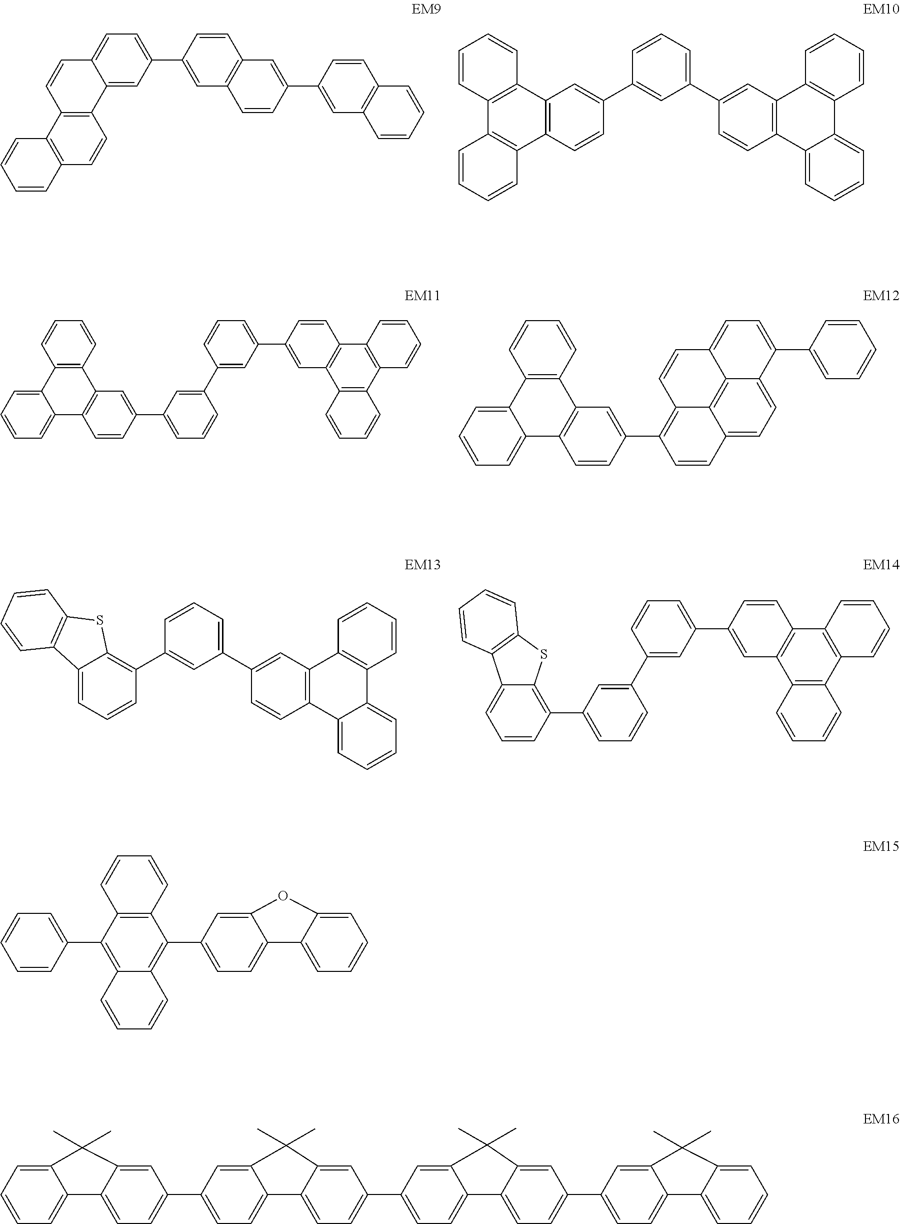

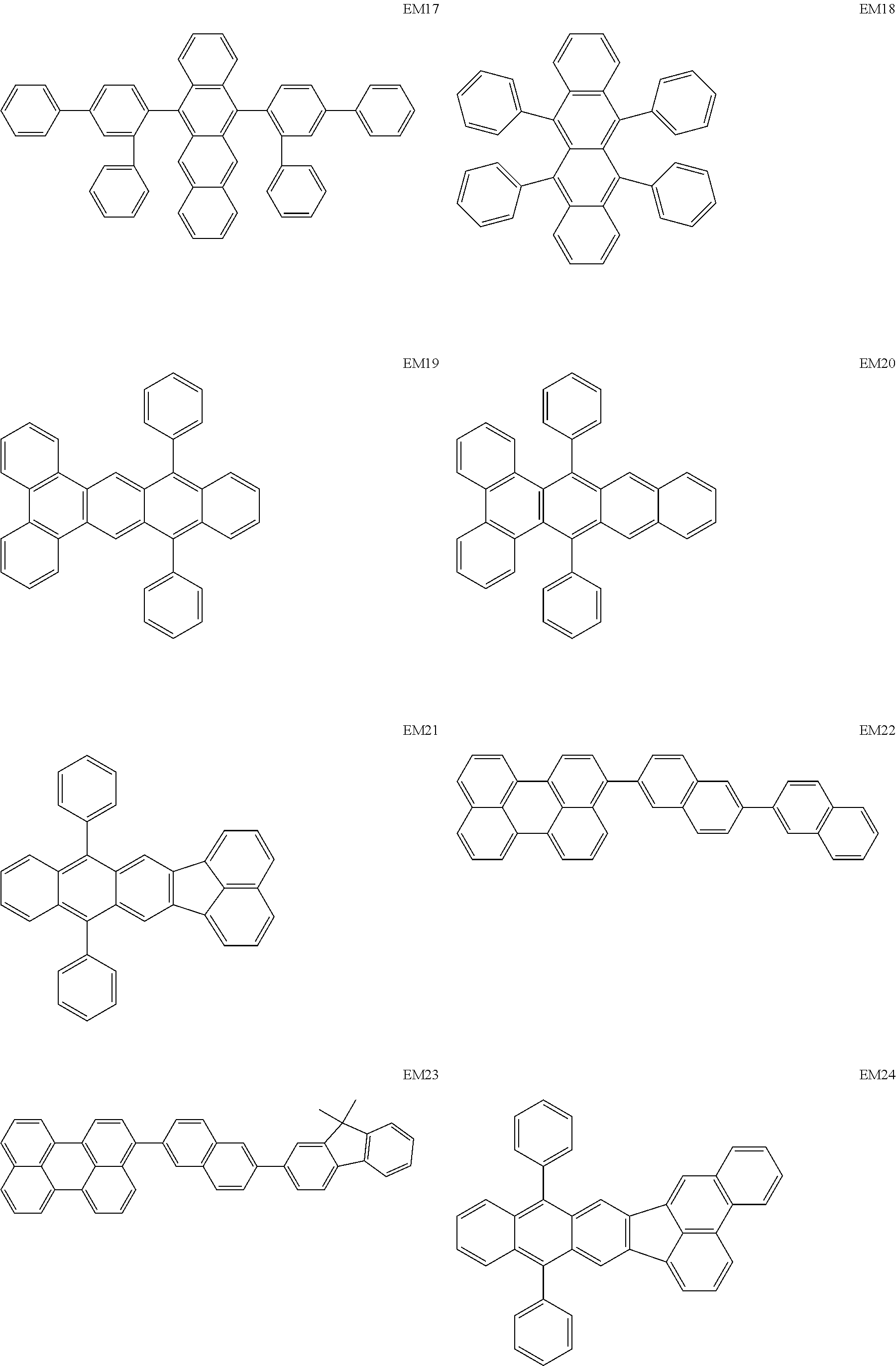

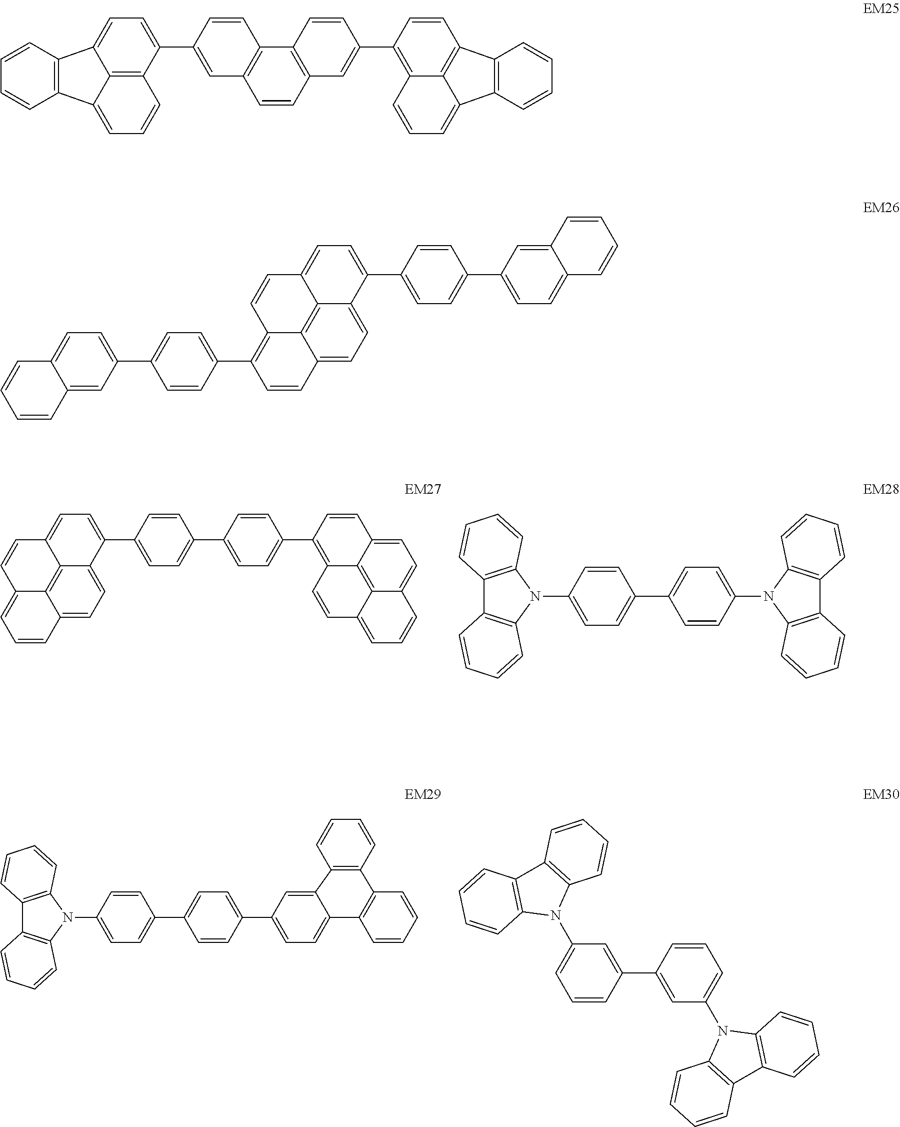

Of the above-described EM1 to EM30, EM1 to EM12 and EM16 to EM27, which are hydrocarbon compounds, can be used from the viewpoint of the above-described bond stability. The use of these compounds as hosts can provide the organic light-emitting device having excellent durability characteristics.

In an embodiment, carbazole derivatives, dibenzofuran derivatives, dibenzothiophene derivatives, organoaluminum complexes, such as tris(8-quinolinolato)aluminum, organoberyllium complexes, and so forth can be used as the first and second organic compounds, in addition to the specific examples described above.

### Assist Material in Second Light-emitting Layer

The second light-emitting layer may contain an assist material. As the assist material, a material having at least any one of a triarylamine skeleton, a carbazole skeleton, an azine ring, an anthraquinone skeleton, a xanthone skeleton, and a thioxanthone skeleton can be used. These materials are excellent in electron-donating property and electron-withdrawing property; thus, HOMO and LUMO are easily adjusted, and injection of carriers from adjacent layers can be promoted. The term “azine ring” is a generic term indicating a six-membered aromatic ring containing nitrogen in the ring, for example, pyridine, pyrimidine, or triazine.

Specific examples of the assist material according to the present embodiment are illustrated below. However, the disclosure is not limited thereto.

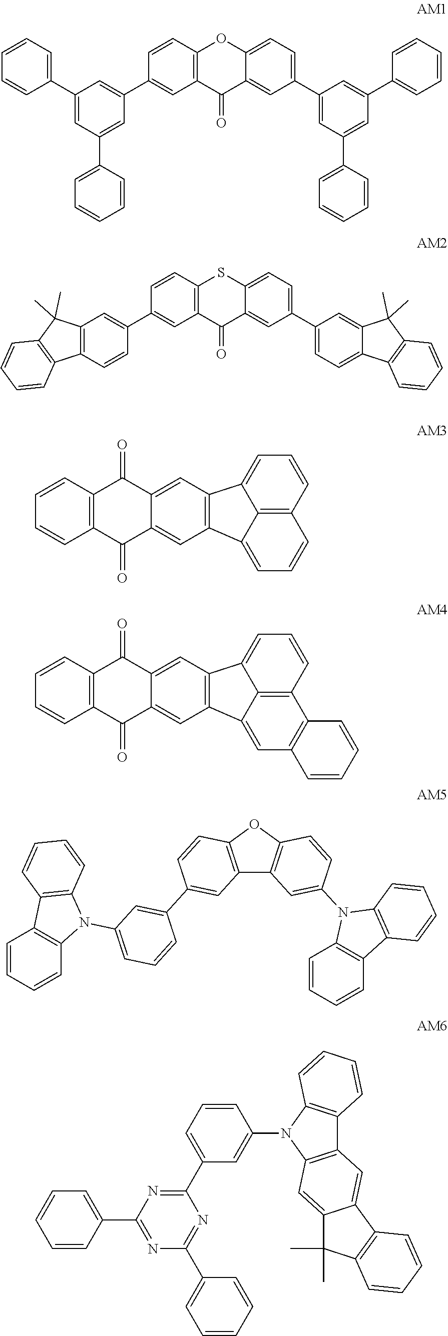 [SMILES: O=c1c2cc(-c3cc(-c4ccccc4)cc(-c4ccccc4)c3)ccc2oc2ccc(-c3cc(-c4ccccc4)cc(-c4ccccc4)c3)cc12 ; CC1(C)c2ccccc2-c2ccc(-c3ccc4sc5ccc(-c6ccc7c(c6)C(C)(C)c6ccccc6-7)cc5c(=O)c4c3)cc21 ; O=C1c2ccccc2C(=O)c2cc3c(cc21)-c1cccc2cccc-3c12 ; O=C1c2ccccc2C(=O)c2cc3c(cc21)-c1cccc2c1c-3cc1ccccc12 ; c1cc(-c2ccc3oc4ccc(-n5c6ccccc6c6ccccc65)cc4c3c2)cc(-n2c3ccccc3c3ccccc32)c1 ; CC1(C)c2ccccc2-c2cc3c4ccccc4n(-c4cccc(-c5nc(-c6ccccc6)nc(-c6ccccc6)n5)c4)c3cc21]

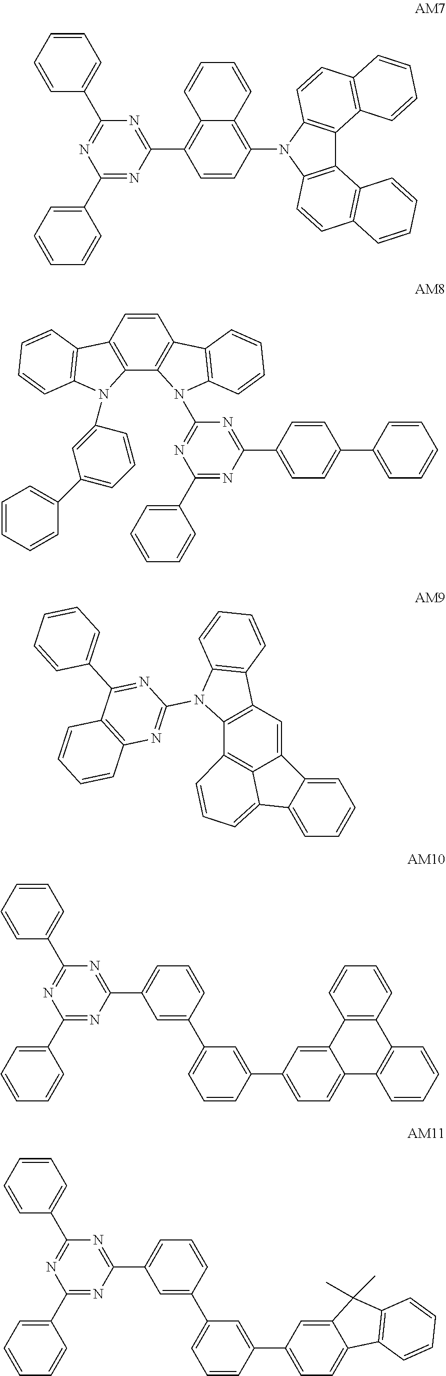 [SMILES: c1ccc(-c2nc(-c3ccccc3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-n4c5ccccc5c5ccc6c7ccccc7n(-c7cccc(-c8ccccc8)c7)c6c54)n3)cc2)cc1 ; c1ccc(-c2nc(-n3c4ccccc4c4cc5c6c(cccc6c43)-c3ccccc3-5)nc3ccccc23)cc1 ; c1ccc(-c2nc(-c3ccccc3)nc(-c3cccc(-c4cccc(-c5ccc6c7ccccc7c7ccccc7c6c5)c4)c3)n2)cc1 ; CC1(C)c2ccccc2-c2ccc(-c3cccc(-c4cccc(-c5nc(-c6ccccc6)nc(-c6ccccc6)n5)c4)c3)cc21]

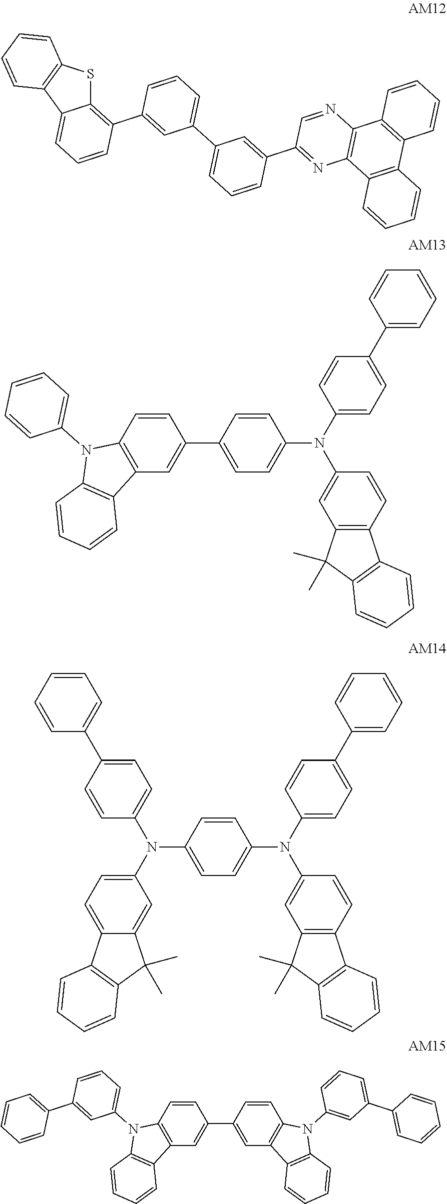

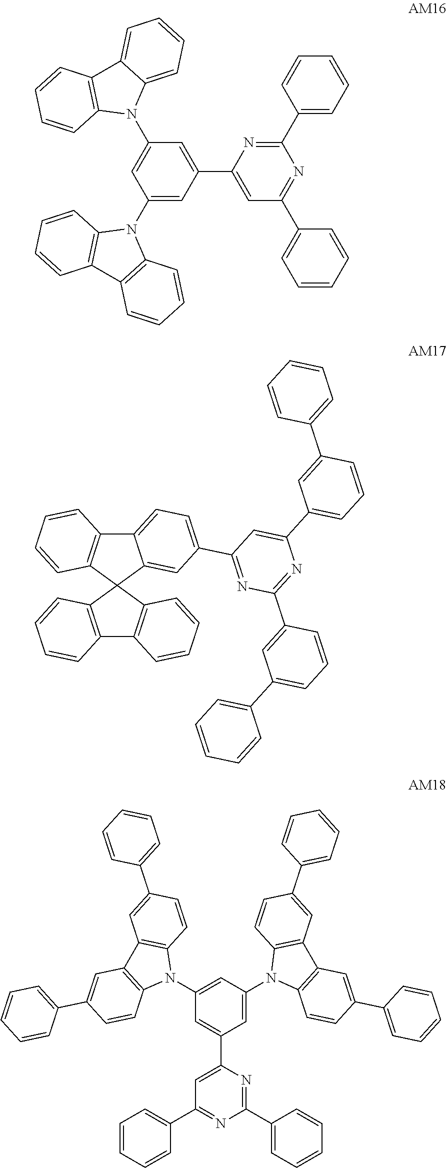 [SMILES: c1ccc(-c2cc(-c3cc(-n4c5ccccc5c5ccccc54)cc(-n4c5ccccc5c5ccccc54)c3)nc(-c3ccccc3)n2)cc1 ; c1ccc(-c2cccc(-c3cc(-c4ccc5c(c4)C4(c6ccccc6-c6ccccc64)c4ccccc4-5)nc(-c4cccc(-c5ccccc5)c4)n3)c2)cc1 ; c1ccc(-c2ccc3c(c2)c2cc(-c4ccccc4)ccc2n3-c2cc(-c3cc(-c4ccccc4)nc(-c4ccccc4)n3)cc(-n3c4ccc(-c5ccccc5)cc4c4cc(-c5ccccc5)ccc43)c2)cc1]

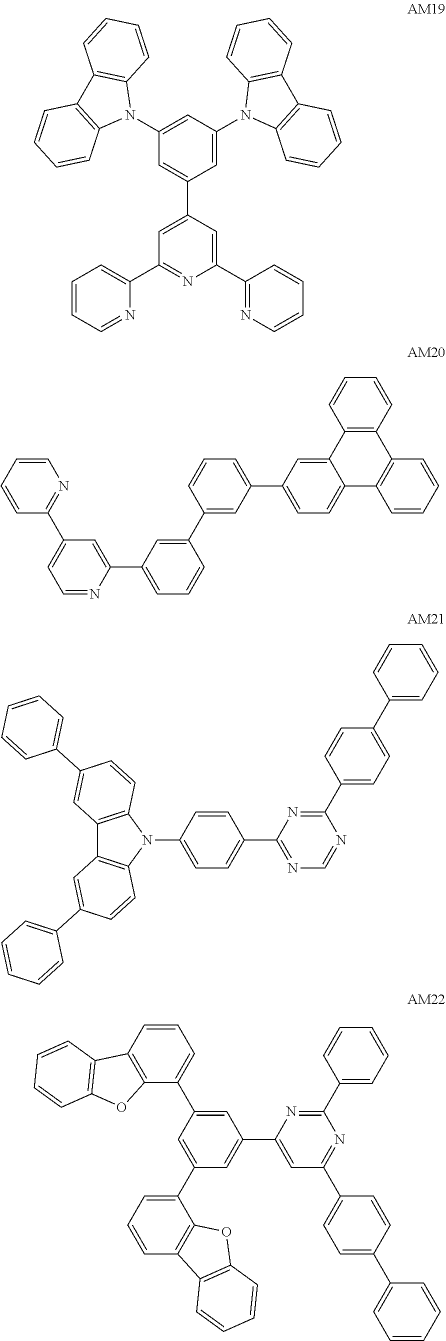 [SMILES: c1ccc(-c2cc(-c3cc(-n4c5ccccc5c5ccccc54)cc(-n4c5ccccc5c5ccccc54)c3)cc(-c3ccccn3)n2)nc1 ; c1ccc(-c2ccnc(-c3cccc(-c4cccc(-c5ccc6c7ccccc7c7ccccc7c6c5)c4)c3)c2)nc1 ; c1ccc(-c2ccc(-c3ncnc(-c4ccc(-n5c6ccc(-c7ccccc7)cc6c6cc(-c7ccccc7)ccc65)cc4)n3)cc2)cc1 ; c1ccc(-c2ccc(-c3cc(-c4cc(-c5cccc6c5oc5ccccc56)cc(-c5cccc6c5oc5ccccc56)c4)nc(-c4ccccc4)n3)cc2)cc1]

Among these, a material having any one of an azine ring, an anthraquinone skeleton, a xanthone skeleton, and a thioxanthone skeleton can be used because the material has a deep LUMO level (far from the vacuum level) owing to its excellent electron-withdrawing property, and can have improved durability characteristics owing to its excellent oxidation stability.

### Other Compounds

Examples of other compounds that can be used in the organic light-emitting device according to the present embodiment are given below.

### Hole Injection-Transport Material

As a hole injection-transport material that can be used for a hole injection layer or the hole transport layer, a material having high hole mobility can be used so as to facilitate the injection of holes from the anode and to transport the injected holes to the light-emitting layers. In addition, a material having a high glass transition temperature can be used in order to inhibit a deterioration in film quality, for example, crystallization, in the organic light-emitting device. Examples of low- or high-molecular-weight materials having the ability to inject and transport holes include triarylamine derivatives, aryl carbazole derivatives, phenylenediamine derivatives, stilbene derivatives, phthalocyanine derivatives, porphyrin derivatives, poly(vinyl carbazole), polythiophene, and other conductive polymers. Moreover, the hole injection-transport material can also be used for an electron-blocking layer.

Non-limiting specific examples of a compound used as the hole injection-transport material will be illustrated below.

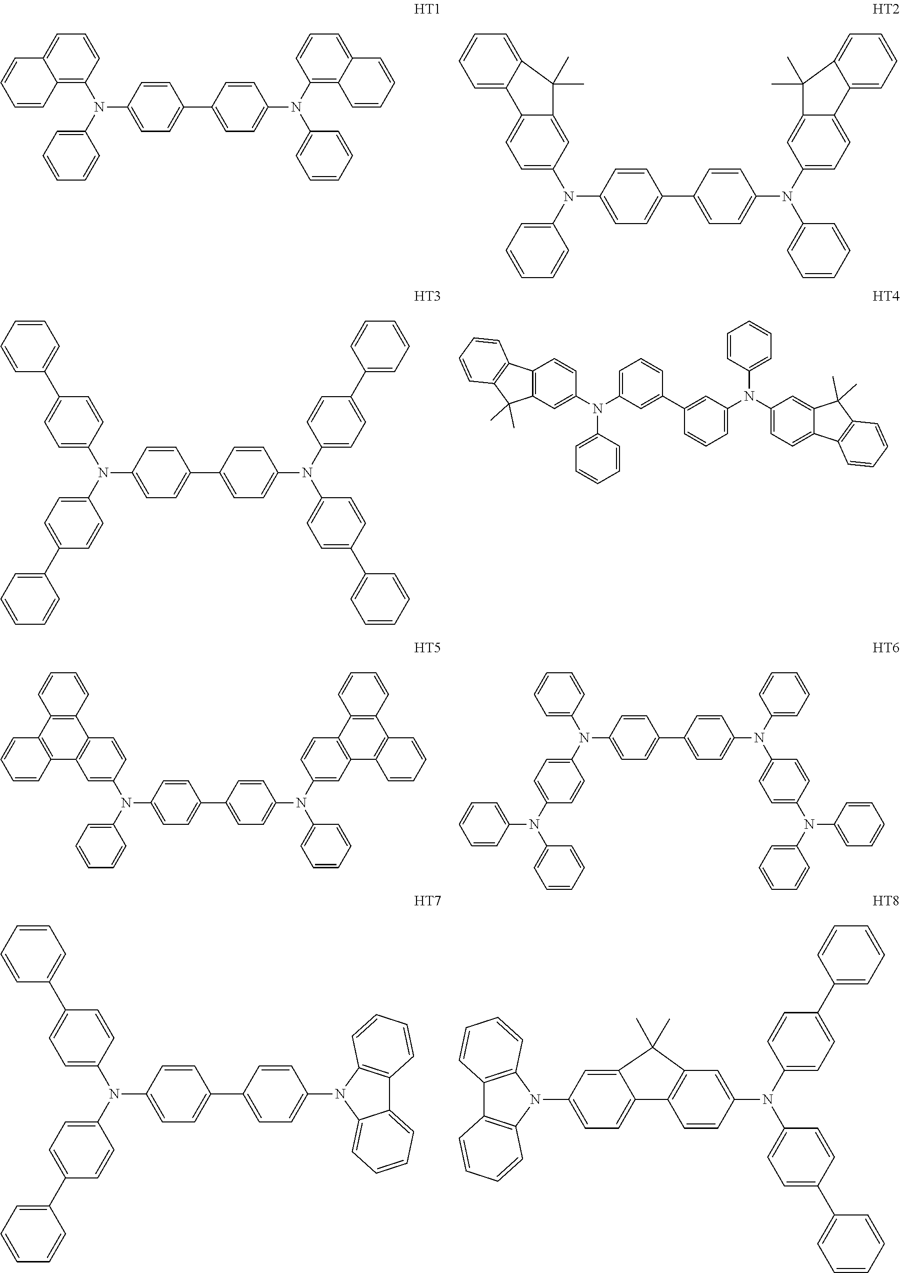

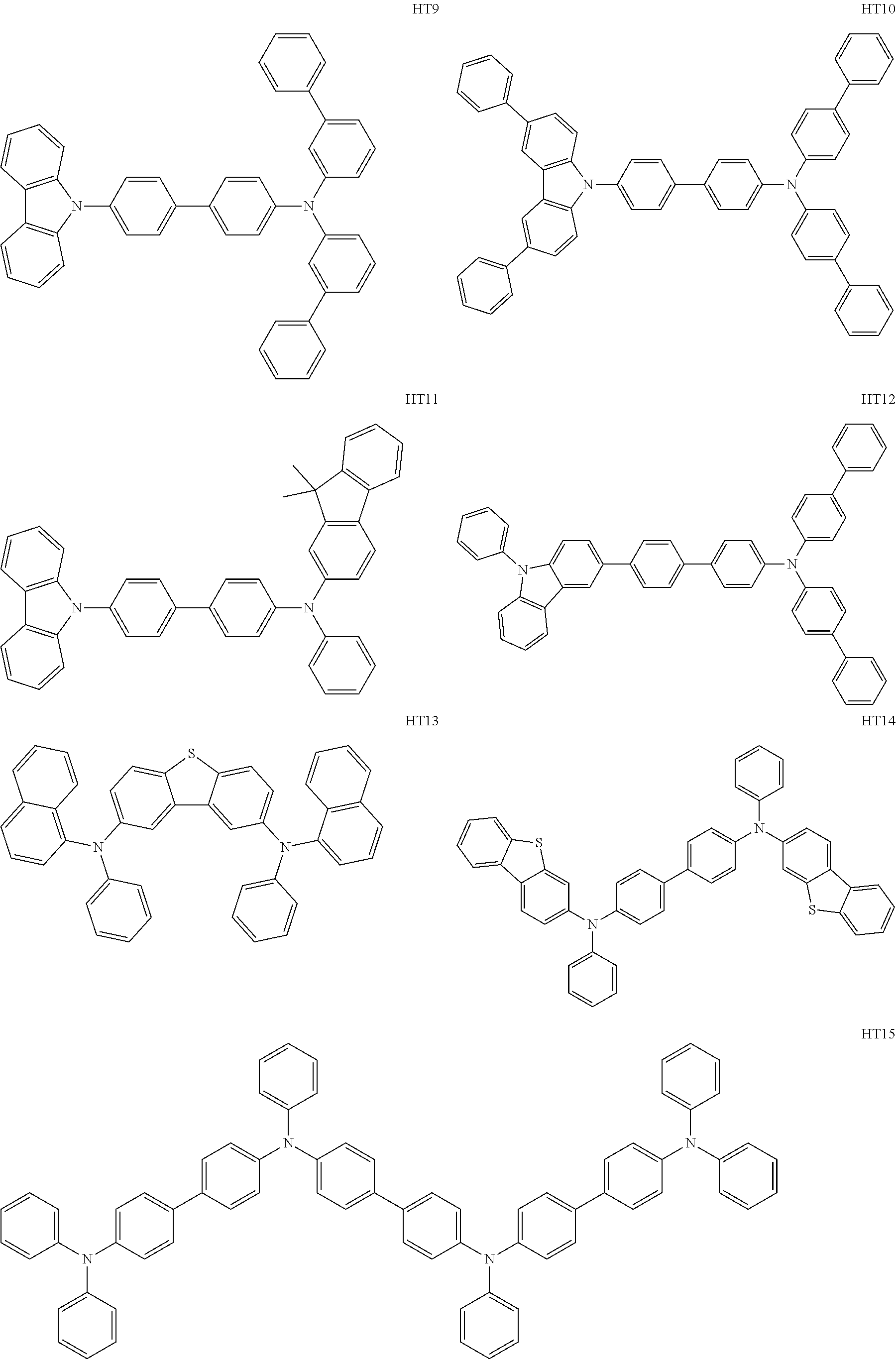

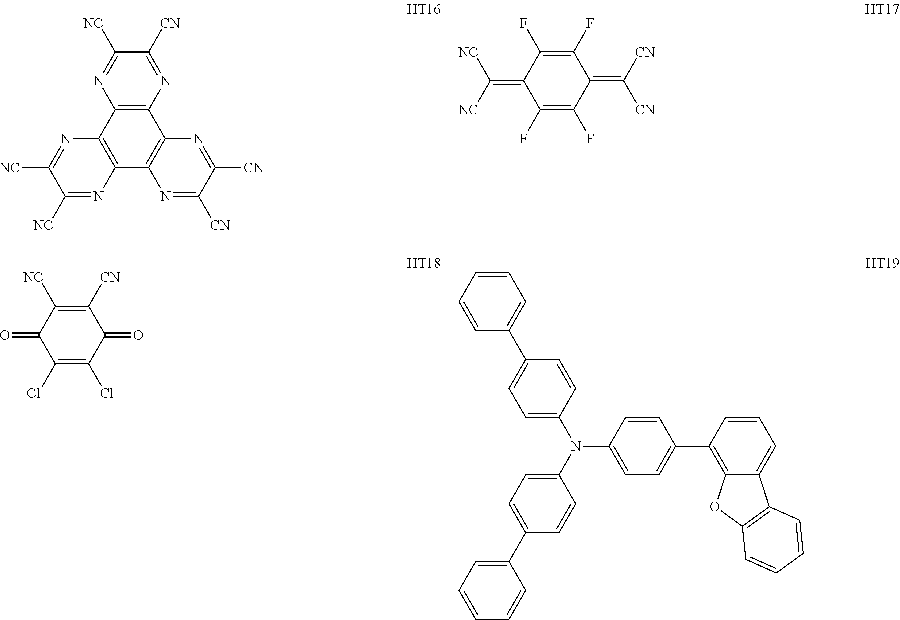 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F ; N#CC1=C(C#N)C(=O)C(Cl)=C(Cl)C1=O ; c1ccc(-c2ccc(N(c3ccc(-c4ccccc4)cc3)c3ccc(-c4cccc5c4oc4ccccc45)cc3)cc2)cc1]

### Electron Transport Material

The electron transport material can be freely-selected from materials capable of transporting electrons injected from the cathode to the light-emitting layer and is selected in consideration of, for example, the balance with the hole mobility of the hole transport material. Examples of a material having the ability to transport electrons include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused-ring compounds, such as fluorene derivatives, naphthalene derivatives, chrysene derivatives, and anthracene derivatives. The electron transport materials can be used for the hole-blocking layer.

Non-limiting specific examples of a compound used as the electron transport material will be described below.

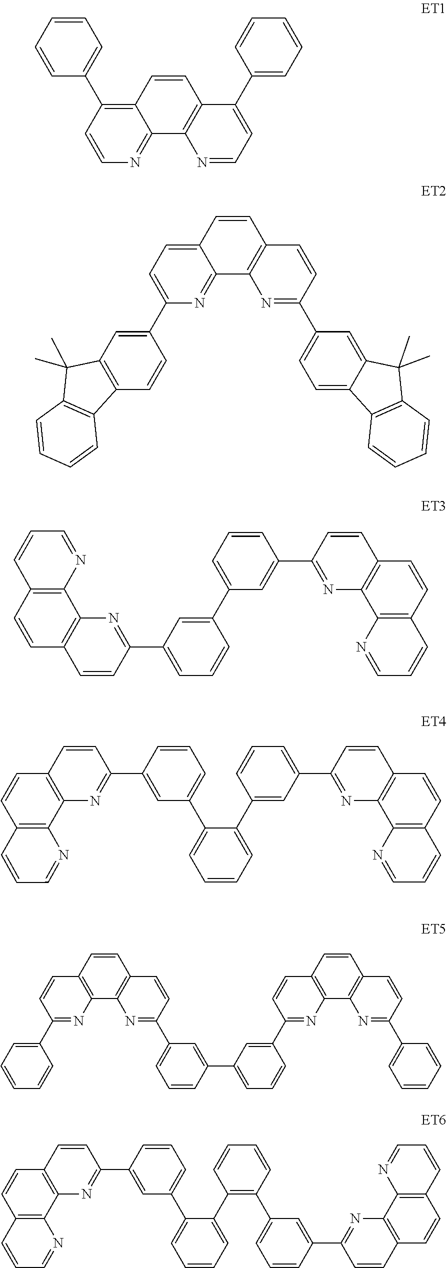

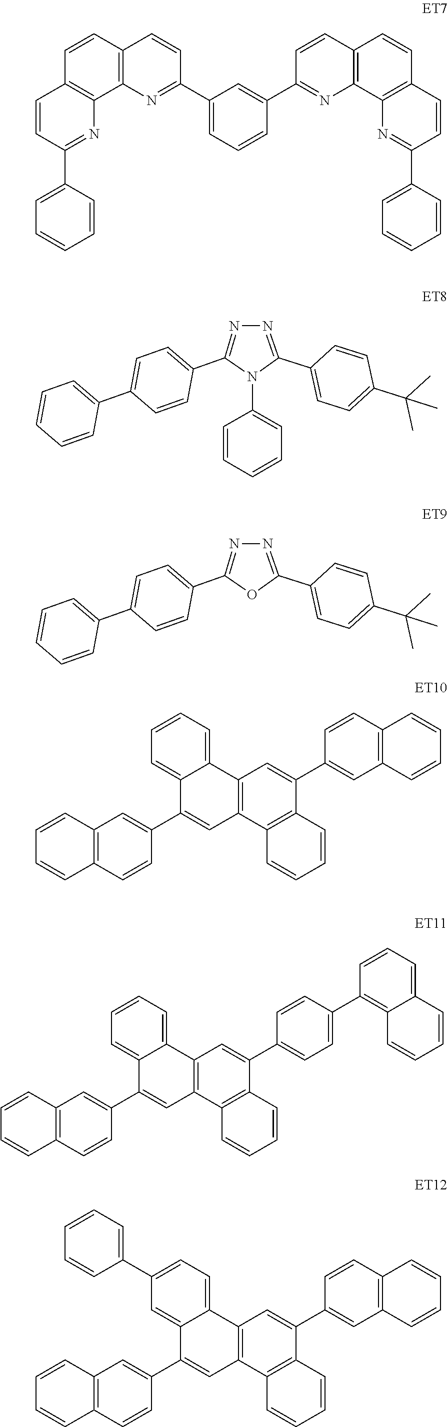

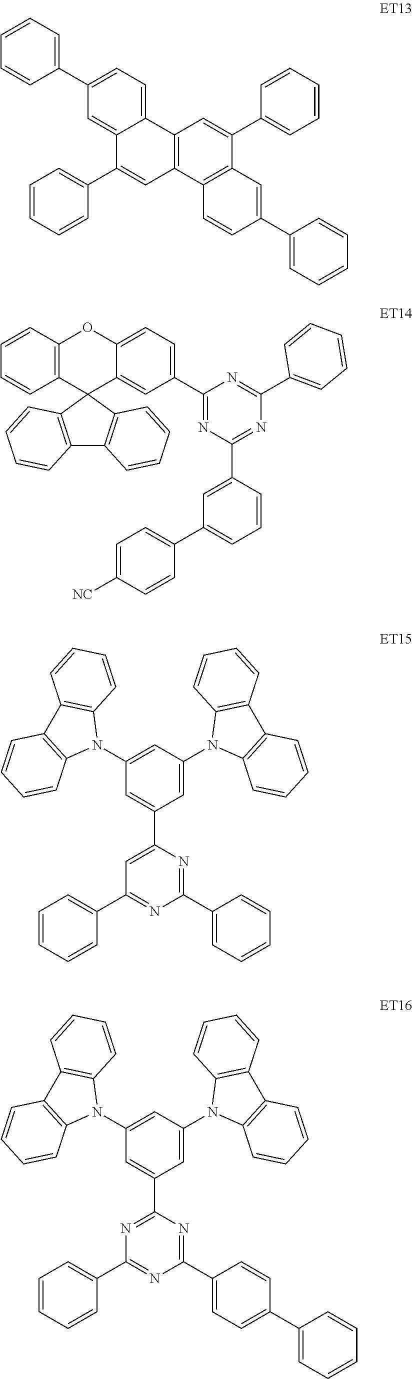

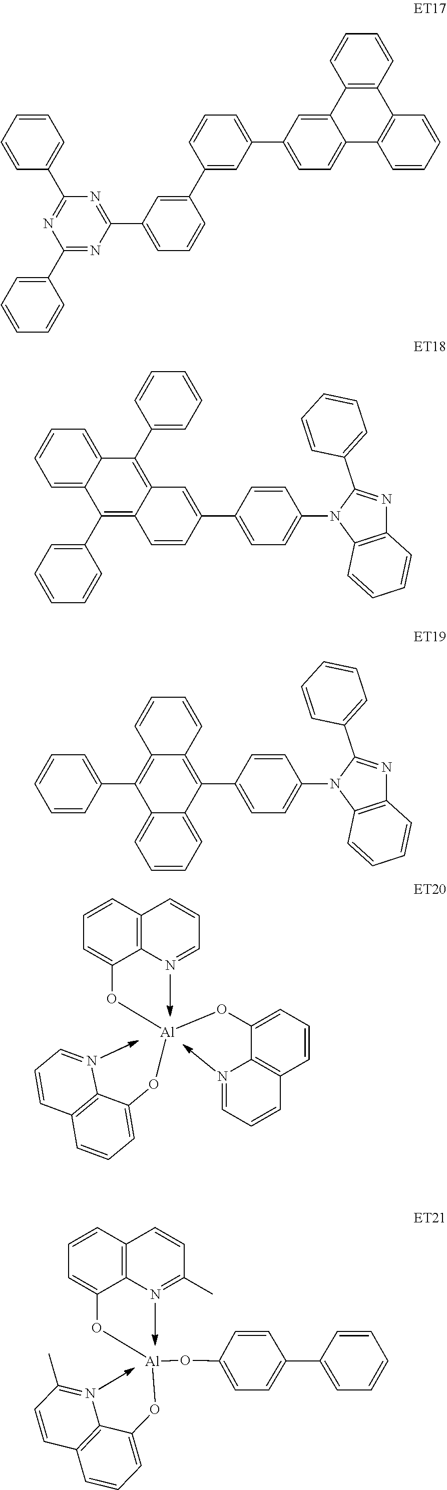

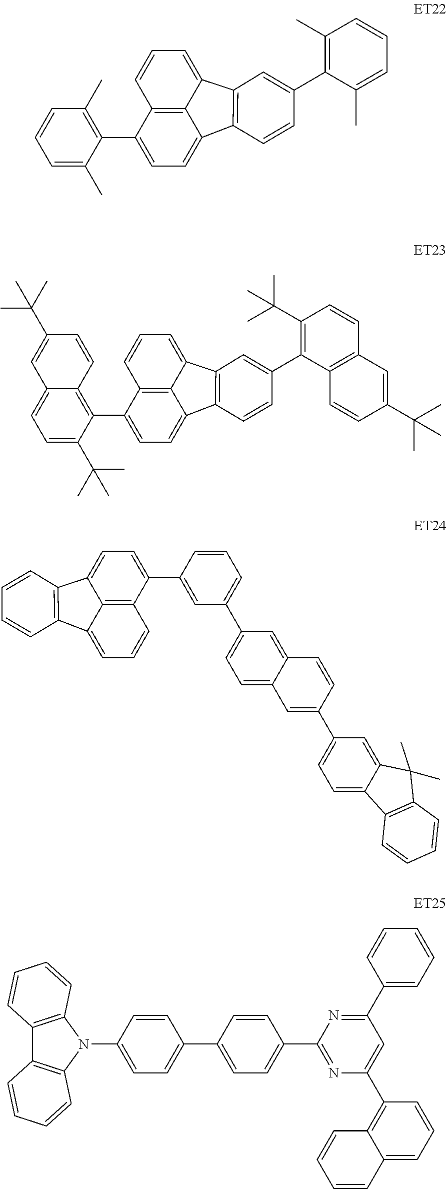

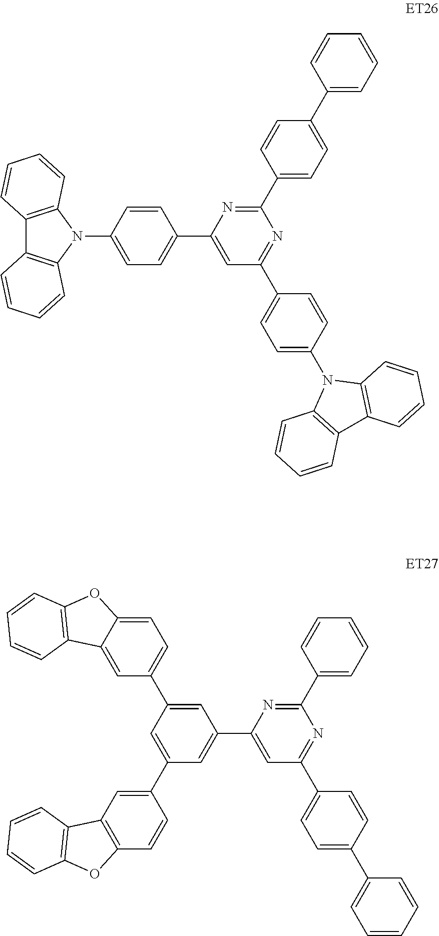 [SMILES: c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

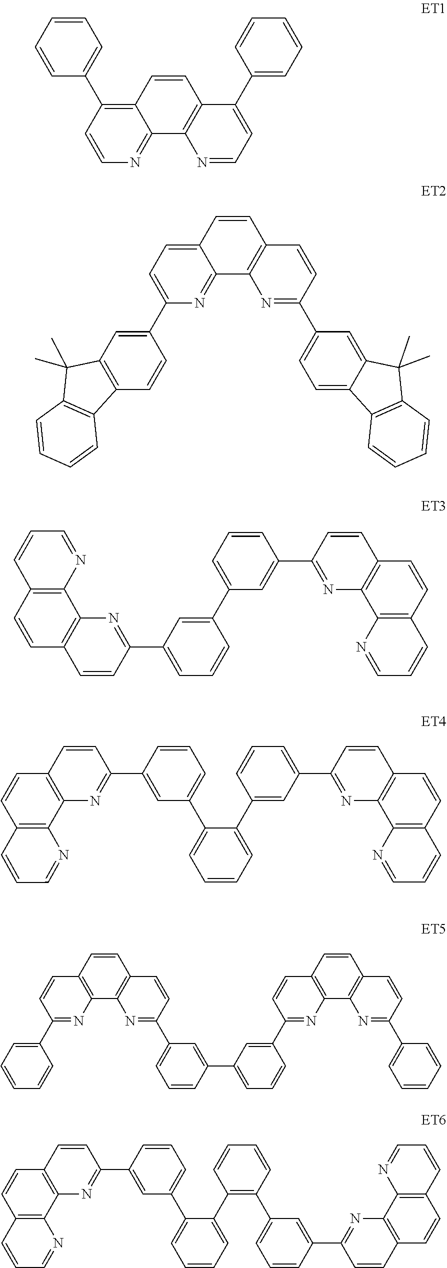

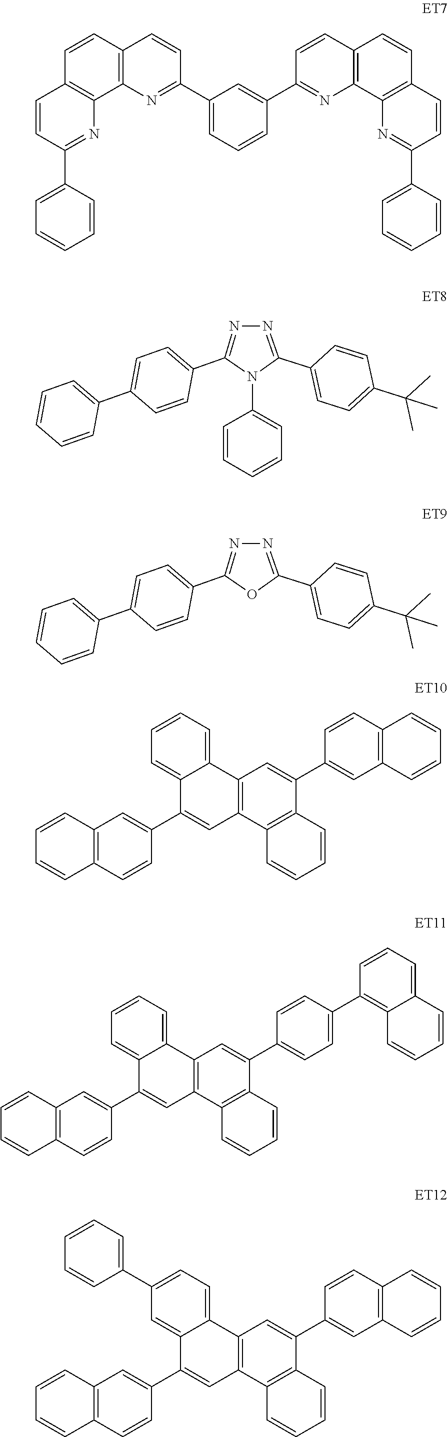

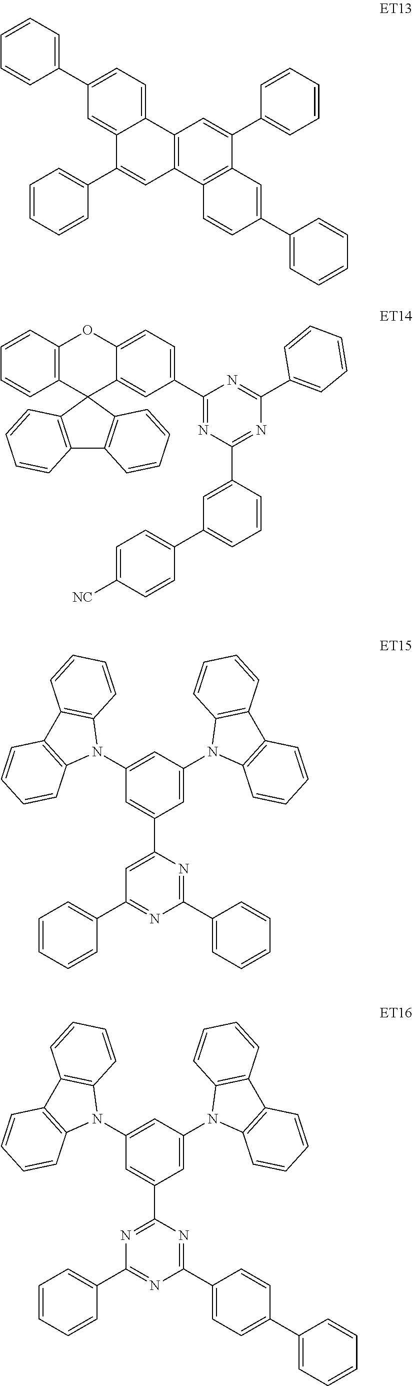

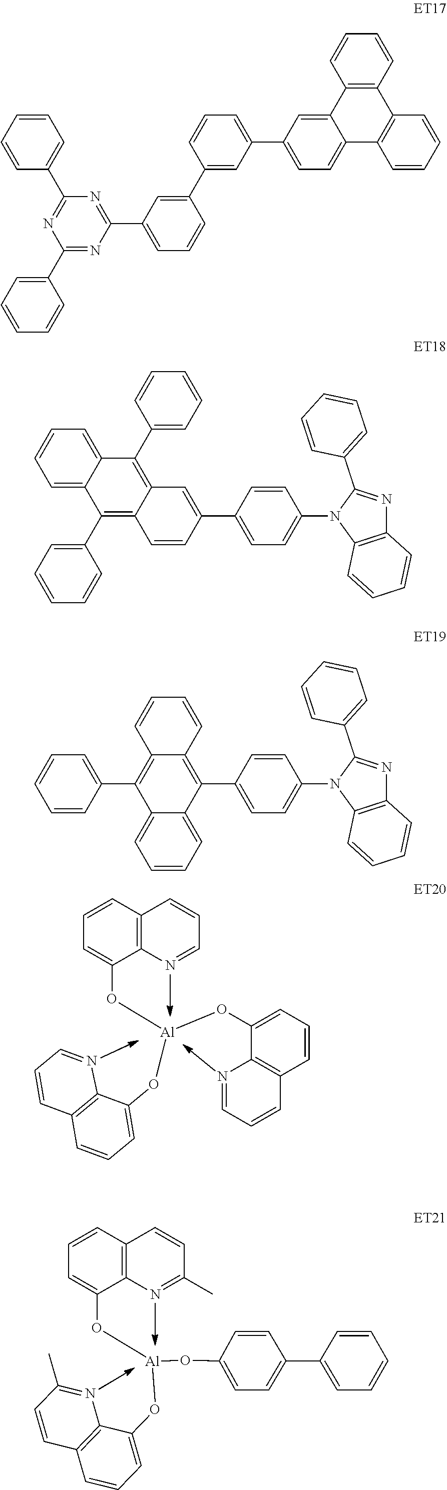

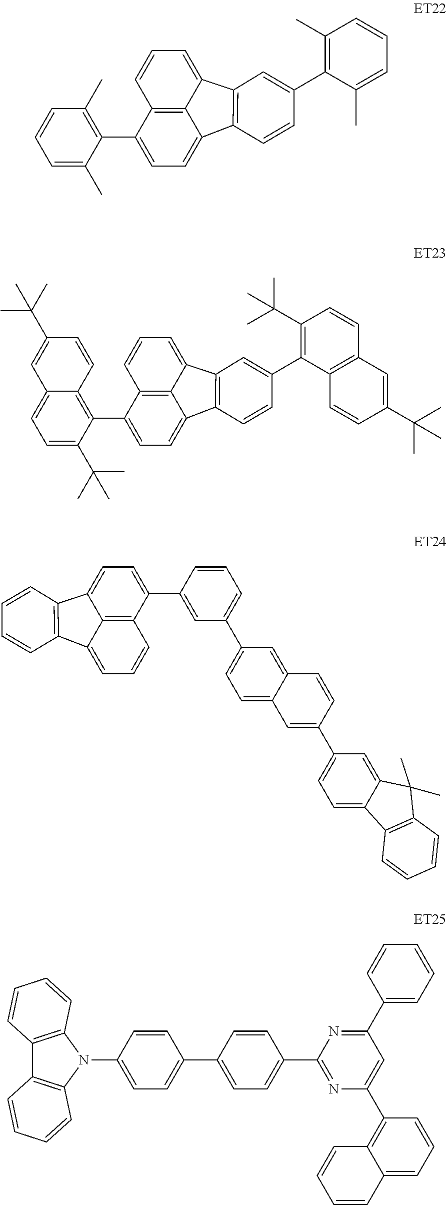

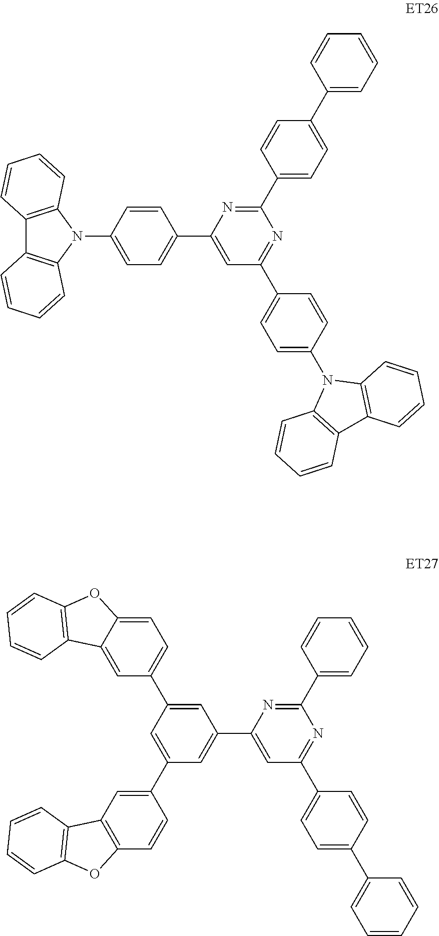 [SMILES: c1ccc(-c2ccc(-c3nc(-c4ccc(-n5c6ccccc6c6ccccc65)cc4)cc(-c4ccc(-n5c6ccccc6c6ccccc65)cc4)n3)cc2)cc1 ; c1ccc(-c2ccc(-c3cc(-c4cc(-c5ccc6oc7ccccc7c6c5)cc(-c5ccc6oc7ccccc7c6c5)c4)nc(-c4ccccc4)n3)cc2)cc1]

### Configuration of Organic Light-Emitting Device

Constituent members, other than the organic compound layers, constituting the organic light-emitting device according to the present embodiment will be described below.

The organic light-emitting device includes an insulating layer, a first electrode, an organic compound layer, a second electrode over a substrate. A protective layer, a color filter, a microlens, and so forth may be disposed over the second electrode. In the case of disposing the color filter, a planarization layer may be disposed between the protective layer and the color filter. The planarization layer can be composed of, for example, an acrylic resin. The same applies when a planarization layer is provided between the color filter and the microlens.

### Substrate

Examples of the substrate include silicon wafers, quartz substrates, glass substrates, resin substrates, and metal substrates. The substrate may include a switching element, such as a transistor, a line, and an insulating layer thereon. Any material can be used for the insulating layer as long as a contact hole can be formed in such a manner that a line can be coupled to the first electrode and as long as insulation with a non-connected line can be ensured. For example, a resin, such as polyimide, silicon oxide, or silicon nitride, can be used.

### Electrode

One of the first and second electrodes is an anode and the other is a cathode. When an electric field is applied in the direction in which the organic light-emitting device emits light, the electrode with the higher potential is the anode, and the other is the cathode. It can also be said that the electrode that supplies holes to the light-emitting layer is the anode and that the electrode that supplies electrons is the cathode.

As the component material of the anode, a material having a work function as high as possible can be used. Examples of the material that can be used include elemental metals, such as gold, platinum, silver, copper, nickel, palladium, cobalt, selenium, vanadium, and tungsten, mixtures thereof, alloys of combinations thereof, and metal oxides, such as tin oxide, zinc oxide, indium oxide, indium-tin oxide (ITO), and indium-zinc oxide. Additionally, conductive polymers, such as polyaniline, polypyrrole, and polythiophene, can be used.

These electrode materials may be used alone or in combination of two or more. The anode may be formed of a single layer or a plurality of layers.

When the anode is used as a reflective electrode, for example, chromium, aluminum, silver, titanium, tungsten, molybdenum, an alloy thereof, or a stack thereof can be used. These materials can also be used to act as a reflective film that does not have the role of an electrode. When the anode is used as a transparent electrode, a transparent conductive oxide layer composed of, for example, indium-tin oxide (ITO) or indium-zinc oxide can be used; however, the anode is not limited thereto.

The electrode can be formed by photolithography.

As the component material of the cathode, a material having a lower work function can be used. Examples thereof include elemental metals such as alkali metals, e.g., lithium, alkaline-earth metals, e.g., calcium, aluminum, titanium, manganese, silver, lead, and chromium, and mixtures thereof. Alloys of combinations of these elemental metals can also be used. For example, magnesium-silver, aluminum-lithium, aluminum-magnesium, silver-copper, and zinc-silver can be used. Metal oxides, such as indium-tin oxide (ITO), can also be used. These electrode materials may be used alone or in combination of two or more. The cathode may have a single-layer structure or a multilayer structure. In particular, silver can be used. To reduce the aggregation of silver, a silver alloy can be used. Any alloy ratio may be used as long as the aggregation of silver can be reduced. The ratio of silver to another metal may be, for example, 1:1 or 3:1.

A top emission device may be provided using the cathode formed of a conductive oxide layer composed of, for example, ITO. A bottom emission device may be provided using the cathode formed of a reflective electrode composed of, for example, aluminum (Al). Any type of cathode may be used. Any method for forming the cathode may be employed. For example, a direct-current or alternating-current sputtering technique can be employed because good film coverage is obtained and thus the resistance is easily reduced.

### Organic Compound Layer

The organic compound layers include at least the light-emitting layers, and may include, in addition to the light-emitting layers, the hole injection layer, the hole transport layer, and the electron-blocking layer on the anode side, and the hole-blocking layer, the electron transport layer, an electron injection layer, and the like on the cathode side, which are appropriately selected as necessary. In the present embodiment, the light-emitting layers include the first light-emitting layer and the second light-emitting layer, the first light-emitting layer and the second light-emitting layer being in contact with each other. The organic compound layers are mainly composed of an organic compound, and may contain inorganic atoms and an inorganic compound. For example, the organic compound layers may contain, for example, copper, lithium, magnesium, aluminum, iridium, platinum, molybdenum, or zinc.

For the organic compound layer included in the organic light-emitting device according to an embodiment, a dry process, such as a vacuum evaporation method, an ionized evaporation method, sputtering, or plasma, may be employed. Alternatively, instead of the dry process, it is also possible to employ a wet process in which a material is dissolved in an appropriate solvent and then a film is formed by a known coating method, such as spin coating, dipping, a casting method, a Langmuir-Blodgett (LB) technique, or an ink jet method.

When the layer is formed by, for example, the vacuum evaporation method or the solution coating method, crystallization and so forth are less likely to occur, and good stability with time is obtained. In the case of forming a film by the coating method, the film may be formed in combination with an appropriate binder resin.

Non-limiting examples of the binder resin include poly(vinyl carbazole) resins, polycarbonate resins, polyester resins, acrylonitrile butadiene styrene (ABS) resins, acrylic resins, polyimide resins, phenolic resins, epoxy resins, silicone resins, and urea resins.

These binder resins may be used alone as a homopolymer or copolymer or in combination as a mixture of two or more. Furthermore, additives, such as a known plasticizer, antioxidant, and ultraviolet absorber, may be used, as needed.

### Protective Layer

A protective layer may be disposed on one of the electrodes. For example, a glass member provided with a moisture absorbent can be bonded to the second electrode to reduce the entry of, for example, water into the organic compound layer, thereby reducing the occurrence of display defects. In another embodiment, a passivation film composed of, for example, silicon nitride may be disposed on the second electrode to reduce the entry of, for example, water into the organic compound layer. For example, after the formation of the second electrode, the substrate may be transported to another chamber without breaking the vacuum, and a silicon nitride film having a thickness of 2 μm may be formed by a chemical vapor deposition (CVD) method to provide a protective layer. After the film deposition by the CVD method, a protective layer may be formed by an atomic layer deposition (ALD) method. Non-limiting examples of the material of the layer formed by the ALD method may include silicon nitride, silicon oxide, and aluminum oxide. Silicon nitride may be deposited by the CVD method on the layer formed by the ALD method. The film formed by the ALD method may have a smaller thickness than the film formed by the CVD method. Specifically, the thickness may be 50% or less, even 10% or less.

### Color Filter

A color filter may be disposed on the protective layer. For example, a color filter may be disposed on another substrate in consideration of the size of the organic light-emitting device and bonded to the substrate provided with the organic light-emitting device. A color filter may be formed by patterning on the protective layer using photolithography. The color filter may be composed of a polymer.

### Planarization Layer

A planarization layer may be disposed between the color filter and the protective layer. The planarization layer is provided for the purpose of reducing the unevenness of the layer underneath. The planarization layer may be referred to as a “material resin layer” without limiting its purpose. The planarization layer may be composed of an organic compound. A low- or high-molecular-weight organic compound may be used. A high-molecular-weight organic compound can be used.

The planarization layers may be disposed above and below (or on) the color filter and may be composed of the same or different component materials. Specific examples thereof include poly(vinyl carbazole) resins, polycarbonate resins, polyester resins, acrylonitrile butadiene styrene (ABS) resins, acrylic resins, polyimide resins, phenolic resins, epoxy resins, silicone resins, and urea resins.

### Microlens

The organic light-emitting device or a light-emitting apparatus including the organic light-emitting device may include an optical member, such as a microlens, on the outgoing light side. The microlens can be composed of, for example, an acrylic resin or an epoxy resin. The microlens may be used to increase the amount of light emitted from the organic light-emitting device or the organic light-emitting apparatus and to control the direction of the light emitted. The microlens may have a hemispherical shape. In the case of a hemispherical shape, among tangents to the hemisphere, there is a tangent parallel to the insulating layer. The point of contact of the tangent with the hemisphere is the vertex of the microlens. The vertex of the microlens can be determined in the same way for any cross-sectional view. That is, among the tangents to the semicircle of the microlens in the cross-sectional view, there is a tangent parallel to the insulating layer, and the point of contact of the tangent with the semicircle is the vertex of the microlens.

The midpoint of the microlens can be defined. In the cross section of the microlens, when a segment is hypothetically drawn from the point where an arc shape ends to the point where another arc shape ends, the midpoint of the segment can be referred to as the midpoint of the microlens. The cross section to determine the vertex and midpoint may be a cross section perpendicular to the insulating layer.

### Opposite Substrate

An opposite substrate may be disposed on the planarization layer. The opposite substrate is disposed at a position corresponding to the substrate described above and thus is called an opposite substrate. The opposite substrate may be composed of the same material as the substrate described above. When the above-described substrate is referred to as a first substrate, the opposite substrate may be referred to as a second substrate.

### Pixel Circuit

The light-emitting apparatus including organic light-emitting devices may include pixel circuits coupled to the organic light-emitting devices. Each of the pixel circuits may be of an active matrix type that independently controls light emission from a plurality of organic light-emitting devices. The active matrix type circuit may be voltage programming or current programming. A driving circuit includes the pixel circuit for each pixel. The pixel circuit may include the organic light-emitting device, a transistor to control the luminance of the organic light-emitting device, a transistor to control the timing of the light emission, a capacitor to retain the gate voltage of the transistor to control the luminance, and a transistor to connect to GND without using the light-emitting device.

The light-emitting apparatus includes a display area and a peripheral area disposed around the display area. The display area includes a pixel circuit, and the peripheral area includes a display control circuit. The mobility of a transistor contained in the pixel circuit may be lower than the mobility of a transistor contained in the display control circuit. The gradient of the current-voltage characteristics of the transistor contained in the pixel circuit may be smaller than the gradient of the current-voltage characteristic of the transistor contained in the display control circuit. The gradient of the current-voltage characteristics can be measured by what is called Vg-Ig characteristics. The transistor contained in the pixel circuit is a transistor coupled to the organic light-emitting device.

### Pixel

A light-emitting apparatus including an organic light-emitting device may include plurality of pixels. Each pixel includes subpixels configured to emit colors different from each other. The subpixels may have respective red, green, and blue (RGB) emission colors.

Light emerges from a region of the pixel, also called a pixel aperture. This region is the same as a first region. The pixel aperture may be 15 μm or less, and may be 5 μm or more. More specifically, the pixel aperture may be, for example, 11 μm, 9.5 μm, 7.4 μm, or 6.4 μm. The distance between subpixels may be 10 μm or less. Specifically, the distance may be 8 μm, 7.4 μm, or 6.4 μm.

The pixels may be arranged in a known pattern in plan view. For example, a stripe pattern, a delta pattern, a Pen Tile matrix pattern, or the Bayer pattern may be used. The shape of each subpixel in plan view may be any known shape. Examples of the shape of the subpixel include quadrilaterals, such as rectangles and rhombi, and hexagons. Of course, if the shape is close to a rectangle, rather than an exact shape, it is included in the rectangle. The shape of the subpixel and the pixel arrangement can be used in combination.

### Application of Organic Light-Emitting Device

The organic light-emitting device according to the present embodiment can be used as a component member of a display apparatus or lighting apparatus. Other applications include exposure light sources for electrophotographic image-forming apparatuses, backlights for liquid crystal displays, and light-emitting apparatuses including white-light sources and color filters.

The display apparatus may be an image information-processing unit having an image input unit that receives image information from an area or linear CCD sensor, a memory card, or any other source, an information-processing unit that processes the input information, and a display unit that displays the input image. The display apparatus includes plurality of pixels, and at least one of the plurality of pixels may include the organic light-emitting device according to the present embodiment and a transistor coupled to the organic light-emitting device.

The display unit of an image pickup apparatus or an inkjet printer may have a touch panel function. The driving mode of the touch panel function may be, but is not particularly limited to, an infrared mode, an electrostatic capacitance mode, a resistive film mode, or an electromagnetic inductive mode. The display apparatus may also be used for a display unit of a multifunction printer.

The following describes a display apparatus according to the present embodiment with reference to the attached drawings.

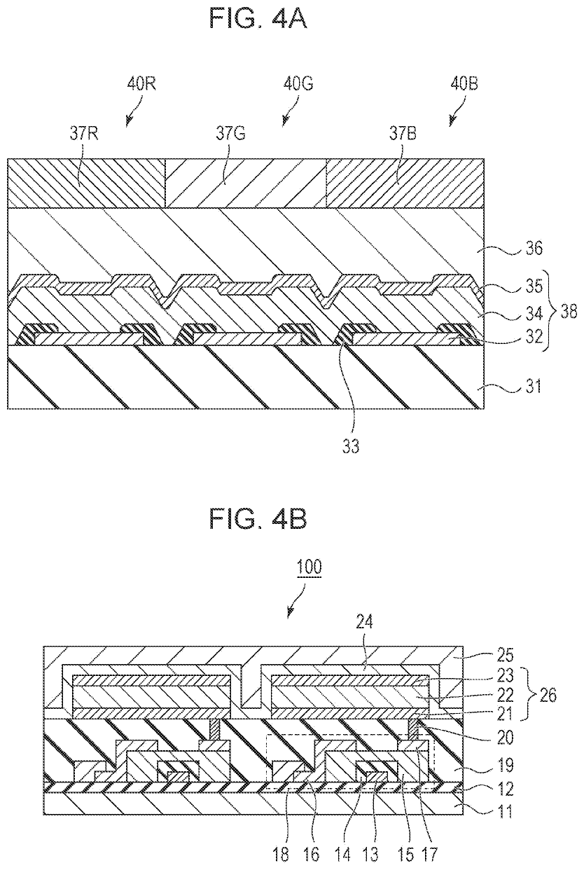

FIG. 4A is an example of pixels that are components of the display apparatus according to the present embodiment. Each of the pixels includes subpixels 40. The subpixels are separated into 40R, 40G, and 40B according to their light emission. The emission color may be distinguished based on the wavelength of light emitted from the light-emitting layer. Alternatively, light emitted from the subpixels may be selectively transmitted or color-converted with, for example, a color filter. Each subpixels 40 includes a reflective electrode serving as a first electrode 32, an insulating layer 33 covering the edge of the first electrode 32, an organic compound layer 34 covering the first electrode 32 and the insulating layer 33, a transparent electrode serving as a second electrode 35, a protective layer 36, and a color filter 37 over an interlayer insulating layer 31. Reference numeral 38 denotes the organic light-emitting device.

The transistors and capacitive elements may be disposed under or in the interlayer insulating layer 31.

Each transistor may be electrically coupled to a corresponding one of the first electrodes 32 through a contact hole (not illustrated).

The insulating layer 33 is also called a bank or pixel separation film. The insulating layer 33 covers the edge of each first electrode 32 and surrounds the first electrode 32. Portions that are not covered with the insulating layer 33 are in contact with the organic compound layer 34 and serve as light-emitting regions.

The second electrode 35 may be a transparent electrode, a reflective electrode, or a semi-transparent electrode.

The protective layer 36 reduces the penetration of moisture into the organic compound layer 34. Although the protective layer 36 is illustrated as a single layer, the protective layer 36 may be formed of a plurality of layers. Each layer may be an inorganic compound layer or an organic compound layer.

The color filter 37 is separated into 37R, 37G, and 37B according to its color. The color filter 37 may be disposed on a planarization layer (not illustrated). A resin protective layer (not illustrated) may be disposed on the color filter 37. The color filter 37 may be disposed on the protective layer 36. Alternatively, the color filter 37 may be disposed on an opposite substrate, such as a glass substrate, and then bonded.

FIG. 4B is a schematic cross-sectional view illustrating an example of a display apparatus including organic light-emitting devices and transistors coupled to the organic light-emitting devices. The organic light-emitting devices 26 and thin-film transistors (TFTs) 18 as an example of transistors are provided. A substrate 11 composed of a material, such as glass or silicon, is provided, and an insulating layer 12 is disposed thereon. The TFTs 18 are arranged on the insulating layer 12. A gate electrode 13, a gate insulating film 14, and a semiconductor layer 15 of each of the TFTs 18 are arranged on the insulating layer 12. Each TFT 18 also includes a drain electrode 16 and a source electrode 17. An insulating film 19 is disposed on the TFTs 18. An anode 21 included in the organic light-emitting devices 26 is coupled to the source electrodes 17 through contact holes 20 provided in the insulating film 19.

The mode of electrical connection between the electrodes (anode 21 and cathode 23) included in each organic light-emitting device 26 and the electrodes (source electrode 17 and drain electrode 16) included in a corresponding one of the TFTs 18 is not limited to the mode illustrated in FIG. 4B. That is, it is sufficient that any one of the anode 21 and the cathode 23 is electrically coupled to any one of the source electrode 17 and the drain electrode 16 of the TFT 18.

In the display apparatus illustrated in FIG. 4B, each organic compound layer 22 is illustrated as a single layer; however, the organic compound layer 22 may be formed of a plurality of layers. To reduce the deterioration of the organic light-emitting devices 26, a first protective layer 24 and a second protective layer 25 are disposed on the cathodes 23.

The transistors used in the display apparatus illustrated in FIG. 4B are not limited to transistors using a single-crystal silicon wafer, but may also be thin-film transistors including active layers on the insulating surface of a substrate. Examples of the material of the active layer include single-crystal silicon, non-single-crystal silicon materials, such as amorphous silicon and microcrystalline silicon, and non-single-crystal oxide semiconductors, such as indium-zinc oxide and indium-gallium-zinc oxide.

The transistors in the display apparatus illustrated in FIG. 4B may be formed in the substrate, such as a Si substrate. The phrase “formed in the substrate” indicates that the transistors are produced by processing the substrate such as a Si substrate. In the case where the transistors are formed in the substrate, the substrate and the transistors can be deemed to be integrally formed.

In the organic light-emitting devices 26 according to the present embodiment, the luminance is controlled by the TFTs, which are an example of switching elements; thus, an image can be displayed at respective luminance levels by arranging a plurality of organic light-emitting devices 26 in the plane. The switching elements according to the present embodiment are not limited to the TFTs and may be low-temperature polysilicon transistors or active-matrix drivers formed on a substrate such as a Si substrate. The phrase “on a substrate” can also be said to be “in the substrate”. Whether transistors are formed in the substrate or TFTs are used is selected in accordance with the size of a display unit. For example, in the case where the display unit has a size of about 0.5 inches, organic light-emitting devices can be disposed on a Si substrate.

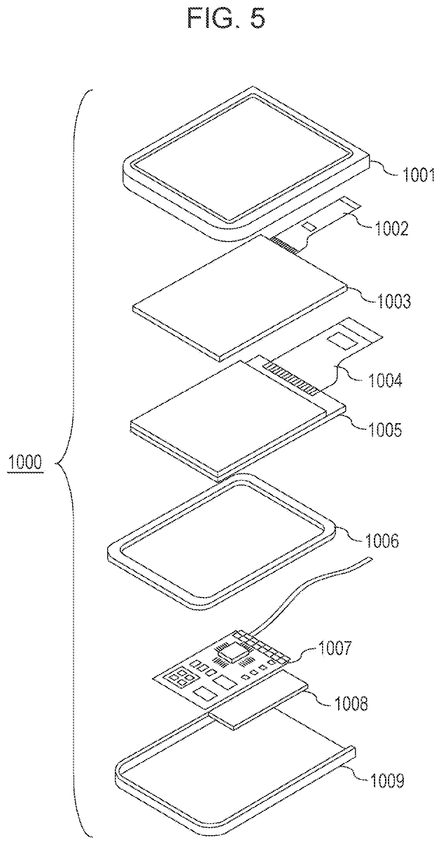

FIG. 5 is a schematic view illustrating an example of a display apparatus according to an embodiment. A display apparatus 1000 includes a touch panel 1003, a display panel 1005, a frame 1006, a circuit board 1007, and a battery 1008 disposed between an upper cover 1001 and a lower cover 1009. The touch panel 1003 and the display panel 1005 are coupled to flexible printed circuits FPCs 1002 and 1004, respectively. The circuit board 1007 includes printed transistors.

The battery 1008 need not be provided unless the display apparatus is a portable apparatus. The battery 1008 may be disposed at a different position even if the display apparatus is a portable apparatus.

The display apparatus according to the present embodiment may include a color filter having red, green, and blue portions. In the color filter, the red, green, and blue portions may be arranged in a delta arrangement.

The display apparatus according to the present embodiment may be used for the display unit of a portable terminal. In that case, the display apparatus may have both a display function and an operation function. Examples of the portable terminal include mobile phones such as smartphones, tablets, and head-mounted displays.

The display apparatus according to the present embodiment may be used for a display unit of an image pickup apparatus including an optical unit including a plurality of lenses and an image pickup device that receives light passing through the optical unit. The image pickup apparatus may include a display unit that displays information acquired by the image pickup device. The display unit may be a display unit exposed to the outside of the image pickup apparatus or a display unit disposed in a finder.

The image pickup apparatus may be a digital camera or a digital camcorder.

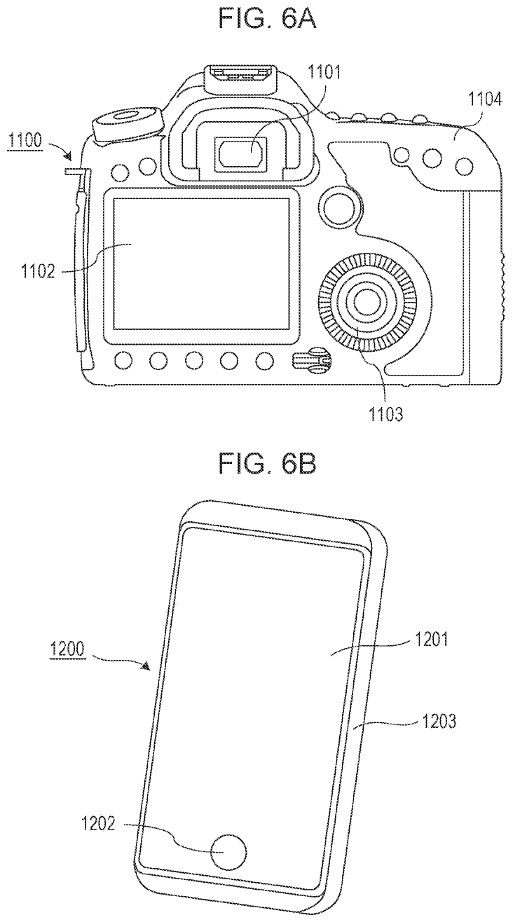

FIG. 6A is a schematic view illustrating an example of an image pickup apparatus according to the present embodiment. An image pickup apparatus 1100 may include a viewfinder 1101, a rear display 1102, an operation unit 1103, and a housing 1104. The viewfinder 1101 includes the display apparatus according to the present embodiment. In this case, the display apparatus may display environmental information, imaging instructions, and so forth in addition to an image to be captured. The environmental information may include, for example, the intensity of external light, the direction of external light, the moving speed of a subject, and the possibility that a subject is shielded by a shielding material.

The timing suitable for imaging is only for a short time; thus, the information may be displayed as soon as possible. Accordingly, the display apparatus including the organic light-emitting device according to the present embodiment is used because of its short response time. The display apparatus including the organic light-emitting device can be used more suitably than liquid crystal display apparatuses for such apparatuses required to have a high display speed.

The image pickup apparatus 1100 includes an optical unit (not illustrated). The optical unit includes a plurality of lenses and is configured to form an image on an image pickup device in the housing 1104. The relative positions of the plurality of lenses can be adjusted to adjust the focal point. This operation can also be performed automatically. The image pickup apparatus is also referred to as a photoelectric conversion apparatus. Examples of an image capturing method employed in the photoelectric conversion apparatus may include a method for detecting a difference from the previous image and a method of cutting out an image from images always recorded, instead of sequentially capturing images.

FIG. 6B is a schematic view illustrating an example of an electronic apparatus according to the present embodiment. An electronic apparatus 1200 includes a display unit 1201, an operation unit 1202, and a housing 1203. The housing 1203 may accommodate a circuit, a printed circuit board including the circuit, a battery, and a communication unit. The operation unit 1202 may be a button or a touch-panel-type reactive unit. The operation unit may be a biometric recognition unit that recognizes a fingerprint to release the lock or the like. An electronic apparatus including a communication unit can also be referred to as a communication apparatus. The electronic apparatus 1200 may further have a camera function by being equipped with a lens and an image pickup device. An image captured by the camera function is displayed on the display unit 1201. Examples of the electronic apparatus include smartphones and notebook computers.

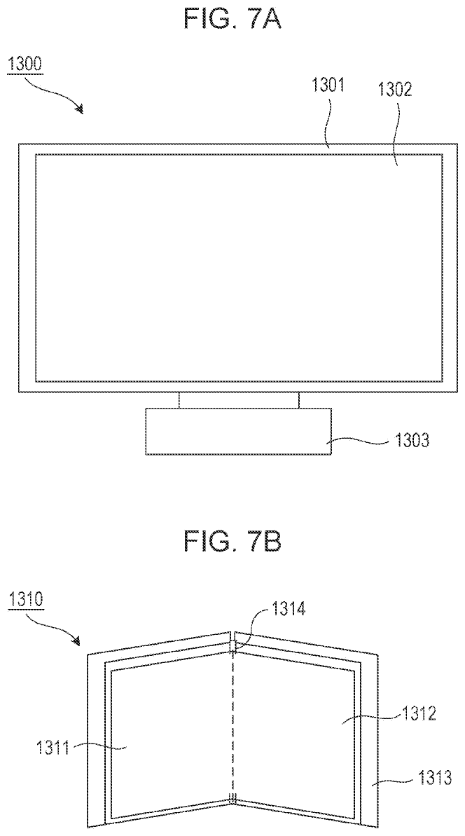

FIG. 7A is a schematic view illustrating an example of a display apparatus according to an embodiment. FIG. 7A illustrates a display apparatus, such as a television monitor or a PC monitor. A display apparatus 1300 includes a frame 1301 and a display unit 1302. The organic light-emitting device according to the present embodiment is used for the display unit 1302. The display apparatus 1300 includes a base 1303 that supports the frame 1301 and the display unit 1302. The base 1303 is not limited to the structure illustrated in FIG. 7A. The lower side of the frame 1301 may also serve as a base. The frame 1301 and the display unit 1302 may be curved. These may have a radius of curvature of 5,000 mm or more and 6,000 mm or less.

FIG. 7B is a schematic view illustrating another example of a display apparatus according to the present embodiment. A display apparatus 1310 illustrated in FIG. 7B can be folded and is what is called a foldable display apparatus. The display apparatus 1310 includes a first display portion 1311, a second display portion 1312, a housing 1313, and an inflection point 1314. The first display portion 1311 and the second display portion 1312 include the organic light-emitting device according to the present embodiment. The first display portion 1311 and the second display portion 1312 may be a single, seamless display apparatus. The first display portion 1311 and the second display portion 1312 can be divided from each other at the inflection point. The first display portion 1311 and the second display portion 1312 may display different images from each other. Alternatively, a single image may be displayed in the first and second display portions.

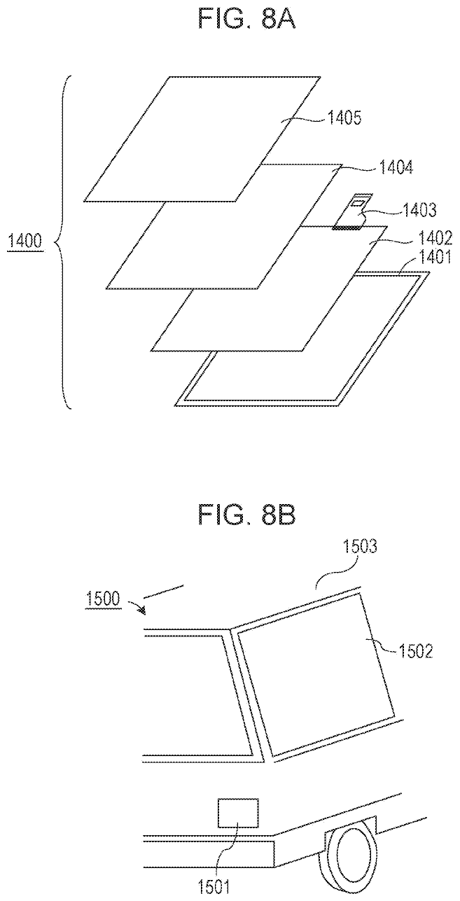

FIG. 8A is a schematic view illustrating an example of a lighting apparatus according to the present embodiment. A lighting apparatus 1400 may include a housing 1401, a light source 1402, a circuit board 1403, an optical filter 1404 that transmits light emitted from the light source 1402, and a light diffusion unit 1405. The light source 1402 includes an organic light-emitting device according to the present embodiment. The optical filter 1404 may be a filter that improves the color rendering properties of the light source. The light diffusion unit 1405 can effectively diffuse light from the light source to deliver the light to a wide range when used for illumination and so forth. The optical filter 1404 and the light diffusion unit 1405 may be disposed at the light emission side of the lighting apparatus. A cover may be disposed at the outermost portion, as needed.

The lighting apparatus is, for example, an apparatus that lights a room. The lighting apparatus may emit light of white, neutral white, or any color from blue to red. A light control circuit that controls the light may be provided. The lighting apparatus may include the organic light-emitting device according to the present embodiment and a power supply circuit coupled to the organic light-emitting device. The power supply circuit is a circuit that converts an AC voltage into a DC voltage.

The color temperature of white is 4,200 K, and the color temperature of neutral white is 5,000 K. The lighting apparatus may include a color filter.

The lighting apparatus according to the present embodiment may include a heat dissipation unit. The heat dissipation unit is configured to release heat in the apparatus to the outside of the apparatus and is composed of, for example, a metal having a high specific heat and liquid silicone.

FIG. 8B is a schematic view illustrating an automobile, as an example of a moving object, according to the present embodiment. The automobile includes a tail lamp, which is an example of a lighting unit. An automobile 1500 includes a tail lamp 1501 and may be configured to light the tail lamp when a brake operation or the like is performed.

The tail lamp 1501 includes an organic light-emitting device according to the present embodiment. The tail lamp 1501 may include a protective member that protects the organic light-emitting device. The protective member may be composed of any transparent material having high strength to some extent and can be composed of, for example, polycarbonate. The polycarbonate may be mixed with, for example, a furandicarboxylic acid derivative or an acrylonitrile derivative.

The automobile 1500 may include an automobile body 1503 and windows 1502 attached thereto. The windows 1502 may be transparent displays if the windows are not used to check the front and back of the automobile. The transparent displays may include an organic light-emitting device according to the present embodiment. In this case, the components, such as the electrodes, of the organic light-emitting device are formed of transparent members.

The moving object according to the present embodiment may be, for example, a ship, an aircraft, or a drone. The moving object may include a body and a lighting unit attached to the body. The lighting unit may emit light to indicate the position of the body. The lighting unit includes the organic light-emitting device according to the present embodiment.

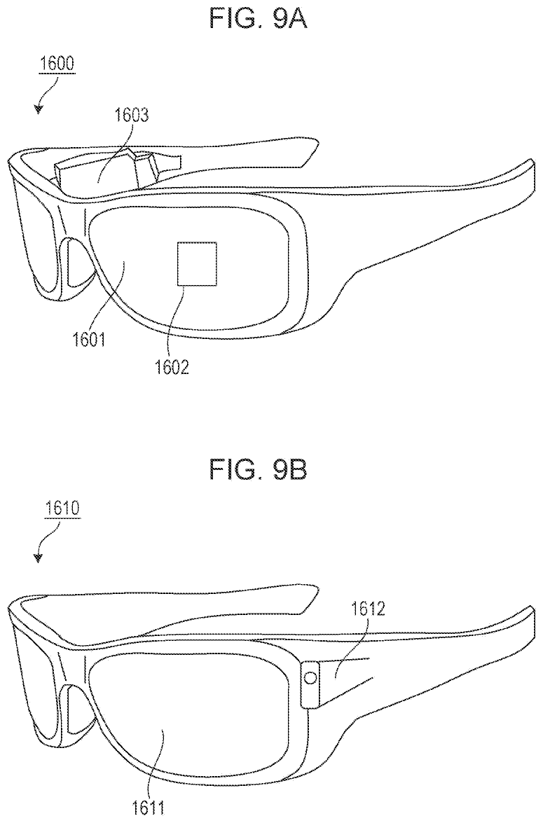

Examples of applications of the display apparatuses of the above embodiments will be described with reference to FIGS. 9A and 9B. The display apparatuses can be used for systems that can be worn as wearable devices, such as smart glasses, head-mounted displays (HMDs), and smart contacts. An image pickup and display apparatus used in such an example of the applications has an image pickup apparatus that can photoelectrically convert visible light and a display apparatus that can emit visible light.

FIG. 9A is a schematic view illustrating an example of a wearable device according to an embodiment. Glasses 1600 (smart glasses) according to an example of applications will be described with reference to FIG. 9A. An image pickup apparatus 1602, such as a complementary metal-oxide semiconductor (CMOS) sensor or a single-photon avalanche diode (SPAD), is provided on a front side of a lens 1601 of the glasses 1600. The display apparatus according to any of the above-mentioned embodiments is provided on the back side of the lens 1601.

The glasses 1600 further include a control unit 1603. The control unit 1603 functions as a power source that supplies electric power to the image pickup apparatus 1602 and the display apparatus. The control unit 1603 controls the operation of the image pickup apparatus 1602 and the display apparatus. The lens 1601 includes an optical system for focusing light on the image pickup apparatus 1602.

FIG. 9B is a schematic view illustrating another example of a wearable device according to an embodiment. Glasses 1610 (smart glasses) according to an example of applications will be described with reference to FIG. 9B. The glasses 1610 include a control unit 1612. The control unit 1612 includes an image pickup apparatus corresponding to the image pickup apparatus 1602 illustrated in FIG. 9A and a display apparatus. A lens 1611 is provided with the image pickup apparatus in the control unit 1612 and an optical system that projects light emitted from the display apparatus. An image is projected onto the lens 1611. The control unit 1612 functions as a power source that supplies electric power to the image pickup apparatus and the display apparatus and controls the operation of the image pickup apparatus and the display apparatus.

The control unit 1612 may include a gaze detection unit that detects the gaze of a wearer. Infrared light may be used for gaze detection. An infrared light-emitting unit emits infrared light to an eyeball of a user who is gazing at a displayed image. An image of the eyeball is captured by detecting the reflected infrared light from the eyeball with an image pickup unit having light-receiving elements. The deterioration of image quality is reduced by providing a reduction unit that reduces light from the infrared light-emitting unit to the display unit when viewed in plan. The user's gaze at the displayed image is detected from the image of the eyeball captured with the infrared light. Any known method can be employed to the gaze detection using the captured image of the eyeball. As an example, a gaze detection method based on a Purkinje image of the reflection of irradiation light on a cornea can be employed. More specifically, the gaze detection process is based on a pupil-corneal reflection method. Using the pupil-corneal reflection method, the user's gaze is detected by calculating a gaze vector representing the direction (rotation angle) of the eyeball based on the image of the pupil and the Purkinje image contained in the captured image of the eyeball.

A display apparatus according to an embodiment may include an image pickup apparatus including light-receiving elements, and may control an image displayed on the display apparatus based on the gaze information of the user from the image pickup apparatus. Specifically, in the display apparatus, a first field-of-view area at which the user gazes and a second field-of-view area other than the first field-of-view area are determined on the basis of the gaze information. The first field-of-view area and the second field-of-view area may be determined by the control unit of the display apparatus or may be determined by receiving those determined by an external control unit. In the display area of the display apparatus, the display resolution of the first field-of-view area may be controlled to be higher than the display resolution of the second field-of-view area. That is, the resolution of the second field-of-view area may be lower than that of the first field-of-view area.

The display area includes a first display area and a second display area different from the first display area. Based on the gaze information, an area of higher priority is determined from the first display area and the second display area. The first display area and the second display area may be determined by the control unit of the display apparatus or may be determined by receiving those determined by an external control unit. The resolution of an area of higher priority may be controlled to be higher than the resolution of an area other than the area of higher priority. In other words, the resolution of an area of a relatively low priority may be low.

Artificial intelligence (AI) may be used to determine the first field-of-view area or the high-priority area. The AI may be a model configured to estimate the angle of gaze from the image of the eyeball and the distance to a target object located in the gaze direction, using the image of the eyeball and the actual direction of gaze of the eyeball in the image as teaching data. The AI program may be stored in the display apparatus, the image pickup apparatus, or an external apparatus. When the AI program is stored in the external apparatus, the AI program is transmitted to the display apparatus via communications.

In the case of controlling the display based on visual detection, smart glasses that further include an image pickup apparatus that captures an external image can be used. The smart glasses can display the captured external information in real time.

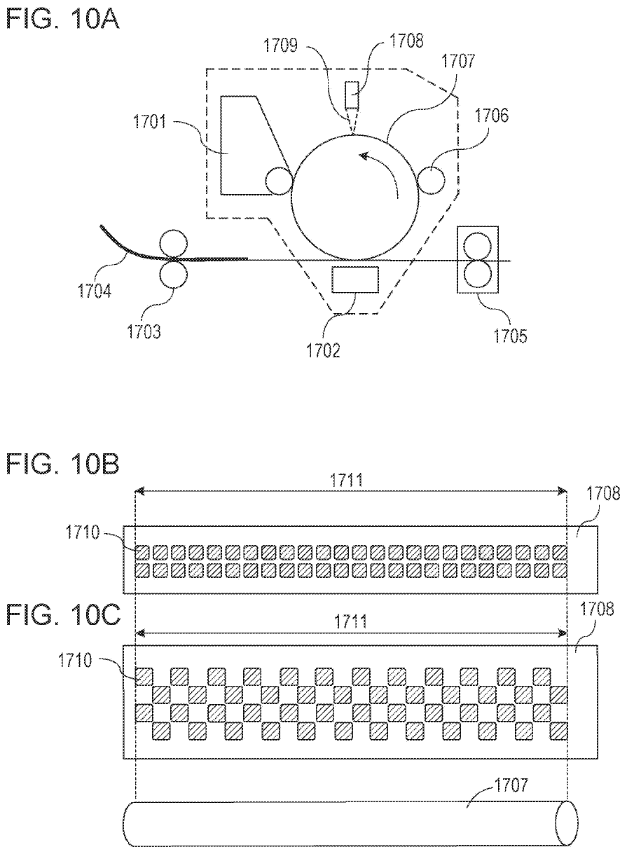

FIG. 10A is a schematic view of an example of an image-forming apparatus according to an embodiment.

An image-forming apparatus is an electrophotographic image-forming apparatus and includes a photoconductor 1707, an exposure light source 1708, a charging unit 1706, a developing unit 1701, a transfer unit 1702, a transport roller 1703, and a fusing unit 1705. The irradiation of light 1709 is performed from the exposure light source 1708 to form an electrostatic latent image on the surface of the photoconductor 1707. This exposure light source 1708 includes the organic light-emitting device according to the present embodiment. The developing unit 1701 contains, for example, a toner. The charging unit 1706 charges the photoconductor 1707.

The transfer unit 1702 transfers the developed image to a recording medium 1704. The transport roller 1703 transports the recording medium 1704. The recording medium 1704 is paper, for example. The fusing unit 1705 fixes the image formed on the recording medium 1704.

FIGS. 10B and 10C each illustrate the exposure light source 1708 and are each a schematic view illustrating a plurality of light-emitting portions 1710 arranged on a long substrate. Arrows 1711 are parallel to the axis of the photoconductor and each represent the row direction in which the light-emitting portions 1710 including the organic light-emitting devices are arranged. The row direction is the same as the direction of the axis on which the photoconductor 1707 rotates. This direction can also be referred to as the long-axis direction of the photoconductor 1707. FIG. 10B illustrates a configuration in which the light-emitting portions 1710 are arranged in the long-axis direction of the photoconductor 1707. FIG. 10C is different from FIG. 10B in that the light-emitting portions 1710 are arranged alternately in the row direction in a first row and a second row. The first row and the second row are located at different positions in the column direction. In the first row, the plurality of light-emitting portions 1710 are spaced apart. The second row has the light-emitting portions 1710 at positions corresponding to the positions between the light-emitting portions 1710 in the first row. In other words, the plurality of light-emitting portions 1710 are also spaced apart in the column direction. The arrangement in FIG. 10C can be rephrased as, for example, a lattice arrangement, a staggered arrangement, or a checkered pattern.

As described above, the use of an apparatus including the organic light-emitting device according to the present embodiment enables a stable display with good image quality even for a long time.

### EXAMPLES

### Example 1

### Evaluation of Singlet Energy

The S1 energy levels of dopants were evaluated by a method described below. Table 1 presents the results.

Photoluminescence (PL) of dilute solutions in toluene was measured using F-4500, available from Hitachi Ltd., with a built-in fluorescence mode at room temperature and an excitation wavelength of 350 nm. The S1 energy levels were calculated from the maximum emission wavelengths of the resulting emission spectra. Evaluation of HOMO and LUMO

The LUMO levels and the HOMO levels of hosts and the dopants were evaluated by methods described below. Table 1 presents the results.

### A) Evaluation Method of HOMO Level

A 30-nm-thick film was formed by vapor deposition on an aluminum substrate under a vacuum of 5×10⁻⁴ Pa or less. Measurement was performed using this thin film with AC-3 (available from Riken Keiki Co., Ltd.).

### B) Evaluation Method of LUMO Level

A 30-nm-thick film was formed by vapor deposition on a quartz substrate under a vacuum of 5×10⁻⁴ Pa. Using this thin film, the optical band gap (absorption edge) of a target material was determined with a spectrophotometer (V-560, available from JASCO Corporation). The sum of the value of the optical band gap and the value of the above-described HOMO level was used as the LUMO level. Table 1 presents the results.

TABLE 1

| | S1 | HOMO | LUMO | | S1 | HOMO | LUMO |
|---|---|---|---|---|---|---|---|
| Compound | (eV) | (eV) | (eV) | Compound | (eV) | (eV) | (eV) |
| BD1 | 2.8 | −5.4 | −2.8 | RD1 | 2.0 | −5.8 | −3.8 |
| BD2 | 2.8 | −5.5 | −2.9 | RD4 | 2.0 | −5.3 | −3.3 |
| BD3 | 2.7 | −5.4 | −2.8 | RD5 | 2.0 | −5.6 | −3.6 |
| BD10 | 2.8 | −6.0 | −3.4 | RD6 | 2.0 | −5.5 | −3.5 |
| BD11 | 2.7 | −6.0 | −3.4 | RD21 | 2.1 | −5.4 | −3.5 |
| BD12 | 2.7 | −6.1 | −3.6 | AM1 | 3.1 | −6.5 | −3.4 |
| BD17 | 2.7 | −6.0 | −3.4 | AM2 | 2.9 | −6.3 | −3.3 |
| BD24 | 2.8 | −6.2 | −3.5 | AM10 | 3.4 | −6.3 | −2.8 |
| GD2 | 2.4 | −5.3 | −3.0 | AM12 | 3.4 | −6.4 | −2.9 |
| | | | | AM13 | 3.4 | −5.6 | −2.6 |
| GD8 | 2.4 | −5.6 | −3.3 | AM15 | 3.4 | −6.1 | −2.6 |
| GD9 | 2.4 | −5.9 | −3.6 | EM1 | 3.0 | −6.0 | −3.1 |
| GD10 | 2.4 | −5.8 | −3.5 | EM2 | 3.0 | −5.9 | −3.0 |
| GD16 | 2.4 | −5.8 | −3.6 | EM5 | 3.0 | −6.0 | −3.1 |
| GD24 | 2.4 | −5.7 | −3.1 | EM14 | 3.4 | −6.4 | −2.9 |
| GD28 | 2.4 | −5.7 | −3.5 | EM18 | 2.2 | −5.7 | −3.4 |
| | | | | EM21 | 2.7 | −5.7 | −3.1 |
| HT3 | 3.0 | −5.6 | −2.6 | EM24 | 2.7 | −5.7 | −3.1 |
| ET19 | 2.9 | −6.1 | −3.2 | EM25 | 2.7 | −6.0 | −3.2 |
| | | | | EM26 | 2.8 | −5.4 | −3.5 |
| | | | | EM28 | 3.4 | −6.2 | −2.7 |

### Example 2

An organic light-emitting device having a bottom-emission structure was produced in which an anode, a hole injection layer, a hole transport layer, an electron-blocking layer, a light-emitting layer, a hole-blocking layer, an electron transport layer, an electron injection layer, and a cathode were sequentially formed on a substrate.

An ITO film was formed on a glass substrate and subjected to desired patterning to form an ITO electrode (anode). The ITO electrode had a thickness of 100 nm. The substrate on which the ITO electrode had been formed in this way was used as an ITO substrate in the following steps. Next, vacuum deposition was performed by resistance heating in a vacuum chamber at 1.33×10⁻⁴ Pa to successively form organic compound layers and an electrode layer presented in Table 2 on the ITO substrate. Here, the opposing electrode (metal electrode layer, cathode) had an electrode area of 3 mm². Thereafter, the substrate was transferred to a glove box and sealed with a glass cap containing a drying agent in a nitrogen atmosphere to provide an organic light-emitting device.

TABLE 2

| | Material | | | Thickness (nm) |
|---|---|---|---|---|
| Cathode | Al | | | 100 |
| Electron injection layer (EIL) | LiF | | | 1 |
| Electron transport layer (ETL) | ET2 | | | 20 |
| Hole-blocking layer (HBL) | ET11 | | | 20 |
| Second light-emitting layer (EML) | Second host | EM1 | Ratio by weight | 15 |
| | | (3.0 eV) | EM1:GD10 = | |
| | Third fluorescent | GD10 | 97:3 | |
| | material | (2.4 eV) | | |
| | (S1 [ev]) | | | |
| First light-emitting layer (EML) | First host | EM2 | Ratio by weight | 5 |
| | | (3.0 eV) | EM2:GD9:RD6 = | |
| | Second | GD9 | 94:5:1 | |
| | fluorescent | (2.4 eV) | | |
| | material | | | |
| | (S1 [ev]) | | | |
| | First fluorescent | RD6 | | |
| | material | (2.0 eV) | | |
| | (S1 [ev]) | | | |

| | | |
|---|---|---|
| Electron-blocking layer (EBL) | HT19 | 15 |
| Hole transport layer (HTL) | HT3 | 30 |
| Hole injection layer (HIL) | HT16 | 5 |

The characteristics of the resulting organic light-emitting device were measured and evaluated. The emission color of the organic light-emitting device was yellow, and the maximum external quantum efficiency (E.Q.E.) was 7%.

The device was subjected to a continuous operation test at a current density of 100 mA/cm². The time when the percentage of luminance degradation reached 5% was measured. Letting the time when the percentage of luminance degradation in Comparative example 1 reached 5% be 1.0, the ratio was defined as a device durability ratio. The device durability ratio of this example was 3.0.

With regard to measurement instruments, in this example, the current-voltage characteristics were measured with a Hewlett-Packard 4140B microammeter, and the luminance was measured with a Topcon BM7.

### Examples 3 to 10 and Comparative Examples 1 to 3

Organic light-emitting devices were produced in the same manner as in Example 2, except that the configurations of the organic compound layers were appropriately changed to compounds given in Table 3. The characteristics of the resulting organic light-emitting devices were measured and evaluated as in Example 2. Table 3 presents the measurement results.

When an assist material was contained in the second light-emitting layer, the ratio by mass of the second organic compound to the assist material to the third light-emitting material was adjusted to 49:49:2.

TABLE 3

| | | First light-emitting layer | | | Second light-emitting layer | | | | | |
|---|---|---|---|---|---|---|---|---|---|---|
| | | | Second light- | First light- | | | Third light- | | | |
| | | First | emitting | emitting | Second | | emitting | | | |
| | | host | material | material | host | Assist | material | | | Device |
| | | (S1 | (S1 [ev]) | (S1 | (S1 | (S1 | (S1 | | E.Q.E | durability |
| | EBL | [ev]) | or assist | [ev]) | [ev] | [ev]) | [ev]) | HBL | [%] | ratio |
| Example 3 | HT19 | EM5 | GD10 | RD5 | EM1 | None | GD2 | ET12 | 7 | 2.6 |
| | | (3.0 eV) | (2.4 eV) | (2.0 eV) | (3.0 eV) | | (2.4 eV) | | | |
| Example 4 | HT15 | EM5 | GD16 | RD1 | EM1 | None | GD2 | ET12 | 6 | 2.4 |
| | | (3.0 eV) | (2.4 eV) | (2.0 eV) | (3.0 eV) | | (2.4 eV) | | | |
| Example 5 | HT15 | EM14 | GD16 | RD1 | EM1 | None | GD2 | ET11 | 5 | 2.3 |
| | | (3.0 eV) | (2.4 eV) | (2.0 eV) | (3.0 eV) | | (2.4 eV) | | | |
| Example 6 | HT19 | EM1 | GD28 | RD21 | EM1 | EM24 | GD28 | ET11 | 8 | 3.9 |
| | | (3.0 eV) | (2.3 eV) | (2.1 eV) | (3.0 eV) | (2.7 eV) | (2.3 eV) | | | |
| Example 7 | HT19 | EM24 | GD28 | RD21 | EM1 | EM24 | GD28 | ET11 | 7 | 3.7 |
| | | (2.7 eV) | (2.3 eV) | (2.1 eV) | (3.0 eV) | (2.7 eV) | (2.3 eV) | | | |
| Example 8 | HT19 | EM21 | GD28 | RD21 | EM1 | None | GD2 | ET11 | 7 | 2.5 |
| | | (2.7 eV) | (2.3 eV) | (2.1 eV) | (3.0 eV) | | (2.4 eV) | | | |
| Example 9 | HT19 | EM26 | GD28 | RD21 | EM1 | None | GD2 | ET12 | 8 | 2.4 |
| | | (2.8 eV) | (2.3 eV) | (2.1 eV) | (3.0 eV) | | (2.4 eV) | | | |
| Example 10 | HT15 | EM26 | GD16 | RD4 | EM2 | None | GD2 | ET12 | 6 | 2.4 |
| | | (2.8 eV) | (2.4 eV) | (2.0 eV) | (3.0 eV) | | (2.4 eV) | | | |
| Comparative | HT19 | EM5 | HT3 | BD3 | EM5 | None | BD3 | ET11 | 6 | 1.0 |
| example 1 | | (3.0 eV) | (3.0 eV) | (2.7 eV) | (3.0 eV) | | (2.7 eV) | | | |
| Comparative | HT19 | HT3 | None | EM18 | EM5 | None | BD3 | ET11 | 6 | 1.1 |
| example 2 | | (3.0 eV) | | (2.2 eV) | (3.0 eV) | | (2.7 eV) | | | |
| Comparative | HT19 | HT3 | None | EM18 | EM5 | ET19 | BD3 | ET11 | 5 | 1.6 |
| example 3 | | (3.0 eV) | | (2.2 eV) | (3.0 eV) | (2.9 eV) | (2.7 eV) | | | |

From Table 3, the E.Q.E. values in Comparative examples 1 to 3 were 6%, 6%, and 5%, respectively. The device durability ratios in Comparative examples 1 to 3 were 1.0, 1.1, and 1.6, respectively. The reason they were not excellent in light emission characteristics and durability characteristics is presumably that the carrier balance in the stacked light-emitting layers was poor.

In contrast, the organic light-emitting devices according to an embodiment exhibited excellent luminous efficiency and excellent device life. This is because the stacked light-emitting layers according to an embodiment have a relationship in which carrier transfer and energy transfer occur easily.

Furthermore, the organic light-emitting devices excellent particularly in device life were successfully produced by selecting the light-emitting materials, i.e., first to third light-emitting materials, suitable for combination with the stacked light-emitting layers of an embodiment.

As described above, the organic compounds according to an embodiment can be used to provide organic light-emitting devices with excellent luminous efficiency and device life.

### Example 11

An organic light-emitting device was produced in the same manner as in Example 2, except that the thickness of the first light-emitting layer was changed to 10 nm. The characteristics of the resulting organic light-emitting device were measured and evaluated in the same manner as in Example 2. The maximum external quantum efficiency (E.Q.E.) was 7%, and the device durability ratio was 3.0.

### Example 12

An organic light-emitting device was produced in the same manner as in Example 2, except that the thickness of the first light-emitting layer was changed to 10 nm and the thickness of the second light-emitting layer was changed to 10 nm. The characteristics of the resulting organic light-emitting device were measured and evaluated as in Example 2. The maximum external quantum efficiency (E.Q.E.) was 6%, and the device durability ratio was 2.9.

### Example 13

An organic light-emitting device was produced in the same manner as in Example 2, except that the component materials and the ratio by mass of the component materials in the first light-emitting layer were changed to EM1:GD9:RD6=96.5:3.0:0.5, and the component materials and the ratio by mass of the component materials in the second light-emitting layer were changed to EM5:GD9=98:2. The characteristics of the resulting organic light-emitting device were measured and evaluated as in Example 2. The maximum external quantum efficiency (E.Q.E.) was 7%, and the device durability ratio was 3.4.

### Example 14

An organic light-emitting device was produced in the same manner as in Example 2, except that the ratio by mass in the first light-emitting layer was changed to EM28:GD9:RD6=95.5:3.0:1.5, and the ratio by mass in the second light-emitting layer was changed to EM14:GD9=95:5. The characteristics of the resulting organic light-emitting device were measured and evaluated as in Example 2. The maximum external quantum efficiency (E.Q.E.) was 6%, and the device durability ratio was 2.7.

According to an embodiment of the disclosure, it is possible to provide the organic light-emitting device having improved durability characteristics.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2022-161354, filed Oct. 6, 2022, which is hereby incorporated by reference herein in its entirety.

What is claimed is:

1. An organic light-emitting device, comprising:
a first electrode;
a first light-emitting layer;
a second light-emitting layer in contact with the first light-emitting layer; and
a second electrode,
wherein the first light-emitting layer contains:
a first organic compound,
a first light-emitting material, and
a second light-emitting material,
the second light-emitting layer contains:
a second organic compound, and
a third light-emitting material, the second light-emitting layer being free of the first light-emitting material,
each of the first light-emitting material, the second light-emitting material, and the third light-emitting material is a fluorescent material, and
the following relationships or inequalities (a) to (c) are satisfied,
S1D2>S1D1 (a),
S1D3≥S1D2 (b),
and
S1D2−S1D1>S1D3−S1D2 (c)
where S1D1 is singlet energy of the first light-emitting material, S1D2 is singlet energy of the second light-emitting material, and S1D3 is singlet energy of the third light-emitting material.

2. The organic light-emitting device according to claim 1, wherein the following relationship or inequality (d) is satisfied,
LUMOD1<LUMOH1 (d)
where LUMOD1 is an energy level of lowest unoccupied molecular orbital of the first light-emitting material, and LUMOH1 is an energy level of lowest unoccupied molecular orbital of the first organic compound.

3. The organic light-emitting device according to claim 1, wherein the following relationship or inequality (e) is satisfied,
LUMOD3<LUMOH2 (e)
where LUMOD3 is an energy level of lowest unoccupied molecular orbital of the third light-emitting material, and LUMOH2 is an energy level of lowest unoccupied molecular orbital of the second organic compound.

4. The organic light-emitting device according to claim 1, wherein the following relationship or inequality (f) is satisfied,
C1D2≥C1D3 (f)
where C1D2 is an amount of the second light-emitting material contained in the first light-emitting layer, and C1D3 is an amount of the third light-emitting material contained in the second light-emitting layer.

5. The organic light-emitting device according to claim 1, wherein the following relationship or inequality (g) is satisfied,
C1D2≥C1D1 (g)
where C1D1 is an amount of the first light-emitting material contained in the first light-emitting layer, and C1D2 is an amount of the second light-emitting material contained in the first light-emitting layer.

6. The organic light-emitting device according to claim 1, wherein the second light-emitting material and the third light-emitting material have at least one identical partial structure.

7. The organic light-emitting device according to claim 6, wherein each of the second light-emitting material and the third light-emitting material has a fluoranthene skeleton.

8. The organic light-emitting device according to claim 6, wherein the second light-emitting material and the third light-emitting material are the same compound.

9. The organic light-emitting device according to claim 1, wherein the following relationships or inequalities (h) and (i) are satisfied,

|LUMOD3−LUMOD2|≤0.2 eV (h)

|HOMOD3−HOMOD2|≤0.2 eV (i)
where LUMOD2 is an energy level of lowest unoccupied molecular orbital of the second light-emitting material, HOMOD2 is an energy level of highest occupied molecular orbital of the second light-emitting material, LUMOD3 is an energy level of lowest unoccupied molecular orbital of the third light-emitting material, and HOMOD3 is an energy level of highest occupied molecular orbital of the third light-emitting material.

10. The organic light-emitting device according to claim 1, wherein the second light-emitting layer contains an assist material.

11. The organic light-emitting device according to claim 1, wherein an emission color of the first light-emitting material is red, and an emission color of the third light-emitting material is green.

12. The organic light-emitting device according to claim 11, wherein the first electrode is an anode, and the second electrode is a cathode, and
wherein the first electrode, the first light-emitting layer, the second light-emitting layer, and the second electrode are arranged in this order.

13. The organic light-emitting device according to claim 12, wherein the following relationship or inequality (j) is satisfied,
C1D3>C1D1 (j)
where C1D1 is an amount of the first light-emitting material contained in the first light-emitting layer, and C1D3 is an amount of the third light-emitting material contained in the second light-emitting layer.

14. The organic light-emitting device of claim 1, wherein the first organic compound and the second organic compound are the same compound.

15. A display apparatus, comprising:
a plurality of pixels,
at least one of the plurality of pixels including:
the organic light-emitting device according to claim 1, and
a transistor coupled to the organic light-emitting device.

16. An image pickup apparatus, comprising:
an optical unit including a plurality of lenses;
an image pickup device configured to receive light passing through the optical unit; and
a display unit configured to display an image captured by the image pickup device,
wherein the display unit includes the organic light-emitting device according to claim 1.

17. An electronic apparatus, comprising:
a display unit including the organic light-emitting device according to claim 1;
a housing provided with the display unit; and
a communication unit being disposed in the housing and communicating with an outside.

18. A lighting apparatus, comprising:
a light source including the organic light-emitting device according to claim 1; and
a light diffusion unit or an optical film configured to transmit light emitted from the light source.

19. A moving object, comprising:
a lighting unit including the organic light-emitting device according to claim 1; and
a body provided with the lighting unit.
